(19) United States
(12) Patent Application Publication
(10) Pub. No.: US 2007/0252233 A1
(43) Pub. Date: Nov. 1, 2007

(54) Semiconductor device and method for manufacturing the semiconductor device

(75) Inventors: Shunpei Yamazaki, Setagaya (JP); Yasuyuki Arai, Atsugi (JP); Ikuko Kawamata, Atsugi (JP)

Correspondence Address: ERIC ROBINSON, PMB 955, 21010 SOUTHBANK ST., POTOMAC FALLS, VA, 20165, US

(73) Assignee: Semiconductor Energy Laboratory Co., Ltd., Atsugi-shi (JP)

(21) Appl. No.: 11/785,150

(22) Filed: Apr. 16, 2007

(30) Foreign Application Priority Data
Apr. 28, 2006 (JP) 2006-126993

(51) Int. Cl. H01L 29/00

(52) U.S. Cl. 257/504

(57) ABSTRACT

A semiconductor device is provided, which comprises a semiconductor layer over an insulating surface, and an insulating layer over the semiconductor layer. The semiconductor layer includes at least two element regions, and an element separation region. The element separation region is disposed between the two element regions. The element separation region includes at least one impurity element selected from the group consisting of oxygen, nitrogen, and carbon. The element separation region has higher resistance than a first source and drain regions included in one of the two element regions and a second source and drain regions included in the other of the two element regions.

### BACKGROUND OF THE INVENTION

1. Field of the Invention

The present invention relates to a semiconductor device that has a plurality of semiconductor elements, and a manufacturing method thereof.

2. Description of the Related Art

In a case where a plurality of semiconductor elements are provided over an insulating surface, a method in which a semiconductor layer formed over an insulating surface is processed into a plurality of island-shaped semiconductor layers by etching treatment is used. The semiconductor element has a stacked-layer structure of plural thin films, and in a case of a thin film transistor of a planer type, a gate insulating layer is stacked so as to cover the semiconductor layers that are separated to have an island shape.

The semiconductor layers processed into an island shape each have a step in an edge portion thereof; therefore, a defect is caused in the edge portion, such that the gate insulating layer is to be thin and the film is damaged.

Characteristic defects to a semiconductor device are caused, such that a leakage current flows between a gate electrode and the semiconductor layer when the gate insulating layer is to be thin, and the gate electrode and the semiconductor layer are in contact with each other and be short-circuited (short) when the gate insulating layer is damaged.

In order to solve the foregoing problem, a method is performed, in which two gate insulating layers having a different shape from each other are stacked, a step in an edge portion of a semiconductor layer is moderated, and coverage is improved (for example, refer to Patent Document 1: Japanese Published Patent Application No. H10-242471).

### SUMMARY OF THE INVENTION

However, in the above method for moderating a step, defects such as a short between a semiconductor layer due to a contact and a gate electrode and a leakage current cannot be sufficiently prevented depending on a thickness of the semiconductor layer and a gate insulating layer. In particular, when a semiconductor element is miniaturized, there is a problem in that the leakage current (for example, the gate length is less than or equal to 1 μm) is notably generated.

It is an object of the present invention to provide a highly reliable semiconductor device in which defects such as a short between a gate electrode and a semiconductor layer and a leakage current due to insufficient coverage of the semiconductor layer with a gate insulating layer are prevented, and a manufacturing method for such a semiconductor device.

In the present invention, in order to form a plurality of semiconductor elements over an insulating surface, an element region serving as a semiconductor element and an element separation region having high resistance and a function for electrically separate the element regions are formed in an uninterrupted semiconductor layer without separating a semiconductor layer into a plurality of semiconductor layers having an island shape.

The element separation region is formed by selective addition of at least one or more kinds of impurity elements of oxygen, nitrogen, and carbon in the uninterrupted semiconductor layer so as to electrically separate elements. The element separation region to which an impurity element that does not contribute to conductivity is added becomes to have high resistance because conductivity is reduced due to mixture of the impurity element that does not contribute to improvement in conductivity and crystallinity is reduced due to physical impact (it can be also referred to as so-called sputtering effect) to the semiconductor layer when adding the impurity element. It is to be noted that the impurity element that does not contribute to conductivity means an impurity element that does not contribute to improvement in conductivity in the present invention. In the element separation region that becomes to have high resistance, elements can be electrically separated because electron field-effect mobility is also reduced. On the other hand, a region to which the impurity element is not added can be used as an element region because electron field-effect mobility capable of serving as an element is held.

It is to be noted that the element region also includes an element formation region before an element is formed in the present specification. Therefore, during an element manufacturing process, an element formation region that is insulated by the element separation region of high resistance in the semiconductor layer is referred to as an element region even when an element is not completed therein (before a step in which other electrode layers and insulating layers are formed).

As addition (introduction) of the impurity element that does not contribute to conductivity in a case of forming the element separation region, an ion implantation method, a (ion) doping method, or the like can be used.

Resistivity of the element separation region is preferably greater than or equal to 1×10¹⁰ Ω·cm, and concentration of the impurity element such as oxygen, nitrogen, or carbon is preferably greater than or equal to 1×10²⁰ cm⁻³ and less than 4×10²² cm⁻³.

It can be said that the element separation region is amorphous because crystallinity is reduced due to addition of the impurity element. On the other hand, the element region is a crystalline semiconductor layer; therefore, in a case of forming a semiconductor element in the element region, crystallinity of a channel formation region thereof is higher than that in the element separation region, and high electron electric-field mobility can be obtained as for a semiconductor element.

As the impurity element added to the element separation region, a rare gas element such as argon (Ar), neon (Ne), krypton (Kr), or xenon (Xe) may be used. When the rare gas element that has comparatively large mass is further added in addition to oxygen, nitrogen, and carbon, physical impact to the semiconductor layer can be increased, and accordingly, crystallinity can be efficiently reduced.

Therefore, with the use of the present invention, separation into a plurality of element regions can be performed without division of a semiconductor layer into island shapes. A step in an edge portion of the semiconductor layer is not generated, and a gate insulating layer is formed over the plane semiconductor layer. As a result, coverage of the semiconductor layer with the gate insulating layer is improved. Accordingly, a highly reliable semiconductor device in which defects such as a short between a gate electrode and a semiconductor layer and a leakage current due to insufficient coverage of the semiconductor layer with the gate insulating layer are prevented, and a manufacturing method of such a semiconductor device can be provided.

It is to be noted that a semiconductor device in the present invention indicates a device that can function with the use of a semiconductor characteristic. A device that has a circuit including a semiconductor element (such as a transistor, a memory element, or a diode), and a semiconductor device such as a chip having a processor circuit can be manufactured with the use of the present invention.

One mode of a semiconductor device of the present invention includes a semiconductor layer including an element separation region and an element region over an insulating surface, where the element separation region and the element region are in contact with each other, the element separation region includes at least one or more kinds of impurity elements of oxygen, nitrogen, and carbon, and the element separation region has higher resistance than the element region.

Another mode of a semiconductor device of the present invention includes a semiconductor layer including an element separation region and an element region over an insulating surface, where the element region has a source region, a drain region, and a channel formation region, the element separation region and the element region are in contact with each other, the element separation region includes at least one or more kinds of impurity elements of oxygen, nitrogen, and carbon, and the element separation region has lower crystallinity than the channel formation region.

Another mode of a semiconductor device of the present invention includes a semiconductor layer including an element separation region, and a first element region and a second element region that are near to each other with the element separation region placed therebetween over an insulating surface, where the element separation region includes at least one or more kinds of impurity elements of oxygen, nitrogen, and carbon, and the element separation region has higher resistance than the first element region and the second element region.

Another mode of a semiconductor device of the present invention includes a semiconductor layer including an element separation region, and a first element region and a second element region that are near to each other with the element separation region placed therebetween over an insulating layer, where the first element region includes a first source region, a first drain region, and a first channel formation region, the second element region includes a second source region, a second drain region, and a second channel formation region, the element separation region includes at least one or more kinds of impurity elements of oxygen, nitrogen, and carbon, and the element separation region has lower crystallinity than the first channel formation region and the second channel formation region.

One mode of a method for manufacturing a semiconductor device of the present invention includes the steps of forming a semiconductor layer over an insulating surface, forming an element region and an element separation region in the semiconductor layer by selective addition of at least one or more kinds of impurity elements of oxygen, nitrogen, and carbon to the semiconductor layer, where the element separation region includes the impurity element, forming an insulating layer over the element region and the element separation region, and forming a gate electrode layer over the element region and the insulating layer.

Another mode of a method for manufacturing a semiconductor device of the present invention includes the steps of forming a semiconductor layer over an insulating surface, forming an element region and an element separation region in the semiconductor layer by selective addition of at least one or more kinds of impurity elements of oxygen, nitrogen, and carbon to the semiconductor layer, where the element separation region includes the impurity element and has higher resistance than the element region, forming an insulating layer over the element region and the element separation region, and forming a gate electrode layer over the element region and the insulating layer.

Another mode of a method for manufacturing a semiconductor device of the present invention includes the steps of forming a semiconductor layer over an insulating surface, forming an element region and an element separation region in the semiconductor layer by selective addition of at least one or more kinds of impurity elements of oxygen, nitrogen, and carbon to the semiconductor layer, where the element separation region includes the impurity element and has lower crystallinity than the element region, forming an insulating layer over the element region and the element separation region, and forming a gate electrode layer over the element region and the insulating layer.

Another mode of a method for manufacturing a semiconductor device of the present invention includes the steps of forming a semiconductor layer over an insulating surface, forming an insulating layer over the semiconductor layer, forming an element region and an element separation region in the semiconductor layer by selective addition of at least one or more kinds of impurity elements of oxygen, nitrogen, and carbon to the semiconductor layer through the insulating layer, where the element separation region includes the impurity element, and forming a gate electrode layer over the element region and the insulating layer.

Another mode of a method for manufacturing a semiconductor device of the present invention includes the steps of forming a semiconductor layer over an insulating surface, forming an insulating layer over the semiconductor layer, forming an element region and an element separation region in the semiconductor layer by selective addition of at least one or more kinds of impurity elements of oxygen, nitrogen, and carbon to the semiconductor layer through the insulating layer, where the element separation region includes the impurity element and has higher resistance than the element region, and forming a gate electrode layer over the element region and the insulating layer.

Another mode of a method for manufacturing a semiconductor device of the present invention includes the steps of forming a semiconductor layer over an insulating surface, forming an insulating layer over the semiconductor layer, forming an element region and an element separation region in the semiconductor layer by selective addition of at least one or more kinds of impurity elements of oxygen, nitrogen, and carbon to the semiconductor layer through the insulating layer, where the element separation region includes the impurity element and has lower crystallinity than the element region, and forming a gate electrode layer over the element region and the insulating layer.

With the use of the present invention, separation into a plurality of element regions can be performed without division of the semiconductor layer into island shapes, and a plurality of semiconductor elements can be manufactured. Accordingly, a step is not generated in an edge portion of the semiconductor layer, and a gate insulating layer is formed over the plane semiconductor layer. Therefore, coverage of the semiconductor layer with the gate insulating layer is improved.

Accordingly, a highly reliable semiconductor device in which defects such as a short between a gate electrode and a semiconductor layer and a leakage current due to insufficient coverage of the semiconductor layer with a gate insulating layer are prevented, and a manufacturing method of such a semiconductor device can be provided. Therefore, miniaturization and high integration can be further performed in the semiconductor device, and high efficiency can be achieved.

### BRIEF DESCRIPTION OF DRAWINGS

FIG. 1A is a view explaining a top view of a semiconductor device of the present invention, and FIGS. 1B and 1C are views each explaining a cross-sectional view thereof.

FIG. 2A is a view explaining a top view of a semiconductor device of the present invention, and FIGS. 2B and 2C are views each explaining a cross-sectional view thereof.

FIG. 3A is a view explaining a top view of a semiconductor device of the present invention, and FIGS. 3B and 3C are cross-sectional views each explaining a cross-sectional view thereof.

FIG. 4A is a view explaining a top view of a semiconductor device of the present invention, and FIGS. 4B and 4C are cross-sectional views each explaining a cross-sectional view thereof.

FIGS. 5A to SE are views each explaining a manufacturing method of a semiconductor device of the present invention.

FIGS. 6A to 6E are views each explaining a manufacturing method of a semiconductor device of the present invention.

FIGS. 7A to 7E are views each explaining a manufacturing method of a semiconductor device of the present invention.

FIGS. 8A to 8E are views each explaining a manufacturing method of a semiconductor device of the present invention.

FIGS. 9A to 9C are views each explaining a manufacturing method of a semiconductor device of the present invention.

FIGS. 10A to 10C are views each explaining a manufacturing method of a semiconductor device of the present invention.

FIG. 11A is a view explaining a top view of a semiconductor device of the present invention, and FIG. 11B is a view explaining a cross-sectional view thereof.

FIG. 12 is a diagram showing an example of an equivalent circuit of a semiconductor device.

FIG. 13 is a diagram showing an example of an equivalent circuit of a semiconductor device.

FIG. 14 is a diagram showing an example of an equivalent circuit of a semiconductor device.

FIG. 15 is a view explaining a top view of a semiconductor device of the present invention.

FIGS. 16A and 16B are views each explaining a cross-sectional view of a semiconductor device of the present invention.

FIG. 17 is a view explaining a top view of a semiconductor device of the present invention.

FIGS. 18A and 18B are views each explaining a cross-sectional view of a semiconductor device of the present invention.

FIG. 19 is a diagram showing an example of a circuit block diagram of a semiconductor device.

FIGS. 20A to 20D are views each explaining a top view of a semiconductor device of the present invention.

FIGS. 21A to 21G are views each explaining an application example of a semiconductor device of the present invention.

FIGS. 22A to 22C are views each explaining an application example of a semiconductor device of the present invention.

FIGS. 23A to 23E are views each explaining an application example of a semiconductor device of the present invention.

FIGS. 24A and 24B are diagrams each explaining writing operation of a semiconductor device.

FIGS. 25A and 25B are views each explaining erasing and reading operation of a semiconductor device.

### DETAILED DESCRIPTION OF THE INVENTION

Embodiment modes of the preset invention will be explained in detail with reference to drawings. However, the present invention is not limited to description below, and the present invention is easily understood by those skilled in the art that various changes and modifications are possible, unless such changes and modifications depart from the content and the scope of the present invention. Therefore, the present invention is not construed as being limited to the description of the following embodiment modes. It is to be noted that the same portion or the portion having the similar function is denoted by the same reference numeral in all the drawings, and repeated explanation thereof is omitted.

### Embodiment Mode 1

In this embodiment mode, as an example of a semiconductor device intended to prevent defectes such as a short between a gate electrode layer and a semiconductor layer and a leakage current due to insufficient coverage of the semiconductor layer with a gate insualting layer and to give higher reliablility, a CMOS (Complementary Metal Oxide Semiconductor) will be explained with reference to drawings.

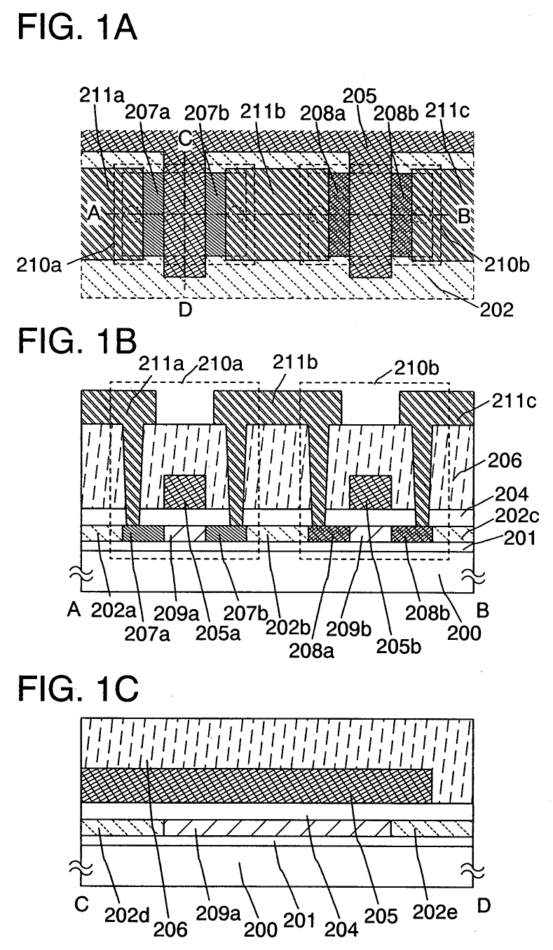

FIGS. 1A to 1C show an example of a semiconductor device having a CMOS structure of this embodiment mode. FIG. 1A is a top view, FIG. 1B is a cross-sectional view taken along a line A-B in FIG. 1A, and FIG. 1C is a cross-sectional view taken along a line C-D in FIG. 1A.

Over a substrate 200 over which an insulating layer 201 serving as a base film for a semiconductor layer is formed, a CMOS structure made of a transistor 210a and a transistor 210b that are an n-channel thin film transistor and a p-channel film transistor, respectively, and an insulating layer 206 are formed. The transistor 210a includes an element region made of n-type impurity regions 207a and 207b and a channel formation region 209a, and a gate electrode layer 205a. The transistor 210b includes an element region made of p-type impurity regions 208a and 208b and a channel formation region 209b, and a gate electrode layer 205b. A gate insulating layer 204 and the insulating layer 206 are uninterruptedly formed over the transistors 210a and 210b. In addition, a wiring layer 211a that is a source or drain electrode layer connected to the n-type impurity region 207a, a wiring layer 211b that is a source or drain electrode layer connected to the n-type impurity region 207b and the p-type impurity region 208a, and a wiring layer 211c that is a source or drain electrode layer connected to the p-type impurity region 208b are provided. The transistor 210a and the transistor 210b are electrically connected by the wiring layer 211b (see FIGS. 1A to 1C).

In a semiconductor layer, the element region made of the n-type impurity regions 207a and 207b and the channel formation region 209a, which are included in the transistor 210a, and the element region made of the p-type impurity regions 208a and 208b and the channel formation region 209b, which are included in the transistor 210b, are electrically separated by element separation regions 202 (202a, 202b, 202c, 202d, and 202e).

The element separation region is formed by selective addition of at least one or more kinds of impurity elements of oxygen, nitrogen, and carbon so as to electrically separate the elements in the uninterrupted semiconductor layer. The element separation region to which the impurity element that does not contribute to conductivity is added becomes to have high resistance because conductivity is reduced due to mixture of the impurity element that does not contribute to conductivity and crystallinity is reduced by physical impact (it can be referred to as so-called sputtering effect) to the semiconductor layer when adding the impurity element. In the element separation region that becomes to have high resistance, the elements can be electrically separated because electron field-effect mobility is also reduced. On the other hand, the region to which the impurity element is not added holds electric field-effect mobility capable of serving as an element because high crystallinity and low resistance are held; therefore, the region to which the impurity element is not added can be used as an element region.

Resistivity of the element separation region is preferably greater than or equal to 1×10¹⁰ Ω·cm, and concentration of the impurity element such as oxygen, nitrogen, or carbon is preferably greater than or equal to 1×10²⁰ cm⁻³ and less than 4×10²² cm⁻³.

It can be said that the element separation region is amorphous because crystallinity is reduced due to addition of the impurity element. On the other hand, the element region is a crystalline semiconductor layer; therefore, in a case of forming a semiconductor element in the element region, crystallinity of a channel formation region thereof is higher than that in the element separation region, and high electron field-effect mobility can be obtained as for a semiconductor element.

As the impurity element added to the element separation region, a rare gas element such as argon (Ar), neon (Ne), krypton (Kr), or xenon (Xe) may be used. When the rare gas element that has comparatively large mass is further added in addition to oxygen, nitrogen, or carbon, physical impact to the semiconductor layer can be increased, and accordingly, crystallinity can be efficiently reduced. As addition (introduction) of the impurity element that does not contribute to conductivity in a case of forming the element separation region, an ion implantation method, a (ion) doping method, or the like can be used.

In FIG. 1C, the gate insulating layer 204 is formed over the channel formation region 209a and the element separation regions 202d and 202e in the semiconductor layer, and a gate electrode 205 is formed over the gate insulating layer 204. In the present invention, the element separation region and the element region are provided in the uninterrupted semiconductor layer; therefore, the element separation regions 202d and 202e and the element region including the channel formation region 209a are uninterrupted. Accordingly, a surface thereof has high planarity and no steep step.

Since the gate insulating layer 204 is formed over the semiconductor layer having high planarity, coverage is favorable and a defective shape is hardly generated. Therefore, defects such as a short and a leakage current between the gate electrode layer 205 formed over the gate insulating layer 204 and the element region can be prevented. Accordingly, the semiconductor device having the CMOS structure of this embodiment mode can be a highly reliable semiconductor device in which defects such as a short between the gate electrode and the semiconductor layer and a leakage current due to insufficient coverage of the semiconductor layer with the gate insulating layer are prevented.

Further, in FIG. 1B, the impurity region is shown by hatching and a blank space. This does not mean that the blank space is not doped with an impurity element, but makes it easy to understand that the concentration distribution of the impurity element in this region reflects the mask and the doping condition. It is to be noted that this is the same in other drawings of the present specification.

As the substrate 200 that has an insulating surface, a glass substrate, a quartz substrate, a sapphire substrate, a ceramic substrate, a metal substrate having an insulating layer over a surface thereof, or the like can be used.

As the insulating layer 201, the gate insulating layer 204, and the insulating layer 206, silicon oxide, silicone nitride, silicon oxynitride, silicon nitride oxide, or the like can be used. In addition, the insulating layer 201, the gate insulating layer 204, and the insulating layer 206 may be a single layer or have a staked-layer structure having two or three layers. It is to be noted that silicon oxynitride in the present specification indicates a substance in which the content of oxygen is higher than that of nitrogen, and it can also be referred to as silicon oxide containing nitrogen. In the same manner, silicon nitride oxide indicates a substance in which the content of nitrogen is higher than that of oxygen, and it can also be referred to as silicon nitride containing oxygen.

As another material of the insulating layer 201, the gate insulating layer 204, and the insulating layer 206, a material of aluminum nitride, aluminum oxynitride in which the content of oxygen is higher than that of nitrogen, aluminum nitride oxide or aluminum oxide in which the content of nitrogen is higher than that of oxygen, diamond like carbon (DLC), nitrogen-containing carbon, polysilazane, and other substances containing an inorganic insulating material can be used. A material containing siloxane may also be used. Siloxane corresponds to a material including the Si—O—Si bond. It is to be noted that siloxane includes a skeleton structure formed by the bond of silicon (Si) and oxygen (O). As a substituent thereof, an organic group containing at least hydrogen (for example, an alkyl group or an arly group) is used. Alternatively, a fluoro group may also be used as the substituent. Furthermore, a fluoro group and an organic group containing at least hydrogen may also be used as the substituent. Furthermore, an oxazole resin can be used, for example a photosensitive polybenzoxazole or the like can be used.

The insulating layer 201, the gate insulating layer 204, and the insulating layer 206 can be formed by a sputtering method, a PVD (Physical Vapor Deposition) method, a low pressure CVD method (LPCVD method), or a CVD (Chemical Vapor Deposition) method such as a plasma CVD method. Alternatively, a droplet discharging method by which a pattern can be selectively formed, a printing method by which a pattern can be transferred or described (a method, such as a screen printing method or an offset printing method, by which a pattern can be formed), or other methods such as a coating method such as a spin coating method, a dipping method, a dispenser method, or the like can also be used.

An etching process for processing an object into a desired shape may employ either plasma etching (dry etching) or wet etching. In a case of processing a large area substrate, plasma etching is suitable. As an etching gas, a fluorine based gas such as CF₄ or NF₃ or a chlorine based gas such as Cl₂ or BCl₃ is used, to which an inert gas such as He or Ar may be appropriately added. When an etching process by atmospheric pressure discharge is employed, local electric discharge can also be realized, which does not require a mask layer to be formed over an entire surface of the substrate.

Further, the gate insulating layer may be formed by performing plasma treatment to the semiconductor layer. When the plasma treatment is performed under a nitrogen atmosphere or an oxygen atmosphere, for example, nitriding treatment or oxidation treatment is performed to a surface of the semiconductor layer using silicon or the vicinity thereof, and a nitrogen plasma treatment layer or an oxygen plasma treatment layer can be formed. Further, when the gate insulating layer is subjected to oxidation treatment or nitriding treatment (alternatively, both oxygen treatment and nitriding treatment can be performed) using plasma treatment, a surface of the gate insulating layer is modified, and then a further dense gate insulating layer can be formed. Therefore, a defect such as a pinhole can be suppressed, and a characteristic of the semiconductor device or the like can be improved.

As solid-phase oxidation treatment or solid-phase nitriding treatment by plasma treatment, plasma excited by a microwave (typically, 2.45 GHz), in which an electron density is greater than or equal to 1×10¹¹ cm⁻³ and less than or equal to 1×10¹³ cm⁻³ and an electron temperature is greater than or equal to 0.5 eV or less than or equal to 1.5 eV, is preferably used. This is because, in the solid-phase oxidation treatment or solid-phase nitriding treatment at a temperature of less than or equal to 500° C., a dense insulating layer is formed and a practical response speed is obtained.

In a case where a surface of the semiconductor layer is oxidized by this plasma treatment, the plasma treatment is performed under an oxygen atmosphere. As the oxygen atmosphere, for example, an atmosphere including oxygen (O₂) and a rare gas; an atmosphere including dinitrogen monoxide (N₂O) and a rare gas; an atmosphere including oxygen, hydrogen (H₂), and a rare gas; or an atmosphere including dinitrogen monoxide, hydrogen, and a rare gas is given. As the rare gas, at least one of He, Ne, Ar, Kr, and Xe is included. In a case where the surface of the semiconductor layer is nitrided by the plasma treatment, the plasma treatment is performed under a nitrogen atmosphere. As the nitrogen atmosphere, for example, an atmosphere including nitrogen (N₂) and a rare gas; an atmosphere including nitrogen, hydrogen, and a rare gas; or an atmosphere including NH₃ and a rare gas is given. As the rare gas, at least one of He, Ne, Ar, Kr, and Xe is included. In this embodiment mode, as a rare gas, Ar can be used, for example. Further, a gas in which Ar and Kr are mixed may be used. It is to be noted that the plasma treatment includes oxidation treatment, nitriding treatment, oxynitriding treatment, hydrogenation treatment, and surface modifying treatment to a semiconductor layer, an insulating layer, and a conductive layer. When plasma excitation is performed by introduction of the microwave, plasma having a high electron density (greater than or equal to 1×10¹¹ cm⁻³) can be generated at a low electron temperature (less than or equal to 3 eV, preferably, less than or equal to 1.5 eV). By an oxygen radical (there is a case where an OH radical is included) and/or a nitrogen radical (there is a case where a NH radical is included) generated by the high-density plasma, a surface of the semiconductor layer can be oxidized or nitrided. When a rare gas such as argon is mixed into the gas for plasma treatment, an oxygen radical or a nitrogen radical can be efficiently generated in accordance with excited species of the rare gas.

A surface of a silicon layer is oxidized by plasma treatment as a typical example of the semiconductor layer, whereby a dense oxide layer that has no distortion in an interface can be formed. Further, the oxide layer is nitrided by plasma treatment, whereby, when oxygen in an outer layer is substituted by nitrogen to form a nitride layer, the layer can be further dense. Accordingly, an insulating layer with high dielectric voltage can be formed.

However, in a case of performing plasma treatment in the present invention, the plasma treatment is performed under the condition where adverse affect is not given to an electric characteristic of a transistor.

Furthermore, after the substrate, the insulating layer, an interlayer insulating layer are formed as well as another insulating layer, conductive layer, and the like for forming the semiconductor device, oxidation treatment or nitriding treatment are performed using plasma treatment, whereby a surface of the substrate, insulating layer, and interlayer insulating layer may be subjected to oxidation treatment or nitriding treatment. When the semiconductor layer and the insulating layer are subjected to oxidation treatment or nitriding treatment using plasma treatment, a surface of the insulating layer is modified, and a further dense insulating layer can be formed as compared with an insulating layer formed by a CVD method or a sputtering method. Therefore, a defect such as a pinhole can be suppressed, and a characteristic of the semiconductor device or the like can be improved. In addition, the above plasma treatment can be performed to the conductive layer such as a gate electrode layer, a source wiring layer, and a drain wiring layer, and a surface thereof and the vicinity of the surface can be subjected to nitriding treatment or oxidation treatment.

As the semiconductor layer, one formed from a single crystalline semiconductor or a polycrystalline semiconductor is preferably used. As formation, for example, a semiconductor layer formed by a sputtering method, a plasma CVD method, or a low pressure CVD method over an entire surface of the substrate is crystallized. As a semiconductor material, silicon is preferable, and in addition, a silicon germanium semiconductor can be used. As a crystallization method of the semiconductor layer, a laser crystallization method, a crystallization method by thermal treatment using rapid thermal annealing (RTA) or an annealing furnace, a crystallization method using a metal element promoting crystallization, or a method in which these methods are combined can be adopted.

A p-type impurity may be injected to the semiconductor layer. As the p-type impurity, for example, boron is used, which may be added at concentration of about 5×10¹⁵ atoms/Cm³ to 1×10¹⁶ atoms/cm³. The impurity is used for controlling a threshold voltage of a transistor, and the impurity is added to the channel formation regions 209a and 209b, whereby it operates effectively.

The wiring layer and the gate electrode layer included in the transistor can be formed from a material selected from indium tin oxide (ITO), indium zinc oxide (IZO) in which zinc oxide (ZnO) is mixed with indium oxide, a conductive material in which silicon oxide (SiO₂) is mixed with indium oxide, organoindium, organotin, indium oxide containing tungsten oxide, indium zinc oxide containing tungsten oxide, indium oxide containing titanium oxide, or indium tin oxide containing titanium oxide; a metal such as tungsten (W), molybdenum (Mo), zirconium (Zr), hafnium (Hf), vanadium (V), niobium (Nb), tantalum (Ta), chromium (Cr), cobalt (Co), nickel (Ni), titanium (Ti), platinum (Pt), aluminum (Al), copper (Cu), or silver (Ag); an alloy of such metals; or metal nitride thereof.

The thin film transistor is not limited to this embodiment mode, and it may have a single gate structure in which one channel formation region is formed, a double gate structure in which two channel formation regions are formed, or a triple gate structure in which three channel formation regions are formed. In addition, a thin film transistor in a peripheral driver circuit region may have a single gate structure, a double gate structure, or a triple gate structure.

Therefore, with the use of the present invention, separation into a plurality of element regions can be performed without division of a semiconductor layer into island shapes. A step is not generated in an edge portion of the semiconductor layer, and a gate insulating layer is formed over the plane semiconductor layer. As a result, coverage of the semiconductor layer with the gate insulating layer is improved. Accordingly, a highly reliable semiconductor device in which defects such as a short between a gate electrode layer and a semiconductor layer and a leakage current due to insufficient coverage of the semiconductor layer with a gate insulating layer are prevented, and a manufacturing method of such a semiconductor device can be provided. Thus, further miniaturization and high integration can be performed in the semiconductor device, and high efficiency of the semiconductor device can be achieved. In addition, a defect due to a defective shape of such a film can be reduced; therefore, production can be performed with high yield in the manufacturing process.

### Embodiment Mode 2

In this embodiment mode, as a semiconductor device intended to prevent defects such as a short between an electrode layer and a semiconductor layer and a leakage current due to insufficient coverage of the semiconductor layer with an insulating layer and to give higher reliability, an example of a nonvolatile semiconductor storage device will be explained with reference to drawings.

A nonvolatile storage element has a similar structure to a MOSFET (Metal Oxide Semiconductor Filed Effect Transistor) and a feature that a region capable of accumulating charges for a long period is provided over a channel formation region. This charge accumulating region is formed over an insulating layer and insulated from circumference; thus, it is also referred to as a floating gate electrode layer. In addition, the floating gate electrode layer is referred to as a charge accumulating layer because it has a function for accumulating charges. In the present specification, this charge accumulating region mainly including the floating gate electrode layer is referred to as a charge accumulating layer. Over the floating gate electrode layer, a control gate electrode layer is provided with an insulating layer interposed therebetween.

In a so-called floating gate-type nonvolatile semiconductor storage device having such a structure, operation is performed, in which charges are accumulated in the charge accumulating layer and then discharged by a voltage that is applied to the control gate electrode layer. In other words, the nonvolatile semiconductor storage device has mechanism in which data is stored by taking in and out charges to be held in the charge accumulating layer. Specifically, charges are injected and drawn into and from the charge accumulating layer by application of a high voltage between a semiconductor layer in which a channel formation region is formed and a control gate electrode layer. It is said that hot electrons (NOR type) or Fowler-Nordheim type (F-N type) tunnel current (NAND type) flows in an insulating layer over the channel formation region, at this time. From this, the insulating layer is also referred to as a tunnel insulating layer.

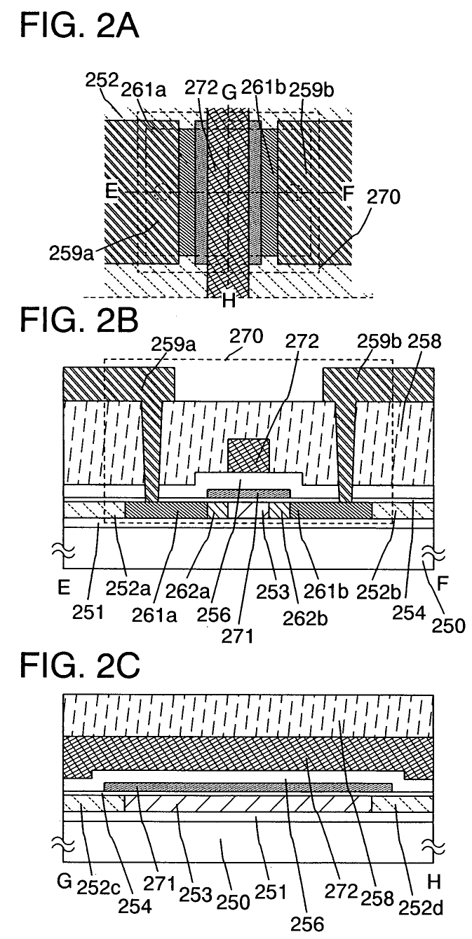

FIGS. 2A to 2C show an example of a semiconductor device of a nonvolatile semiconductor storage device of this embodiment mode. FIG. 2A is a top view, FIG. 2B is a cross-sectional view taken along a line E-F in FIG. 2A, and FIG. 2C is a cross-sectional view taken along a line G-H in FIG. 2A.

Over a substrate 250 over which an insulating layer 251 serving as a base film of a semiconductor layer is formed, a memory element 270 that is a nonvolatile memory element and an interlayer insulating layer 258 are formed. The memory element 270 includes an element region that is made of high concentration impurity regions 261a and 261b, low concentration regions 262a and 262b, and a channel formation region 253, a first insulating layer 254, a charge accumulating layer 271, a second insulating layer 256, a control gate electrode layer 272, and wiring layers 259a and 259b. Element separation regions 252a and 252b are formed to be in contact with the element region (see FIGS. 2A to 2C).

The high concentration impurity regions 261a and 261b and the low concentration impurity regions 262a and 262b include an impurity element imparting n-type conductivity (such as phosphorus (P) or arsenic (As)) as an impurity element imparting one conductivity. The high concentration impurity regions 261a and 261b are regions serving as a source or a drain in a memory element.

In the semiconductor layer, the element region that is made of the high concentration impurity regions 261a and 261b, the low concentration impurity regions 262a and 262b, and the channel formation region 253 is electrically separated from another semiconductor element by element separation regions 252 (252a, 252b, 252c, and 252d) surrounding circumference of the element region.

The element separation region is formed by selective addition of at least one or more kinds of impurity elements of oxygen, nitrogen, and carbon so as to electrically separate the elements in the uninterrupted semiconductor layer. The element separation region to which the impurity element that does not contribute to conductivity becomes to have high resistance because conductivity is reduced due to mixture of the impurity element that does not contribute to conductivity and crystallinity is reduced by physical impact (it can be referred to as so-called sputtering effect) to the semiconductor layer when adding the impurity element. In the element separation region that becomes to have high resistance, the elements can be electrically separated because electron field-effect mobility is also reduced. On the other hand, the region to which the impurity element is not added holds electric field-effect mobility capable of serving as an element because high crystallinity and low resistance are held; therefore, the region to which the impurity element is not added can be used as an element region.

Resistivity of the element separation region is preferably greater than or equal to 1×10¹⁰ Ω·cm, and concentration of the impurity element such as oxygen, nitrogen, or carbon is preferably greater than or equal to 1×10²⁰ cm⁻³ and less than 4×10²² cm⁻³.

It can be said that the element separation region is amorphous because crystallinity is reduced due to addition of the impurity element. On the other hand, the element region is a crystalline semiconductor layer; therefore, in a case of forming a semiconductor element in the element region, crystallinity of a channel formation region thereof is higher than that in the element separation region, and high electron field-effect mobility can be obtained as for a semiconductor element.

As the impurity element added to the element separation region, a rare gas element such as argon (Ar), neon (Ne), krypton (Kr), or xenon (Xe) may be used. When the rare gas element that has comparatively large mass is further added in addition to oxygen, nitrogen, and carbon, physical impact to the semiconductor layer can be increased, and accordingly, crystallinity can be efficiently reduced.

In FIG. 2C, the control gate electrode layer 272 is formed through the first insulating layer 254, the charge accumulating layer 271, and the second insulating layer 256 that extend over the channel formation region 253 and the element separation regions 252c and 252d in the semiconductor layer. In the present invention, the element separation regions and the element region are provided in an uninterrupted semiconductor layer; therefore, the element separation regions 252c and 252d and the element region including the channel formation region 253 are uninterrupted. Accordingly, a surface thereof has high planarity and no steep step.

Since the first insulating layer 254 is formed over the semiconductor layer having high planarity, coverage is favorable and a defective shape is hardly generated. Therefore, defects such as a current leakage and a short in the charge accumulating layer 271 formed over the first insulating layer 254 and the channel formation region 253 can be prevented. Accordingly, the semiconductor device of the nonvolatile semiconductor storage device of this embodiment mode can be a highly reliable semiconductor device in which defects such as a short between the charge accumulating layer and the semiconductor layer and a leakage current due to insufficient coverage of the semiconductor layer with the first insulating layer 254 are prevented.

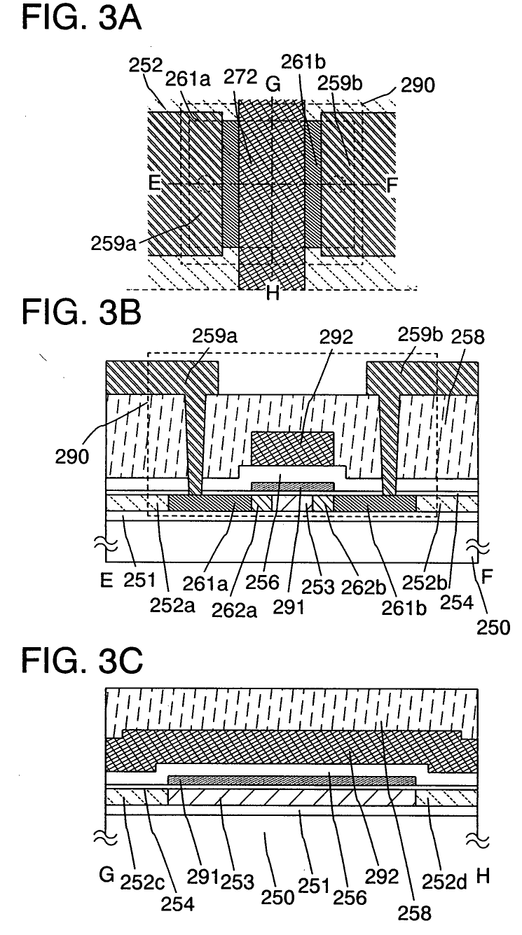

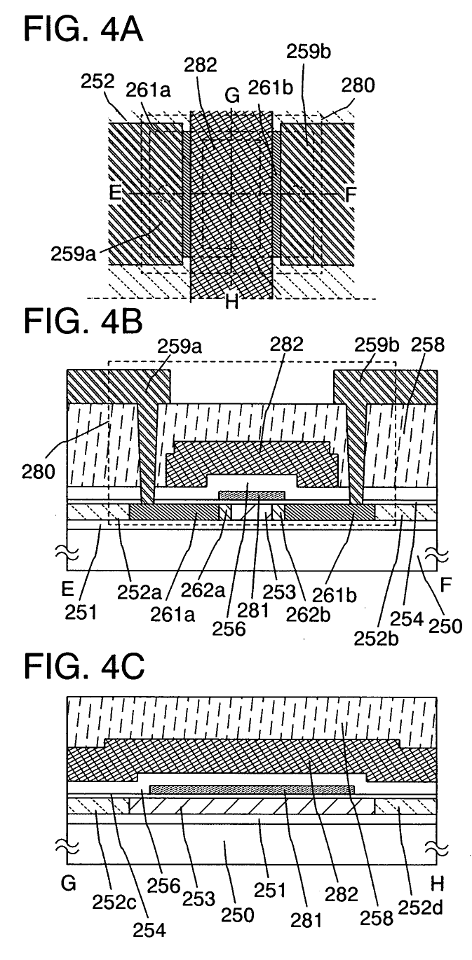

Further, in FIGS. 2A to 2C, an example is shown, in which the element region in the semiconductor layer has a smaller size than the charge accumulating layer 271 in the line G-H direction and the element region has a larger size than the control gate electrode layer 272 in the line E-F direction; however, the present invention is not limited thereto. Other combination examples of sizes of an element region, a charge accumulating layer, and a control gate electrode layer are shown in FIGS. 3A to 3C and FIG. 4A to 4C. It is to be noted that, in FIGS. 3A to 3C and FIGS. 4A to 4C, other factors than a charge accumulating layer and a control gate electrode layer are similar to those of FIGS. 2A to 2C; therefore, the same reference numerals are used for them, and explanation thereof is omitted.

In a memory element 290 of FIGS. 3A to 3C, an element region in a semiconductor layer has approximately the same size as a charge accumulating layer 291 in a line G-H direction, and the element region has a larger size than a control gate electrode layer 292 in a line E-F direction. In FIG. 3B, edge portions of the charge accumulating layer 291 and edge portions of the control gate electrode layer 292 are approximately in alignment through a second insulating layer 256. In FIG. 3C, edge portions of a channel formation region 253 in the element region and edge portions of the charge accumulating layer 291 are approximately in alignment through a first insulating layer 254.

In a memory element 280 of FIGS. 4A to 4C, an element region in a semiconductor layer has a larger size than a charge accumulating layer 281 in a line G-H direction, and the element region has a larger size than a control gate electrode layer 282 in a line E-F direction. Therefore, in FIG. 4B, edge portions of the charge accumulating layer 281 are on an inner side than edge portions of the control gate electrode layer 282 through a second insulating layer 256. In FIG. 4C, edge portions of a channel formation region 253 in the element region is on an outer side than the edge portions of the charge accumulating layer 281 through a first insulating layer 254.

As described above, in accordance with combination of sizes of the element region, the charge accumulating layer, and the control gate electrode layer, capacity that can be accumulated in the second gate insulating layer between the charge accumulating layer and the control gate electrode layer, and capacity that can be accumulated in the first insulating layer 254 between the charge accumulating layer and the semiconductor layer can be controlled; therefore, a voltage value to be applied can be controlled.

As an interlayer insulating layer 258, silicon oxide, silicone nitride, silicon oxynitride, silicon nitride oxide, or the like can be used. In addition, the interlayer insulating layer 258 may be a single layer or have a staked-layer structure having two or three layers. It is to be noted that silicon oxynitride in the present specification indicates a substance in which the content of oxygen is higher than that of nitrogen, and it can also be referred to as silicon oxide containing nitrogen. In the same manner, silicon nitride oxide indicates a substance in which the content of nitrogen is higher than that of oxygen, and it can also be referred to as silicon nitride containing oxygen.

As another material of the interlayer insulating layer 258, a material of aluminum nitride, aluminum oxynitride in which the content of oxygen is higher than that of nitrogen, aluminum nitride oxide or aluminum oxide in which the content of nitrogen is higher than that of oxygen, diamond like carbon (DLC), nitrogen-containing carbon, polysilazane, and other substances containing an inorganic insulating material can be used. A material containing siloxane may also be used. Siloxane corresponds to a material including the Si—O—Si bond. It is to be noted that siloxane includes a skeleton structure formed by the bond of silicon (Si) and oxygen (O). As a substituent thereof, an organic group containing at least hydrogen (for example, an alkyl group or an arly group) is used. Alternatively, a fluoro group may also be used as the substituent. Further, alternatively, a fluoro group and an organic group containing at least hydrogen may also be used as the substituent. Furthermore, an oxazole resin can be used, for example, a photosensitive polybenzoxazole or the like can be used.

The interlayer insulating layer 258 can be formed by a sputtering method, a PVD (Physical Vapor Deposition) method, a low pressure CVD method (LPCVD method), or a CVD (Chemical Vapor Deposition) method such as a plasma CVD method. Alternatively, a droplet discharging method by which a pattern can be selectively formed, a printing method by which a pattern can be transferred or described (a method, such as a screen printing method or an offset printing method, by which a pattern can be formed), or other methods such as a coating method such as a spin coating method, a dipping method, a dispenser method, or the like can also be used.

An etching process for processing the object into a desired shape may employ either plasma etching (dry etching) or wet etching. In a case of processing a large area substrate, plasma etching is suitable. As an etching gas, a fluorine based gas such as CF₄ or NF₃ or a chlorine based gas such as Cl₂ or BCl₃ is used, to which an inert gas such as He or Ar may be appropriately added. When an etching process by atmospheric pressure discharge is employed, local electric discharge can also be realized, which does not require a mask layer to be formed over an entire surface of the substrate.

As the semiconductor layer, one formed from a single crystalline semiconductor or a polycrystalline semiconductor is preferably used. As formation, for example, a semiconductor layer formed by a sputtering method, a plasma CVD method, or a low pressure CVD method over the entire surface of the substrate is crystallized. As a semiconductor material, silicon is preferable, and in addition, a silicon germanium semiconductor can be used. As a crystallization method of the semiconductor layer, a laser crystallization method, a crystallization method by thermal treatment using rapid thermal annealing (RTA) or an annealing furnace, a crystallization method using a metal element promoting crystallization, or a method in which these methods are combined can be adopted.

A p-type impurity may be implanted to the semiconductor layer. As the p-type impurity, for example, boron is used, which may be added at concentration of about 5×10¹⁵ atoms/cm³ to 1×10¹⁶ atoms/cm³. The impurity is used for controlling a threshold voltage of a semiconductor element, and the impurity is added to the channel formation region 253, whereby it operates effectively.

The first insulating layer 254 may be formed from silicon oxide or to have a stacked-layer structure of silicon oxide and silicon nitride. The first insulating layer 254 may be formed by deposition of the insulating layer by a plasma CVD method or a low pressure CVD method; however, the first insulating layer 254 is preferably subjected to solid-phase oxidation or solid-phase nitriding by plasma treatment and be formed. This is because an insulating layer formed using a semiconductor layer (typically, a silicon layer) that is oxidized or nitrided by plasma treatment is dense and has high dielectric voltage and superiority in reliability. The first insulating layer 254 is used as a tunnel insulating layer for injecting charges into the charge accumulating layers 271, 281, and 291; therefore, a strong insulating layer is preferable. This first insulating layer 254 is preferably formed to have a thickness of 1 to 20 nm, more preferably, 3 to 6 nm. For example, in a case of a gate length of 600 nm, the first insulating layer 254 can be formed to have a thickness of 3 to 6 nm.

As solid-phase oxidation treatment or solid-phase nitriding treatment by plasma treatment, plasma excited by a microwave (typically, 2.45 GHz), in which an electron density is greater than or equal to 1×10¹¹ cm⁻³ and less than or equal to 1×10¹³ cm⁻³ and an electron temperature is greater than or equal to 0.5 eV or less than or equal to 1.5 eV, is preferably used. This is because, in the solid-phase oxidation treatment or solid-phase nitriding treatment at a temperature of less than or equal to 500° C., a dense insulating film is formed and a practical response speed is obtained.

In a case where the surface of the semiconductor layer is oxidized by this plasma treatment, the plasma treatment is performed under an oxygen atmosphere. As the oxygen atmosphere, for example, an atmosphere including oxygen (O₂) and a rare gas; an atmosphere including dinitrogen monoxide (N₂O) and a rare gas; an atmosphere including oxygen, hydrogen (H₂), and a rare gas; or an atmosphere including dinitrogen monoxide, hydrogen, and a rare gas is given. As the rare gas, at least one of He, Ne, Ar, Kr, and Xe is included. In a case where the surface of the semiconductor layer is nitrided by the plasma treatment, the plasma treatment is performed under a nitrogen atmosphere. As the nitrogen atmosphere, for example, an atmosphere including nitrogen (N₂) and a rare gas; an atmosphere including nitrogen, hydrogen, and a rare gas; or an atmosphere including MH₃ and a rare gas is given. As the rare gas, at least one of He, Ne, Ar, Kr, and Xe is included. In this embodiment mode, as a rare gas, Ar can be used, for example. Further, a gas in which Ar and Kr are mixed may be used. It is to be noted that the plasma treatment includes oxidation treatment, nitriding treatment, oxynitriding treatment, hydrogenation treatment, and surface modifying treatment to a semiconductor layer, an insulating film, and a conductive layer. When plasma excitation is performed by introduction of the microwave, plasma having a high electron density (greater than or equal to 1×10¹¹ cm⁻³) can be generated at a low electron temperature (less than or equal to 3 eV, preferably, less than or equal to 1.5 eV). By an oxygen radical (there is a case where an OH radical is included) and/or a nitrogen radical (there is a case where a NH radical is included) generated by the high-density plasma, the surface of the semiconductor layer can be oxidized or nitrided. When a rare gas such as argon is mixed into the gas for plasma treatment, an oxygen radical or a nitrogen radical can be efficiently generated in accordance with excited species of the rare gas.

As an example of the favorable first insulating layer 254 formed by plasma treatment in FIGS. 2A to 2C, a silicon oxide layer with a thickness of 3 to 6 nm is formed over the semiconductor layer by plasma treatment under an oxygen atmosphere, and then a surface of the silicon oxide layer is processed by nitrogen plasma under a nitrogen atmosphere to form a nitrogen plasma treatment layer. Specifically, first, a silicon oxide layer with a thickness of 3 to 6 nm is formed over the semiconductor layer by plasma treatment under an oxygen atmosphere. Thereafter, plasma treatment is continuously performed under a nitrogen atmosphere, whereby a nitrogen plasma treatment layer with high nitrogen concentration is provided over a surface of the silicon oxide layer or in the vicinity of the surface. It is to be noted that the vicinity of the surface indicates the depth of about 0.5 to 1.5 nm from a surface of the silicon oxide layer. For example, when plasma treatment is performed under a nitrogen atmosphere, a structure is obtained, in which nitrogen is contained at a ratio of 20 to 50 atom % at the depth of about 1 nm from a surface of the silicon oxide layer.

A surface of a silicon layer as a typical example of the semiconductor layer is oxidized by plasma treatment, whereby a dense oxide layer that has no distortion in an interface can be formed. Further, the oxide layer is nitrided by plasma treatment, whereby, when oxygen in an outer layer is substituted by nitrogen to form a nitride layer, the layer can be further dense. Accordingly, an insulating layer with high dielectric voltage can be formed.

In any cases, when the above solid-phase oxidation treatment or solid-phase nitriding treatment by plasma treatment is used, an insulating layer equivalent to a thermal oxide film that is formed at 950 to 1050° C. can be formed even when a glass substrate with an allowable temperature limit of less than or equal to 700° C. is used. In other words, a highly reliable tunnel insulating layer as a tunnel insulating layer of a nonvolatile memory element can be formed.

The charge accumulating layers 271, 281, and 291 are formed over the insulating layer 254. The charge accumulating layers 271, 281, and 291 may have a single layer or a stacked layer of plural layers.

As a semiconductor material for forming the charge accumulating layers 271, 281, and 291, silicon, a silicon compound, germanium, or a germanium compound can be typically used. As the silicon compound, silicon nitride, silicon nitride oxide, silicon carbide, silicon germanium containing germanium at concentration of greater than or equal to 10 atom %, metal nitride, metal oxide, or the like can be applied. As a typical example of the germanium compound, silicon germanium is given, in which germanium of greater than or equal to 10 atom % to the silicon is preferably contained.

A charge accumulating layer serving as a floating gate is applied to a nonvolatile semiconductor storage device relating to the present invention, which is intended to accumulate charges. However, another material can be applied as long as it has the similar function. For example, a ternary semiconductor containing germanium may be used. Further, the semiconductor material may be hydrogenated. As one having a function as a charge accumulating layer of a nonvolatile memory element, the charge accumulating layer can be replaced with an oxide of the germanium or the germanium compound or a nitride of the germanium or the germanium compound.

Further, metal nitride or metal oxide can be used for forming the charge accumulating layers 271, 281, and 291. As metal nitride, tantalum nitride, tungsten nitride, molybdenum nitride, titanium nitride, or the like can be used. As metal oxide, tantalum oxide, titanium oxide, tin oxide, or the like can be used.

Furthermore, the charge accumulating layers 271, 281, and 291 may be formed of a stacked-layer structure of the above materials. When a layer of the above silicon or silicon compound or a layer of the metal nitride or metal oxide is provided on an upper layer side of a layer formed from germanium or a germanium compound, the layer can be used as a barrier layer for the purpose of water resistance or chemical resistance during a manufacturing process. Accordingly, a substrate in a photolithography step, an etching step, and a washing step can be handled easily, and productivity can be improved. In other words, the charge accumulating layer can be easily processed.

The second insulating layer 256 is formed by a low pressure CVD method, a plasma CVD method, or the like to have one layer or plural layers of a silicon oxide film, a silicon oxynitride (SiO_{X}N_{Y}) (x>y>0) film, a silicon nitride (SiNx) or silicon nitride oxide (SiN_{X}O_{Y}) (x>y>0) film, or the like. Alternatively, the second insulating layer 256 may be formed using aluminum oxide (AlOx), hafnium oxide (HfOx), or tantalum oxide (TaOx). The second insulating layer 256 is formed to have a thickness of 1 to 20 nm, preferably, 5 to 10 nm. For example, the insulating layer in which a silicon nitride layer is deposited to have a thickness of 3 nm and a silicon oxide layer is deposited to have a thickness of 5 nm can be used. Further, each surface of the charge accumulating layers 271, 281, and 291 may be subjected to plasma treatment to form a nitride film over the surface of the charge accumulating layers where nitriding treatment is performed (for example, silicon nitride in a case of using silicon as the charge accumulating layers 271, 281, and 291). In any cases, one of or both the first insulating layer 254 and the second insulating layer 256 on the side in contact with the charge accumulating layers 271, 281, and 291 are to be a nitride film, whereby oxidization of the charge accumulating layers 271, 281, and 291 can be prevented.

The control gate electrode layers 272, 282, and 292 are preferably formed from a metal selected from tantalum (Ta), tungsten (W), titanium (TI), molybdenum (Mo), chromium (Cr), niobium (Nb), or the like, or an alloy material or a compound material containing the metal as its main component. Alternatively, polycrystalline silicon to which an impurity element such as phosphorus is added can be used. Further, the control gate electrode layers 272, 282, and 292 may be formed to have one layer or a stacked-layer structure of plural metal nitride layers and the above metal layer. As the metal nitride, tungsten nitride, molybdenum nitride, or titanium nitride can be used. When a metal nitride layer is provided, adhesiveness of the metal layer can be improved, and peeling can be provided. Further, metal nitride such as tantalum nitride has high work function; therefore, a thickness of the first insulating layer 254 can be increased by the synergistic effect with the second insulating layer 256.

The wiring layers 259a and 259b can be formed from a material selected from indium tin oxide (ITO), indium zinc oxide (IZO) in which zinc oxide (ZnO) is mixed with indium oxide, a conductive material in which silicon oxide (SiO₂) is mixed with indium oxide, organoindium, organotin, indium oxide containing tungsten oxide, indium zinc oxide containing tungsten oxide, indium oxide containing titanium oxide, or indium tin oxide containing titanium oxide; a metal such as tungsten (W), molybdenum (Mo), zirconium (Zr), hafnium (Hf), vanadium (V), niobium (Nb), tantalum (Ta), chromium (Cr), cobalt (Co), nickel (Ni), titanium (Ti), platinum (Pt), aluminum (Al), copper (Cu) or silver (Ag); an alloy of such metals; or metal nitride thereof.

Electrons are injected into the charge accumulating layer by a method using hot electrons or a method using a F-N type tunnel current. In a case of utilizing hot electrons, a positive voltage is applied to the control gate electrode layer, and a high voltage is applied to a drain to generate hot electrons. Accordingly, hot electron can be injected into the charge accumulating layer. In a case of utilizing an F-N type tunnel current, a positive voltage is applied to the control gate electrode layer, and electrons are injected to the charge accumulating layer from the semiconductor layer by the F-N type tunnel current.

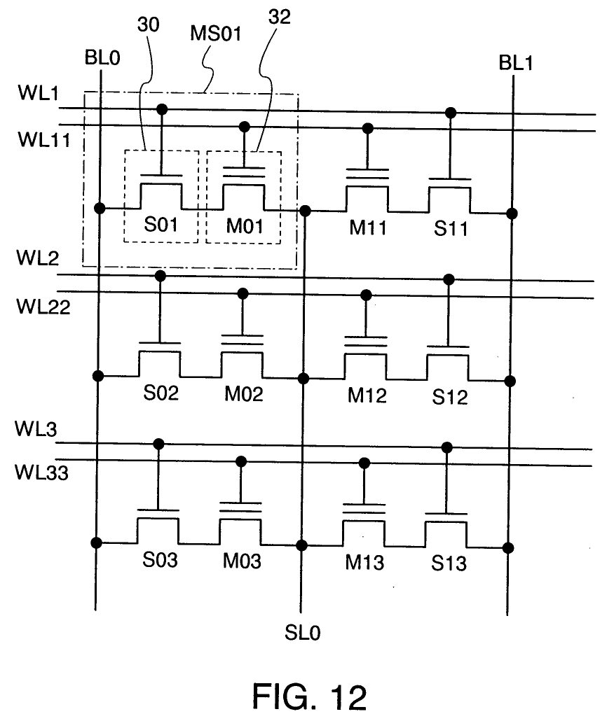

As an example of a semiconductor device with the use of the present invention, various types of nonvolatile semiconductor storage devices with a nonvolatile memory element can be obtained. FIG. 12 shows an example of an equivalent circuit of a nonvolatile memory cell array. A memory cell MS01 storing information of 1 bit includes a selection transistor S01 and a nonvolatile memory element M01. The selection transistor S01 is inserted between a bit line BL0 and the nonvolatile memory element M01 in series, and a gate thereof is connected to a word line WL1. A gate of the nonvolatile memory element M01 is connected to a word line WL11. When data is written to the nonvolatile memory element M01, a high voltage is applied to the word line WL11 under the condition that an H level is applied to the word line WL1 and the bit line BL0 and a L level is applied to a bit line BL1. As a result, charges are accumulated in the charge accumulating layer as described above. When the data is erased, a high voltage of negative polarity is applied to the word line WL11 under the condition that an H level is applied to the word line WL1 and the bit line BL0.

In this memory cell MS01, the selection transistor S01 and the nonvolatile memory element M01 are respectively formed using element regions 30 and 32 each of which is separately formed by element separation regions to which an impurity element is added in a semiconductor layer uninterruptedly formed over an insulating surface, whereby interference from other selection transistors or nonvolatile memory elements can be prevented. Further, both the selection transistor S01 and the nonvolatile memory element M01 in the memory cell MS01 are n-channel type. Therefore, both the selection transistor S01 and the nonvolatile memory element M01 are formed in one element region, whereby a wiring for connecting these two elements can be omitted.

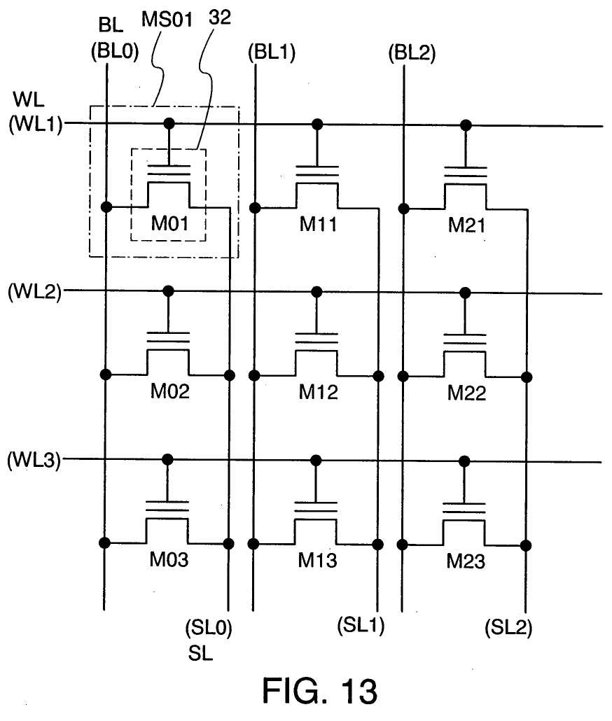

FIG. 13 shows a NOR-type equivalent circuit in which a nonvolatile memory element is directly connected to a bit line. A memory cell array is provided so that a word line WL and a bit line BL are intersected with each other, and nonvolatile memory elements are arranged in each intersection point. In the NOR type, a drain of each nonvolatile memory element is connected to the bit line BL. A source of each nonvolatile memory element is connected to a source line SL in common.

Also, in this case, in a memory cell MS01, a nonvolatile memory element M01 is formed using an element region 32 that is separately formed by element separation regions to which an impurity element is added in a semiconductor layer uninterruptedly formed over an insulating surface, whereby interference from other nonvolatile memory elements can be prevented without separating a semiconductor layer into island shapes, specifically. Further, a plurality of nonvolatile memory elements (for example, nonvolatile memory elements M01 to M23 shown in FIG. 13) are recognized as one block, and these nonvolatile memory elements are formed using element regions that are separately formed by element separation regions to which an impurity element is added in a semiconductor layer uninterruptedly formed over an insulating surface, whereby erasing operation can be performed by block units.

The NOR type operates, for example, as follows. When data is written, a high voltage is applied to a word line WL that is selected for writing data under the condition that the source line SL is set to be 0V, and potential corresponding to data “0” and data “1” is applied to the bit line BL. For example, potential of an H level and a L level with respect to “0” and “1” are each given to the bit line BL. In the nonvolatile memory element to which an H level is applied in order to write “0” data, hot electrons are generated in the vicinity of the drain, and the hot electrons are injected to the charge accumulating layer. In the case of “1” data, such an electron injection is not generated.

In the memory cell given “0” data, hot electrons are generated in the vicinity of the drain by a strong electric field in a horizontal direction between the drain and the source, and the hot electrons are injected to the charge accumulating layer. From this, a state in which a threshold voltage becomes high by injection of the electrons to the charge accumulating layer is “0”. In the case of “1” data, hot electrons are not generated, and a state in which a threshold voltage is low without injection of the electrons to the charge accumulating layer, that is, an erasing state, is held.

When data is erased, a positive voltage of about 10 V is applied to the source line SL, and the bit line BL is kept to be a floating state. Then, a high voltage of negative polarity is applied to the word line (a high voltage of negative polarity is applied to the control gate), and electrons are drawn from the charge accumulating layer. From this, an erasing state of data “1” is obtained.

Reading data is performed as follows: the source line SL is set to be 0 V, and the bit line BL is set to be about 0.8 V; a reading voltage that is set to be an intermediate value of a threshold value of data “0” and “1” is applied to the selected word line WL; and whether or not the current draw of the nonvolatile memory element exists is determined by a sense amplifier connected to the bit line BL.

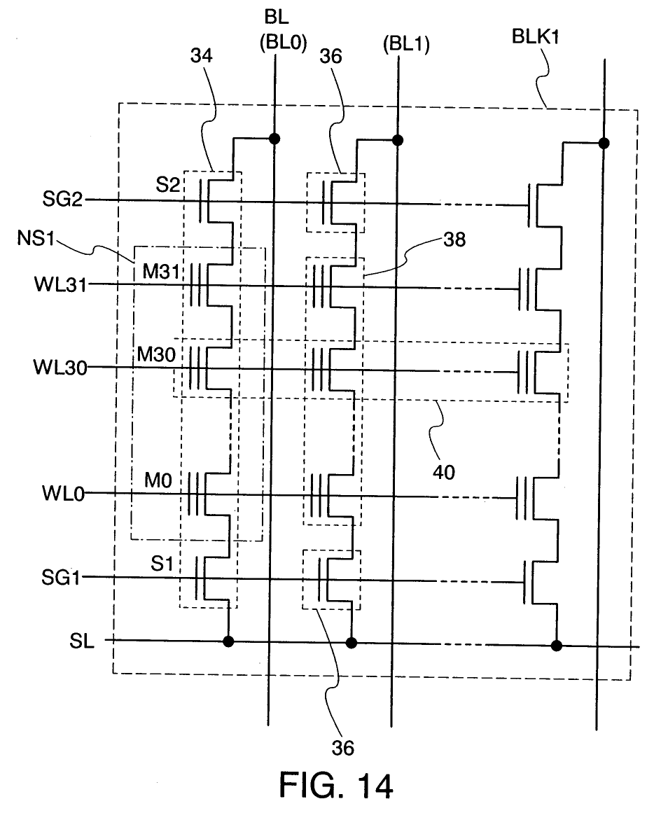

FIG. 14 shows an equivalent circuit of a NAND-type memory cell array. A NAND cell NS1 in which a plurality of nonvolatile memory elements are connected in series is connected to a bit line BL A block BLK includes a plurality of NAND cells. There are 32 word lines (word lines WL0 to WL31) of a block BLK1 shown in FIG. 14. Nonvolatile memory elements positioned in the same row of the block BLK1 are connected to word lines corresponding to this row in common.

In this case, selection transistors S i and S2 and nonvolatile memory elements M0 to M31 are connected in series. These selection transistors and the nonvolatile memory elements may be recognized as one unit and formed using one semiconductor layer 34 in common. Accordingly, a wiring for connecting the nonvolatile memory elements can be omitted, and integration can be attempted. Further, separation from an adjacent NAND cell can be easily performed. Semiconductor layers 36 of the selection transistors S1 and S2 and a semiconductor layer 38 of the NAND cell may be separately formed. When erasing operation in which charges are drawn from a charge accumulating layer of the nonvolatile memory elements M0 to M31 is performed, the erasing operation can be performed by a unit of the NAND cell. Further, nonvolatile memory elements connected to one word line (for example, nonvolatile memory elements in a row of M30) in common may be formed using one semiconductor layer 40.

Writing operation is implemented after the NAND cell NS1 is in an erasing state, that is, a threshold value of each nonvolatile memory element of the NAND cell NS1 is in a negative voltage state. Writing is sequentially performed from the memory element M0 on a source line SL side. In a case where writing to the memory element M0 is explained as an example, the outline of writing operation is shown as below.

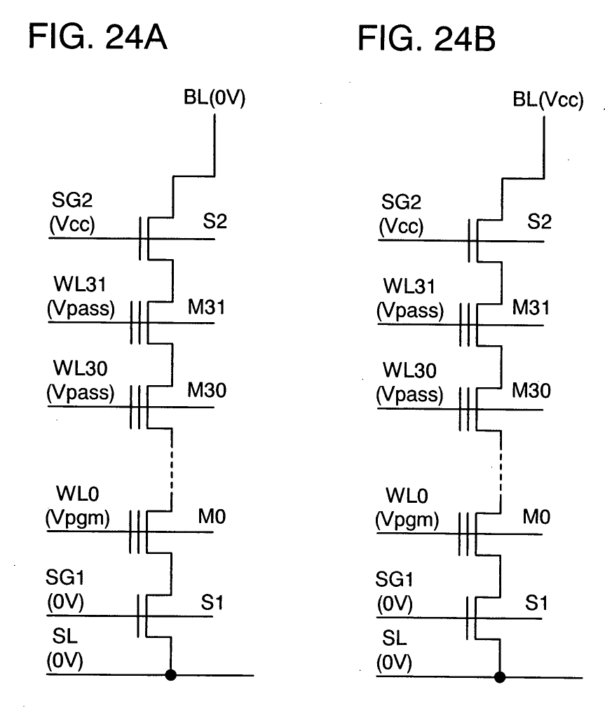

In FIG. 24A, when “0” writing is conducted, Vcc (a power supply voltage), for example, is applied to a selection gate line SG2 to turn on a selection transistor S2, and concurrently, a bit line BL0 is set to be in 0 V (a grand voltage). A selection gate line SG1 is set to be in 0 V, and the selection transistor S1 is turned off. Next, a high voltage Vpgm (about 20 V) is applied to a word line WL0 of a memory cell MS0, and an intermediate voltage Vpass (about 10 V) are applied to other word lines. Since a voltage of the bit line BL is 0 V, potential of a channel formation region of the selected memory cell MS0 becomes 0 V. A potential difference between the word line WL0 and the channel formation region is large, and therefore, electrons are injected to a charge accumulating layer of the memory cell MS0 by F-N tunnel current as described above. From this, a threshold voltage of the memory cell MS0 becomes a positive state (a state in which “0” is written).

On the other hand, when “1” writing is conducted, Vcc (a power supply voltage), for example, is applied to a bit line BL as shown in FIG. 24B. Since a voltage of a selection gate line SG2 is Vcc, when the voltage becomes Vcc minus Vth (Vcc−Vth) with respect to a threshold voltage Vth of a selection transistor S2, the selection transistor S2 is cut off. Accordingly, a channel formation region of a memory cell MS0 becomes in a floating state. Next, when a high voltage Vpgm (20 V) is applied to a word line WL0 and an intermediate voltage Vpass (10 V) is applied to other word lines, a voltage of the channel formation region is increased from Vcc−Vth to, for example, about 8 V by capacity coupling of each word line and channel formation region. Since the voltage of the channel formation region is boosted to the high voltage, a potential difference between the word line WL0 and the channel formation region is small, which is different from the case of the “0” writing. Accordingly, electron injection by F-N tunnel current is not generated in the charge accumulating layer of the memory cell MS0. Therefore, a threshold value of a memory cell MC1 is kept in a negative state (a state in which “1” is written).

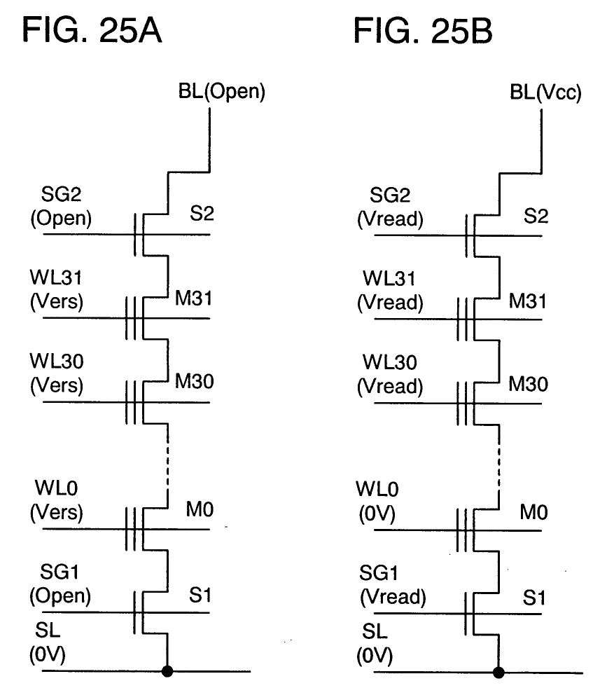

When erasing operation is conducted, a high voltage of negative polarity (Vers) is applied to all word lines in a selected block as shown in FIG. 25A. A bit line BL and a source line SL are to be in a floating state. From this, electrons in a charge accumulating layer in all memory cells of the block are discharged to a semiconductor layer by a tunnel current. As a result, a threshold voltage of these memory cells is shifted to a negative direction.

In reading operation shown in FIG. 25B, a voltage Vr (for example, 0V) is applied to a word line WL0 of a memory cell MS0 in which reading is selected, and an intermediate voltage Vread for reading is applied to word lines WL1 to WL31 of non-selected memory cells and selection gate lines SG1 and SG2, which is a little higher than a power supply voltage. In other words, the memory elements other than the select memory element serve as a transfer transistor as shown in FIG. 13. From this, whether or not a current flows in the memory cell MS0 in which reading is selected is detected. That is, in a case where data stored in the memory cell MS0 is “0”, the memory cell MS0 is turned off, and a bit line BL does not discharge. On the other hand, in a case where data is “1”, the memory cell MS0 is turned on, and the bit line BL discharges.

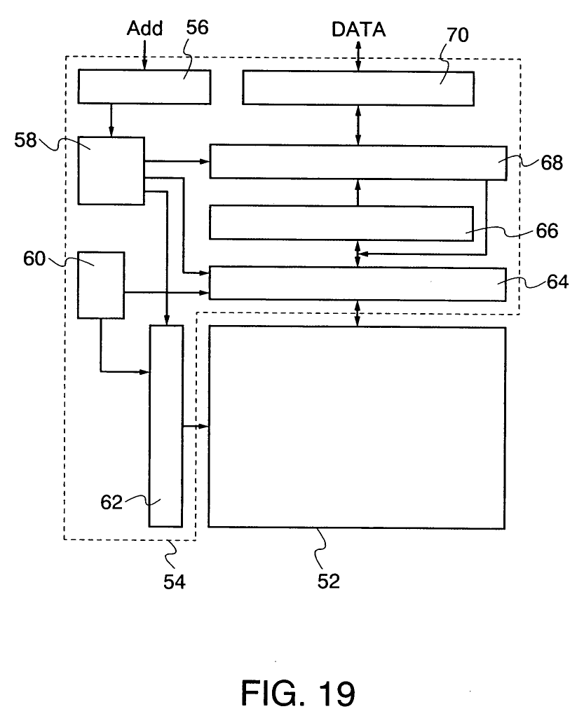

FIG. 19 shows an example of a circuit block diagram of a nonvolatile semiconductor storage device. In the nonvolatile semiconductor storage device, a memory cell array 52 and a peripheral circuit 54 are formed over a same substrate. The memory cell array 52 has a structure as shown in FIG. 12, FIG. 13, or FIG. 14. The peripheral circuit 54 has a structure described as below.

A row decoder 62 for selecting a word line and a column decoder 64 for selecting a bit line are provided on the periphery of the memory cell array 52. An address is transferred to a control circuit 58 through an address buffer 56, and an internal row address signal and an internal column address signal are respectively transferred to the row decoder 62 and the column decoder 64.

For writing and erasing data, potential that boosts a power supply voltage is used. Therefore, a boosting circuit 60 that is controlled corresponding to an operation mode by the control circuit 58 is provided. Output of the boosting circuit 60 is supplied to a word line WL or a bit line BL through the row decoder 62 and the column decoder 64. In a sense amplifier 66, data that is output from the column decoder 64 is input. Data that is read by the sense amplifier 66 is held in a data buffer 68, accessed at random by control from the control circuit 58, and output through a data input/output buffer 70. Writing data is once held in the data buffer 68 through the data input/output buffer 70 and transferred to the column decoder 64 by control of the control circuit 58.

As described above, in the memory cell array 52 of the nonvolatile semiconductor storage device, potential that is different from power supply potential is necessary to be used. Therefore, it is desirable that at least an interval between the memory cell array 52 and the peripheral circuit 54 be electrically insulated.

Therefore, with the use of the present invention, separation into a plurality of element regions can be performed without division of a semiconductor layer into island shapes. A step is not generated in an edge portion of the semiconductor layer, and an insulating layer is formed over the plane semiconductor layer. As a result, coverage of the semiconductor with the insulating layer is improved. Accordingly, a highly reliable nonvolatile semiconductor storage device in which defects such as a short between a charge accumulating layer, a control gate electrode layer, and a semiconductor layer and a leakage current due to insufficient coverage of the semiconductor with the insulating layer are prevented, and a manufacturing method of such a semiconductor device can be provided. Thus, further miniaturization and high integration can be performed in the semiconductor device, and high efficiency of the semiconductor device can be achieved. In addition, a defect due to a defective shape of such a film can be reduced; therefore, production can be performed with high yield in the manufacturing process.

### Embodiment Mode 3

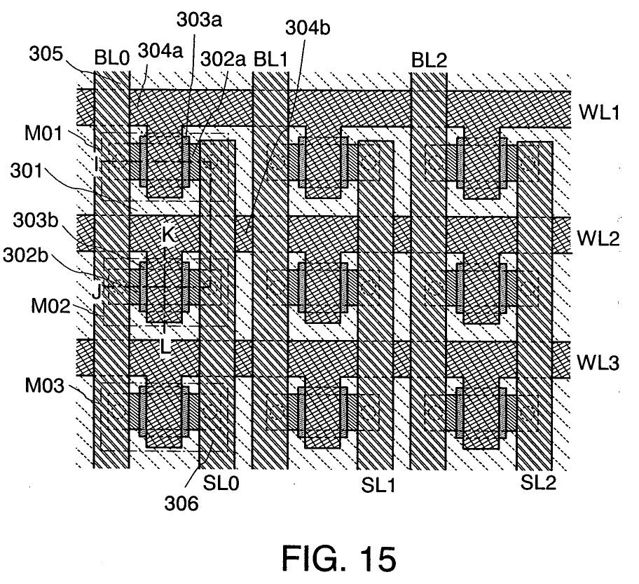

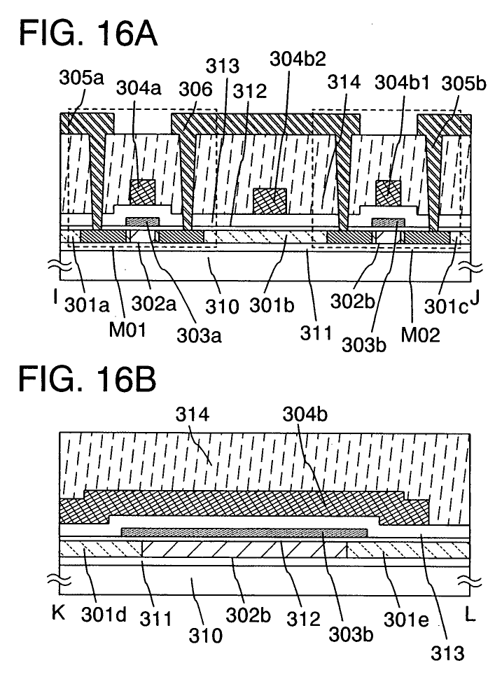

In this embodiment mode, an example of a semiconductor device will be explained with reference to drawings, which has a memory element (also referred to as a storage element) intended to prevent defects such as a short between a gate electrode layer and a semiconductor layer and a leakage current due to insufficient coverage of the semiconductor layer with an insulating layer in a semiconductor element and to give higher reliability. FIG. 15 shows a top view of a semiconductor device of this embodiment mode, FIG. 16A shows a cross-sectional view taken along a line I-L in FIG. 15, and FIG. 16B shows a cross-sectional view taken along a line K-L in FIG. 15.

FIG. 15 shows a NOR-type equivalent circuit in which nonvolatile memory elements M (M01, M02, and M03) are connected to bit lines BL (BL0, BL1, and BL2). As this memory cell array, word lines WL (WL1, WL2, and WL3) and bit lines BL (BL0, BL1, and BL2) are arranged so as to intersect with each other, and the nonvolatile memory elements (M01, M02, and M03) are arranged at each intersection portion. In the NOR type, a drain of each nonvolatile memory element (such as M01, M02, or M03) is connected to the bit line BL (such as BL0, BL1, or BL2). A source of each nonvolatile memory element is connected to the source line SL (such as SL0, SL1, or SL2) in common.

In FIG. 15, each drain of the memory elements M01, M02, and M03 is connected to a bit line BL 0305 (305a and 305b), and each source thereof is connected to a source line SL 0306. The memory element M01 includes an element region 302a, a charge accumulating layer 303a, and a control gate electrode layer 304a. The memory element M02 includes an element region 302b, a charge accumulating layer 303b, and a control gate electrode layer 304b. A first insulating layer 312, a second insulating layer 313, and an interlayer insulating layer are uninterruptedly formed in the memory element M01 and the memory element M02. The element region 302a and the element region 302b each have a high concentration n-type impurity region and a low concentration impurity region serving as a source or a drain.

In a semiconductor layer, the element region 302a included in the memory element M01 and the element region 302b included in the memory element M02 are electrically separated by element separation regions 301 (301a, 301b, 301c, 301d, and 301e).

In the uninterrupted semiconductor layer, in order to electrically separate elements, the element separation regions are formed by selective addition of at least one or more kinds of impurity elements of oxygen, nitrogen, and carbon. The element separation region to which the impurity element that does not contribute to conductivity is added becomes to have high resistance because conductivity is reduced due to mixture of the impurity element that does not contribute to conductivity and crystallinity is reduced due to physical impact (it can be also referred to as so-called sputtering effect) to the semiconductor layer when adding the impurity element. In the element separation region that becomes to have high resistance, the elements can be electrically separated because electron field-effect mobility is also reduced. On the other hand, the region to which the impurity element is not added holds electric field-effect mobility capable of serving as an element because high crystallinity and low resistance are held; therefore, the region to which the impurity element is not added can be used as an element region.

Resistivity of the element separation region is preferably greater than or equal to 1×10¹⁰ Ω·cm, and concentration of the impurity element such as oxygen, nitrogen, or carbon is preferably greater than or equal to 1×10²⁰ cm⁻³ and less than 4×10²² cm⁻³.

It can be said that the element separation region is amorphous because crystallinity is reduced due to addition of the impurity element. On the other hand, the element region is a crystalline semiconductor layer; therefore, in a case of forming a semiconductor element in the element region, crystallinity of a channel formation region thereof is higher than that in the element separation region, and high electron field-effect mobility can be obtained as for a semiconductor element.

As the impurity element added to the element separation region, a rare gas element such as argon (Ar), neon (Ne), krypton (Kr), or xenon (Xe) may be used. When the rare gas element that has comparatively large mass is further added in addition to oxygen, nitrogen, and carbon, physical impact to the semiconductor layer can be increased, and accordingly, crystallinity can be efficiently reduced.

In FIG. 16B, the charge accumulating layer 303b is formed through the first insulating layer 312 that extends over the element region 302b and the element separation regions 301d and 301e in the semiconductor layer. In the present invention, the element separation regions and the element region are provided in an uninterrupted semiconductor layer; therefore, the element separation regions 301d and 301e and the element region 302b are uninterrupted. Accordingly, a surface thereof has high planarity and no steep step.

Since the first insulating layer 312 is formed over the semiconductor layer having high planarity, coverage is favorable and a defective shape is hardly generated. Therefore, defects such as a current leakage and a short between the charge accumulating layers 303a and 303b formed over the first insulating layer 312 and the element regions 302a and 302b can be prevented. Accordingly, the semiconductor device of the nonvolatile semiconductor storage device of this embodiment mode can be a highly reliable semiconductor device in which defects such as a short between the charge accumulating layer and the semiconductor layer and a leakage current due to insufficient coverage the semiconductor layer with of the first insulating layer 312 are prevented.

This embodiment mode can be implemented by being combined with another embodiment mode shown in the present specification.

Therefore, with the use of the present invention, separation into a plurality of element regions can be performed without division of a semiconductor layer into island shapes. A step is not generated in an edge portion of the semiconductor layer, and an insulating layer is formed over the plane semiconductor layer. As a result, coverage of the semiconductor layer with the insulating layer is improved. Accordingly, a semiconductor device of a highly reliable nonvolatile semiconductor storage device in which defects such as a short between a charge accumulating layer, a control gate electrode layer, a gate electrode layer, and a semiconductor layer and a leakage current due to insufficient coverage of the semiconductor layer with the insulating layer are prevented, and a manufacturing method of such a semiconductor device can be provided. Thus, further miniaturization and high integration can be performed in the semiconductor device, and high efficiency of the semiconductor device can be achieved. In addition, a defect due to a defective shape of such a film can be reduced; therefore, production can be performed with high yield in the manufacturing process.

### Embodiment Mode 4

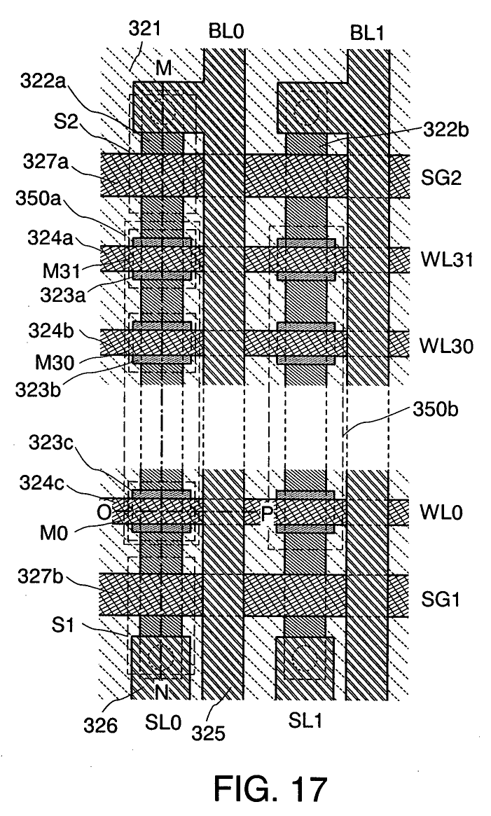

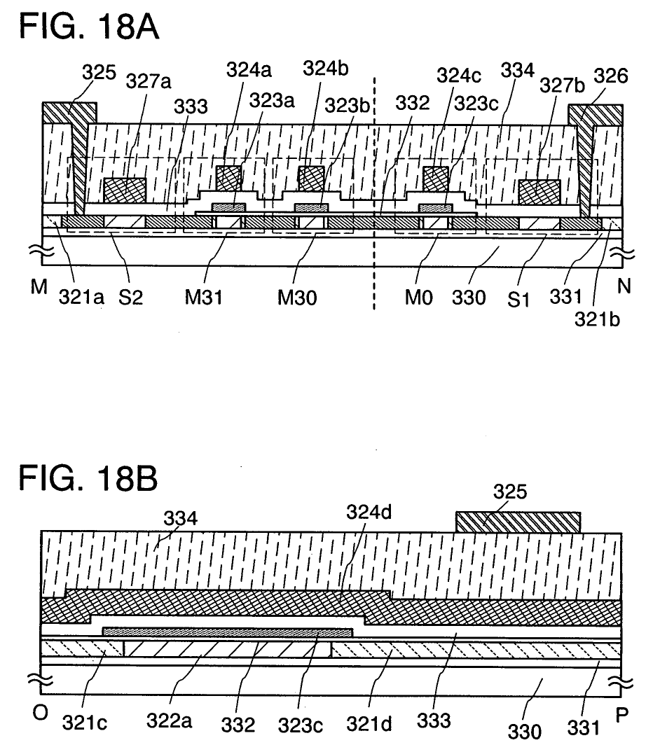

In this embodiment mode, an example of a semiconductor device will be explained with reference to drawings, which has a memory element (also referred to as a storage element) intended to prevent defects such as a short between a gate electrode layer and a semiconductor layer and a current leakage due to insufficient covereage of the semiconductor layer with an insulating layer in a semiconductor element and to give higher reliability. FIG. 17 shows a top view of a semiconductor device of this embodiment mode, FIG. 18A shows a cross-sectional view taken along a line M-N in FIG. 17, and FIG. 18B shows a cross-sectional view taken along a line O-P in FIG. 17.

In this embodiement mode, a case in which a plurality of nonvolatile memory elements are provided in one element region in the structure shown in Embodiment Mode 2 will be explained with reference to drawings. It is to be noted that, when the same portios as those in the above embodiment mode are indicated, the explanation thereof is omitted.

In the semiconductor device shown in this embodiment mode, element regions 322a and 322b are provided in a semiconductor layer, which are electrically connected to bit lines BL0 and BL1, respectively, are provided, and the element regions 322a and 322b each include a plurality of nonvolatile memory elements (see FIG. 17 and FIG. 18A). Specifically, in the element region 322a, a NAND cell 350a including a plurality of nonvolatile memory elements M0 to M31 is provided between selection transistors S1 and S2. Also, in the element region 322b, a NAND cell 350b including a plurality of nonvolatile memory elements is provided between the selection transistors. In addition, an element separation region 321 is provided between the element regions 322a and 322b, whereby the NAND cell 350a and the NAND cell 350b, which are near to each other, can be insulated.

In addition, by a plurality of nonvolatile semiconductor elements being provided in one element region, integration of the nonvolatile memory elements can be further achieved, and a large-capacity nonvolatile semiconductor storage device can be formed.

In FIG. 17 and FIGS. 18A and 18B, the selection transistors S1 and S2 and the memory elements M0, M30, and M31 are provided over a substrate 330 over which an insulating layer 331 is provided. Gate electrode layers (SG1 and SG2) 327a and 327b are respectively included in the selection transistors S1 and S2. Charge accumulating layers 323a, and 323b, and 323c and control gate electrode layers (WL31, WL30, and WL0) 324a, 324b, and 324c are respectively included in the memory elements M31, M30, and M0. A first insulating layer 332, a second insulating layer 333, and an interlayer insulating layer 334 are included in the selection transistors S1 and S2 and the memory elements M31, M30, and M0 in common. The selection transistor S1 is connected to the bit line BL0, and the selection transistor S2 is connected to a SL 0326.

In a semiconductor layer, the element region 322a included in the NAND cell 350a and the element region 322b included in the NAND cell 350b are electrically separated by element separation regions 321 (321a, 321b, 321c, and 321d).

In the uninterrupted semiconductor layer, in order to electrically separate elements, the element separation regions are formed by selective addition of at least one or more kinds of impurity elements of oxygen, nitrogen, and carbon. The element separation region to which the impurity element that does not contribute to conductivity is added becomes to have high resistance because conductivity is reduced due to mixture of the impurity element that does not contribute to conductivity and crystallinity is reduced due to physical impact (it can be also referred to as so-called sputtering effect) to the semiconductor layer when adding the impurity element. In the element separation region that becomes to have high resistance, the elements can be electrically separated because electron field-effect mobility is also reduced. On the other hand, the region to which the impurity element is not added holds electric field-effect mobility capable of serving as an element because high crystallinity and low resistance are held; therefore, the region to which the impurity element is not added can be used as an element region.

Resistivity of the element separation region is preferably greater than or equal to 1×10¹⁰ Ω·cm, and concentration of the impurity element such as oxygen, nitrogen, or carbon is preferably greater than or equal to 1×10²⁰ cm⁻³ and less than 4×10²² cm⁻³.

It can be said that the element separation region is amorphous because crystallinity is reduced due to addition of the impurity element. On the other hand, the element region is a crystalline semiconductor layer; therefore, in a case of forming a semiconductor element in the element region, crystallinity of a channel formation region thereof is higher than that in the element separation region, and high electron field-effect mobility can be obtained as for a semiconductor element.

As the impurity element added to the element separation region, a rare gas element such as argon (Ar), neon (Ne), krypton (Kr), or xenon (Xe) may be used. When the rare gas element that has comparatively large mass is further added in addition to oxygen, nitrogen, and carbon, physical impact to the semiconductor layer can be increased, and accordingly, crystallinity can be efficiently reduced.

In FIG. 18C, the charge accumulating layer 323c is formed through the first insulating layer 332 that extends over the element region 322a and the element separation regions 321c and 321d in the semiconductor layer. In the present invention, the element separation regions and the element region are provided in an uninterrupted semiconductor layer; therefore, the element separation regions 321c and 321d and the element region 322a are uninterrupted. Accordingly, a surface thereof has high planarity and no steep step.

Since the first insulating layer 322 is formed over the semiconductor layer having high planarity, coverage is favorable and a defective shape is hardly generated. Therefore, defects such as a current leakage and a short between the charge accumulating layers 323a, 323b, and 323c formed over the first insulating layer 322 and the element region 322a can be prevented. Accordingly, the semiconductor device of the nonvolatile semiconductor storage device of this embodiment mode can be a highly reliable semiconductor device in which defects such as a short between the charge accumulating layer and the semiconductor layer and a leakage current due to insufficient coverage of the semiconductor layer with the first insulating layer 322 are prevented.

This embodiment mode can be implemented by being combined with another embodiment mode shown in the present specification.

Therefore, with the use of the present invention, separation into a plurality of element regions can be performed without division of a semiconductor layer into island shapes. A step is not generated in an edge portion of the semiconductor layer, and an insulating layer is formed over the plane semiconductor layer. As a result, coverage of the semiconductor layer with the insulating layer is improved. Accordingly, a semiconductor device of a highly reliable nonvolatile semiconductor storage device in which defects such as a short between a charge accumulating layer, a control gate electrode layer, a gate electrode layer, and a semiconductor layer and a leakage current due to insufficient coverage of the semiconductor layer with the insulating layer are prevented, and a manufacturing method of such a semiconductor device can be provided. Thus, further miniaturization and high integration can be performed in the semiconductor device, and high efficiency of the semiconductor device can be achieved. In addition, a defect due to a defective shape of such a film can be reduced; therefore, production can be performed with high yield in the manufacturing process.

### Embodiment Mode 5

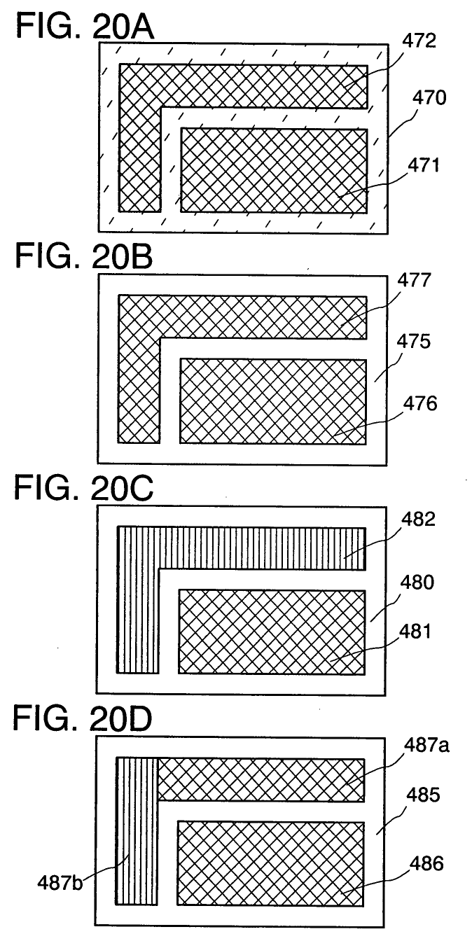

In this embodiment mode, an example of a nonvolatile semiconductor storage device as a semiconductor device to which the present invention is applied will be explained. In the present invention, plural semiconductor elements are manufactured in an uninterrupted semiconductor layer that is not divided into insland shapes. The present invention may be applied to all semiconductoe elements provided in the semiconductor device or to the semiconductor device partially. The present invention may be appropriately applied depending on a function that is required for the semiconductor element. An example of such a semiconductor device to which the present invention invention is applied will be explained with reference to FIGS. 20A to 20D.

FIGS. 20A to 20D are top views of a semiconductor device of the present invention, each of which is simply represented by a substrate and a peripheral circuit portion and a memory element portion that are formed over the substrate. In each semiconductor device of this embodiment mode shown in FIGS. 20A to 20D, a memory element portion and a peripheral circuit portion are formed over the same substrate. In FIG. 20A, a peripheral circuit portion 472 and a memory element portion 471 are provided over a substrate 470, and a semiconductor layer is formed over an entire surface of the substrate 470. Over the substrate 470, the semiconductor layer of the peripheral circuit portion 472 and the memory element portion 471 is separated into an element region and an element separation region that is formed by addition of an impurity element that does not contribute to conductivity, to which the present invention is applied. Thus, a plurality of semiconductor elements are formed in the semiconductor layer. The semiconductor layer in a region formed over the substrate 470, which is other than the peripheral circuit portion 472 and the memory element portion 471 may be to be a high resistance region by addition of an impurity element that does not contribute to conductivity as similar to the element separation region in the peripheral circuit portion 472 and the memory element portion 471.

FIG. 20B shows an example in which a semiconductor layer is not provided over an entire surface of a substrate 475, and a semiconductor layer provided in a region other than a peripheral circuit portion 477 and a memory element portion 476 over the substrate 475 is removed by etching or the like. The peripheral circuit portion 477 and the memory element portion 476 in FIG. 20B have a structure in which a plurality of semiconductor elements are formed in an uninterrupted semiconductor layer by an element separation region of a high resistance region to which an impurity element that does not contribute to conductivity is added, similarly to the peripheral circuit portion 472 and the memory element portion 471. A semiconductor layer in a region where the semiconductor element is not formed over the substrate as FIG. 20B may be a high resistance region or be removed. An element separation method of the present invention may be applied to a region where a plurality of semiconductor elements are near to each other and minute separation treatment is needed for the semiconductor layer, and the semiconductor layer in a region where intervals between the elements are comparatively large or the elements are not formed may be removed.

FIG. 20C shows an example in which a different element separation method is applied to semiconductor elements provided over a substrate 480 depending on a required function and size. In FIG. 20C, a peripheral circuit portion 482 provided over the substrate 480 includes semiconductor elements processed into an island shape, and each semiconductor element is separated by removal of a semiconductor layer by etching. On the other hand, in a memory element portion 481, an impurity element that does not contribute to conductivity is added to an uninterrupted semiconductor layer, whereby element separation regions are formed, and each semiconductor element is separated by the element separation regions with high resistance. In a case where required characteristics of the semiconductor element of the peripheral circuit portion and the memory element portion are different from each other, for example, in a case where a voltage that is applied to the semiconductor element in the memory element portion (for example, a (writing) voltage of about 10 to 20 V) is higher than a voltage that is applied to the semiconductor element in the peripheral circuit portion (for example, a voltage of about 3 to 5 V), adversely affect of insufficient coverage of the semiconductor layer with a gate insulating layer is large and easily generated. Therefore, in FIG. 20C, a semiconductor element may be used, in which an element region in an uninterrupted semiconductor layer is preferably used for the memory element portion 481, and an element region that is separated into island-shaped semiconductor layers is used for the peripheral circuit portion 482. In a case where the memory element portion in which writing or erasing is needed to be performed at a voltage of about 10 to 20 V and the peripheral circuit portion in which control of input/output of data and instruction is mainly performed at a voltage of about 3 to 7 V are formed over the same substrate, mutual interference by difference of voltages applied to each element can be prevented.

As similar to FIG. 20C, FIG. 20D shows an example in which a different element separation method is applied to semiconductor elements provided over the substrate 485 depending on a required function and size. In FIG. 20D, a peripheral circuit portion 487b provided over the substrate 485 includes semiconductor elements processed into an island shape, and each semiconductor element is separated by removal of a semiconductor layer by etching. On the other hand, in a peripheral circuit portion 487a and a memory element portion 481, an impurity element that does not contribute to conductivity is added to an uninterrupted semiconductor layer, whereby element separation regions are formed, and each semiconductor element is separated by the element separation regions with high resistance. In such a manner, a structure in which elements are selectively separated by island-shaped semiconductor layers and a structure in which elements are separated by providing element separation regions in an uninterrupted semiconductor layer are appropriately combined in the peripheral circuit portion and the memory element portion, depending on a circuit structure provided over the substrate.

The semiconductor elements provided over the substrate each have a different characteristic to be required depending on functions, and each shape thereof is changed in accordance with the required characteristic (for example, a thickness of a gate insulating layer or the like). In a region having a minute structure in which semiconductor elements are near to each other, element separation regions are provided in an uninterrupted semiconductor layer, whereby a plurality of semiconductor elements can be formed. On the other hand, in a region in which intervals between elements are comparatively large or thinning of films to a gate insulating layer is not required so much, a semiconductor layer is removed, and a plurality of semiconductor elements as island-shaped semiconductor layers can be manufactured. In such a manner, an element separation method is appropriately selected depending on characteristics to be required over the substrate, whereby a semiconductor device having high efficiency capable of high speed response and high reliability can be manufactured.

In the uninterrupted semiconductor layer, in order to electrically separate elements, the element separation regions are formed by selective addition of at least one or more kinds of impurity elements of oxygen, nitrogen, and carbon. The element separation region to which the impurity element that does not contribute to conductivity is added becomes to have high resistance because conductivity is reduced due to mixture of the impurity element that does not contribute to conductivity and crystallinity is reduced due to physical impact (it can be also referred to as so-called sputtering effect) to the semiconductor layer when adding the impurity element. In the element separation region that becomes to have high resistance, the elements can be electrically separated because electron field-effect mobility is also reduced. On the other hand, the region to which the impurity element is not added holds electric field-effect mobility capable of serving as an element; therefore, the region to which the impurity element is not added can be used as an element region.

Resistivity of the element separation region is preferably greater than or equal to 1×10¹⁰ Ω·cm, and concentration of the impurity element such as oxygen, nitrogen, or carbon is preferably greater than or equal to 1×10²⁰ cm⁻³ and less than 4×10²² cm⁻³.

It can be said that the element separation region is amorphous because crystallinity is reduced due to addition of the impurity element. On the other hand, the element region is a crystalline semiconductor layer; therefore, in a case of forming a semiconductor element in the element region, crystallinity of a channel formation region thereof is higher than that in the element separation region, and high electron field-effect mobility can be obtained as for a semiconductor element.

As the impurity element added to the element separation region, a rare gas element such as argon (Ar), neon (Ne), krypton (Kr), or xenon (Xe) may be used. When the rare gas element that has comparatively large mass is further added in addition to oxygen, nitrogen, and carbon, physical impact to the semiconductor layer can be increased, and accordingly, crystallinity can be efficiently reduced.

Accordingly, a semiconductor device having a highly reliable memory element in which defects such as a short between a charge accumulating layer, a control gate electrode layer, a gate electrode layer, and a semiconductor layer and a leakage current due to insufficient coverage of the semiconductor layer with the insulating layer are prevented, and a manufacturing method of such a semiconductor device can be provided. Thus, further miniaturization and high integration can be performed in the semiconductor device having a memory element, and high efficiency of the semiconductor device can be achieved. In addition, a defect due to a defective shape of such a film can be reduced; therefore, production can be performed with high yield in the manufacturing process.

### Embodiment Mode 6

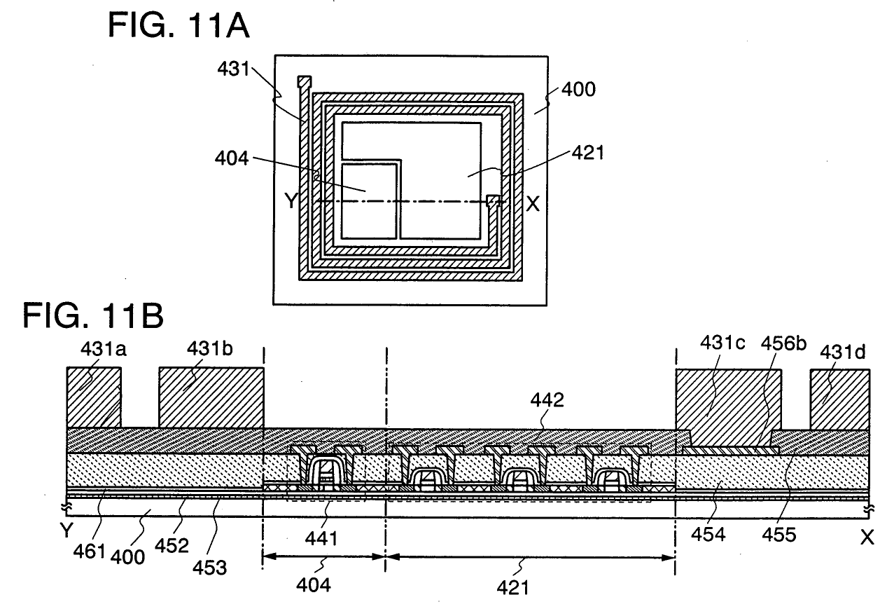

In this embodiment mode, an example of a semiconductor device will be explained with reference to drawings, which has a memory element (also referred to as a storage element) intended to prevent defects such as a short between a gate electrode layer and a semiconductor layer and a leakage current due to insufficient coverage of the semiconductor layer with an insulating layer in a semiconductor element and to give higher reliabilty. FIG. 11A is a top view of a semiconductor device of this embodiment mode, and FIG. 11B is a cross-sectional view taken along a line X-Y in FIG. 11A.

As shown in FIG. 11A, a memory element portion 404, a circuit portion 421, and an antenna 431 which are a semiconductor device having a memory element are formed over a substrate 400. FIGS. 11A and 11B show a state in which the memory element portion, the circuit portion, and the antenna are formed over the substrate 400 that can withstand a manufacturing condition, which is during a manufacturing process. A material and manufacturing steps may be selected similarly to Embodiment Mode 3 to manufacture the semiconductor device.

A memory element 441 in the memory element portion 404 and a transistor 442 in the circuit portion 421 are provided over the substrate 400 with a peeling layer 452 and an insulating layer 453 interposed therebetween. An insulating layer 455 is formed over the memory element 441 and the transistor 442.

In the semiconductor device in FIG. 11B, antennas 431a, 431b, 431c, and 431d are each formed over the insulating layer 455. The antenna 431c is formed to be in contact with a wiring layer 456b at an opening formed in the insulating layer 455, which reaches the wiring layer 456b. Thus, the antenna is electrically connected to the memory portion 404 and the circuit portion 421.

It is to be noted that this embodiment mode can be implemented by being combined with the above embodiment modes freely. Further, the semiconductor device manufactured in this embodiment mode is peeled from the substrate in a peeling step and attached to a flexible substrate, whereby the semiconductor device can be provided over a flexible base to be a semiconductor device having flexibility.

The semiconductor device having flexibility that is attached to a flexible substrate is also referred to as an IC film. The IC film is a semiconductor device having flexibility of which a thickness is less than or equal to 100 μm, preferably less than or equal to 50 μm, further preferably less than or equal to 20 μm. The IC chip includes a semiconductor layer with a thickness of less than or equal to 100 μm, preferably less than or equal to 70 μm.

The flexible base corresponds to a substrate formed from PET (polyethylene terephthalate), PEN (polyethylene naphthalate), PES (polyethersulfone), polypropylene, polypropylene sulfide, polycarbonate, polyetherimide, polyphenylene sulfide, polyphenylene oxide, polysulfone, polyphthalamide, or the like; a film formed from polypropylene, polyester, vinyl, polyvinyl fluoride, vinyl chloride, or the like; paper formed from a fibrous material; a stacked film of a base film (such as polyester, polyamide, an inorganic evaporation film, or paper) and an adhesive synthetic resin film (such as an acrylic synthetic resin or an epoxy synthetic resin); or the like. The film is attached to an object by heat treatment and pressure treatment. When heat treatment and pressure treatment are performed to the film, an adhesive layer provided on the outermost surface of the film or a layer provided on the outermost layer (not the adhesive layer) is melted by heat and attached by pressure. The adhesive layer may be provided on the base but not necessarily. The adhesive layer corresponds to a layer including an adhesive such as a thermosetting resin, an ultraviolet curing resin, an epoxy resin adhesive, or a resin additive.

In the present invention, the memory element may be formed over a first substrate that is resistant to a process condition (such as temperature), and then may be transposed to a second substrate, whereby a semiconductor device having the memory element may be manufactured. In this specification, “transposition” is that the memory element formed over the first substrate is peeled from the first substrate and transposed to the second substrate; in other words, a place for providing the memory element is moved to another substrate.

A transposition step to another substrate may employ any of the following methods: a method in which a peeling layer and an insulating layer are formed between a substrate and an element formation layer, a metal oxide film is provided between the peeling layer and the insulating layer, and the metal oxide film is weakened by crystallization, thereby peeling the element formation layer; a method in which an amorphous silicon film containing hydrogen is provided between a substrate having high heat resistance and an element formation layer, and the amorphous silicon film is irradiated with laser light or etched to be removed, thereby peeling the element-formation layer; a method in which a peeling layer and an insulating layer are formed between a substrate and an element formation layer, a metal oxide film is provided between the peeling layer and the insulating layer, the metal oxide film is weakened by crystallization, and a part of the peeling layer is etched and removed using a solution or a halogen fluoride gas such as NF₃, BrF₃, or ClF₃, thereby peeling the element formation layer by the weakened metal oxide film; a method in which a substrate over which an element formation layer is formed is mechanically removed or is etched and removed using a solution or a halogen fluoride gas such as NF₃, BrF₃, or ClF₃; or the like. Alternatively, a method in which a film containing nitrogen, oxygen, or hydrogen (such as an amorphous silicon film containing hydrogen, an alloy film containing hydrogen, or an alloy film containing oxygen) is used as a peeling layer, and the peeling layer is irradiated with laser light to release the nitrogen, oxygen, or hydrogen contained therein to promote peeling between an element formation layer and a substrate, may be used.

By combination of the above peeling methods, the transposing step can be more easily performed. That is, the peeling can also be performed with physical force (by a machine, or the like) after performing laser light irradiation; etching to the peeling layer with a gas, a solution, or the like; or mechanical removal with a sharp knife, scalpel, or the like; so as to make a condition where the peeling layer and the element formation layer can be easily peeled from each other.

The antenna may be provided either to overlap the memory element portion or to surround the memory element portion without overlapping the memory element portion. In the case of overlapping the memory element portion, the antenna may overlap the memory element portion either entirely or partially. A structure where the antenna portion and the memory element portion are overlapped with each other improves reliability because defective operation of a semiconductor device caused by noise or the like in a signal for communication by the antenna, or fluctuation or the like of electromotive force generated by electromagnetic induction can be reduced. Furthermore, the semiconductor device can also be downsized.

As a signal transmission system in the above semiconductor device that is capable of transmitting and receiving data without contact, an electromagnetic coupling system, an electromagnetic induction system, a microwave system, or the like can be used. The transmission system can be appropriately selected considering an intended use by a practitioner, and an optimum antenna may be provided in accordance with the transmission system.

For example, when an electromagnetic coupling system or an electromagnetic induction system (such as a 13.56 MHz band) is employed as the signal transmission system for the semiconductor device, electromagnetic induction caused by change in magnetic field density is utilized; therefore, a conductive layer serving as an antenna is formed into a ring shape (such as a loop antenna) or a spiral shape (such as a spiral antenna).

When a microwave system (such as an UHF band (a 860 to 960 MHz band), a 2.45 GHz band, or the like) is used as the signal transmission system for the semiconductor device, the shape such as the length of the conductive layer serving as an antenna may be appropriately set considering the wavelength of an electromagnetic wave used for signal transmission. For example, the conductive layer serving as an antenna can be formed into a linear shape (such as a dipole antenna), a flat shape (such as a patch antenna), a ribbon shape, or the like. The shape of the conductive layer serving as an antenna is not limited to a linear shape, and the conductive layer serving as an antenna may also be provided in the form of a curve, a meander, or a combination thereof, considering the wavelength of the electromagnetic wave.

The conductive layer serving as an antenna is formed from a conductive material by a CVD method, a sputtering method, a printing method such as screen printing or gravure printing, a droplet discharge method, a dispensing method, a plating method, or the like. The conductive layer is formed to have a single-layer structure or a stacked-layer structure of an element selected from aluminum (Al), titanium (Ti), silver (Ag), copper (Cu), gold (Au), platinum (Pt), nickel (Ni), palladium (Pd), tantalum (Ta), or molybdenum (Mo), or an alloy material or a compound material containing the foregoing element as its main component.

In a case of forming the conductive layer serving as an antenna by using screen printing, for example, the conductive layer can be provided by selectively printing conductive paste in which conductive particles each having a particle size of several nm to several tens of μm are dissolved or dispersed in an organic resin. As the conductive particle, a metal particle of one or more of silver (Ag), gold (Au), copper (Cu), nickel (Ni), platinum (Pt), palladium (Pd), tantalum (Ta), molybdenum (Mo), and titanium (Ti), or the like, a fine particle of silver halide, or a dispersive nanoparticle can be used. In addition, as the organic resin contained in the conductive paste, one or a plurality of organic resins each serving as a binder, a solvent, a dispersant, or a coating member of the metal particle can be used. Typically, an organic resin such as an epoxy resin or a silicone resin can be used. When forming the conductive layer, baking may be preferably performed after the conductive paste is extruded. For example, in the case of using fine particles (such as ones having a size of greater than or equal to 1 nm and less than or equal to 100 nm) containing silver as its main component, as a material of the conductive paste, the conductive layer can be obtained by baking at a temperature of 150 to 300° C. to be cured. Alternatively, fine particles containing solder or lead-free solder as its main component may be used. In this case, it is preferable to use a fine particle having a particle size of less than or equal to 20 μm. Solder or lead-free solder has an advantage of low cost. In addition to the foregoing materials, ceramic, ferrite, or the like may be applied to the antenna.

In a case where an electromagnetic coupling system or an electromagnetic induction system is employed and a semiconductor device having an antenna is provided to be in contact with metal, a magnetic material having magnetic permeability is preferably provided between the semiconductor device and the metal. If a semiconductor device having an antenna is provided to be in contact with metal, eddy current flows in the metal in accordance with change in a magnetic field, and a demagnetizing field generated by the eddy current impairs the change in magnetic field to shorten the communication distance. By providing of a material having magnetic permeability between the semiconductor device and the metal, eddy current of the metal can be suppressed, whereby reduction in a communication distance can be suppressed. Note that ferrite or a metal thin film having high magnetic permeability and little loss of high frequency wave can be used as the magnetic material.

Further, when providing an antenna, a semiconductor element such as a transistor and a conductive layer serving as an antenna may be directly formed over one substrate, or a semiconductor element and a conductive layer serving as an antenna may be provided over different substrates and then attached to be electrically connected to each other.

The memory element 441 and the transistor 442 use the present invention, and each channel formation region is formed in each element region provided in an uninterrupted semiconductor layer. In addition, the memory element and the transistor are separated by element separation regions with high resistance by addition of an impurity element that does not contribute to conductivity. As described above, with the use of the present invention, separation into a plurality of element regions can be performed without division of the semiconductor layer into island shapes, and a plurality of semiconductor elements can be manufactured. Accordingly, a step is not generated in an edge portion of the semiconductor layer, and an insulating layer is formed over the plane semiconductor layer, whereby coverage of the semiconductor layer with the insulating layer is improved.

Accordingly, a semiconductor device having a highly reliable memory element in which defects such as a short between a charge accumulating layer, a control gate electrode layer, a gate electrode layer, and a semiconductor layer and a leakage current due to insufficient coverage of the semiconductor layer with the insulating layer are prevented, and a manufacturing method of such a semiconductor device can be provided. Thus, further miniaturization and high integration can be performed in the semiconductor device having a memory element, and high efficiency of the semiconductor device can be achieved. In addition, a defect due to a defective shape of such a film can be reduced; therefore, production can be performed with high yield in the manufacturing process.

### Embodiment Mode 7

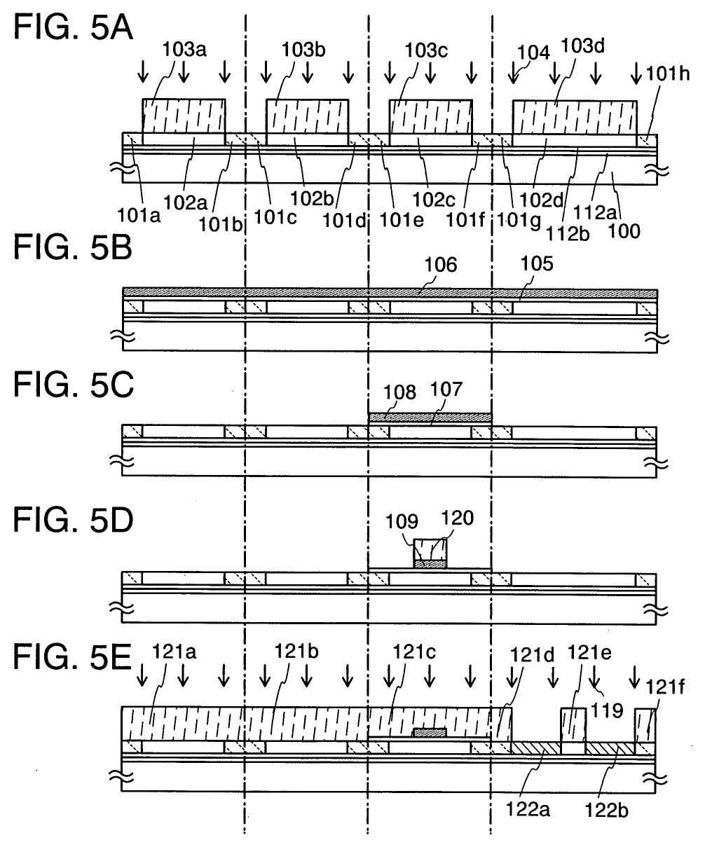

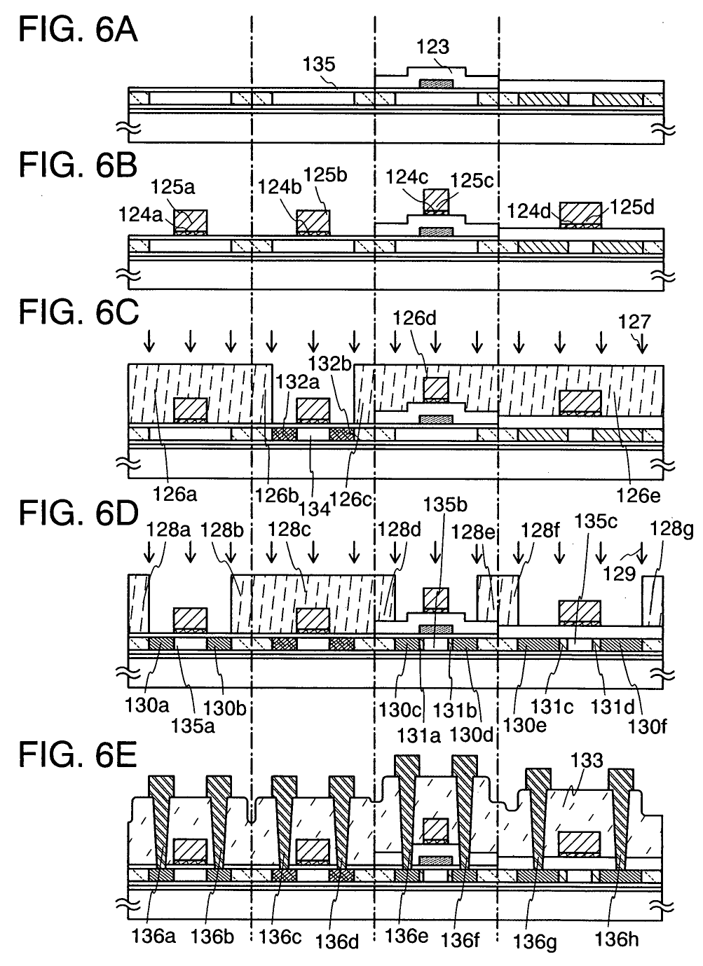

In this embodiment mode, an example of a semiconductor device will be explained with reference to drawings, which has a CMOS circuit and a memory element intended to prevent defects such as a short between a gate electrode layer and a semiconductor layer and a leakage current due to insufficient coverage of the semiconductor layer with an insualting layer in a semiconductor element and to give higher reliability. A manufacturing method of a semiconductor device in this embodiment mode will be explained in detail with reference to FIGS. 5A to SE and FIGS. 6A to 6E.

It is to be noted that a control transistor provided in a memory portion has a higher driving voltage than that of a transistor provided in a logic portion; therefore, gate insulating layers and the like of the transistor provided in the memory portion and the transistor provided in the logic portion are preferably formed to have different thicknesses from each other. For example, when a driving voltage is low and variation in threshold voltage is desired to be reduced, a thin film transistor in which a gate insulating layer is thin is preferably provided, whereas, when a driving voltage is high and a high withstanding voltage of a gate insulating layer is required, a thin film transistor in which a gate insulating layer is thick is preferably provided.

Therefore, in this embodiment mode, an insulating layer with a thin film thickness is formed to the transistor in the logic portion where a driving voltage is low and variation in threshold voltage is desired to be reduced, whereas, an insulating layer with a thick thickness is formed to the transistor in the memory portion where a driving voltage is high and a withstand voltage of a gate insulating layer is required.

Over a substrate 100 having an insulating surface, an insulating layer 112a serving as a base film is formed using a silicon nitride oxide film to have a thickness of 10 to 200 nm (preferably, 50 to 150 nm), and an insulating layer 112b is stacked thereover using a silicon oxynitride film to have a thickness of 50 to 200 nm (preferably, 100 to 150 nm), by a sputtering method, a PVD method (Physical Vapor Deposition), a low pressure CVD method (a LPCVD method), a CVD method (Chemical Vapor Deposition) such as a plasma CVD method, or the like. Alternatively, acrylic acid, methacrylic acid, or a derivative thereof, a heat-resistant high-molecular material such as polyimide, aromatic polyamide, or polybenzimidazole, or a siloxane resin may be used. It is to be noted that a siloxane resin corresponds to a resin including the Si—O—Si bond. Siloxane includes a skeleton structure formed by the bond of silicon (Si) and oxygen (O). As a substituent, an organic group containing at least hydrogen (such as an alkyl group or an aryl group) is used. Alternatively, a fluoro group may be used as the substituent. Further alternatively, a fluoro group and an organic group containing at least hydrogen may be used as the substituent. Moreover, the following resin material may also be used: a vinyl resin such as polyvinyl alcohol or polyvinyl butyral, an epoxy resin, a phenol resin, a novolac resin, an acrylic resin, a melamine resin, an urethane resin, or the like. Further, an organic material such as benzocyclobutene, parylene, fluorinated arylene ether, or polyimide; a composite material including a water-soluble homopolymer and a water-soluble copolymer; or the like may be used. Furthermore, an oxazole resin can also be used, for example, a photosensitive polybenzoxazole or the like can be used.

As a method, a droplet discharging method, a printing method (a method for forming a pattern, such as screen printing or offset printing), a coating method such as a spin coating method, a dipping method, a dispenser method, or the like can also be used. In this embodiment mode, the insulating layer 112a and the insulating layer 112b are formed by a plasma CVD method. The substrate 100 may be a glass substrate, a quartz substrate, a metal substrate, or a stainless steel substrate having a surface covered with an insulating film. In addition, a plastic substrate having heat resistance, which can withstand a processing temperature of this embodiment mode, or a flexible substrate such as a film may also be used. As a plastic substrate, a substrate formed of PET (polyethylene terephthalate), PEN (polyethylene naphthalate), or PES (polyether sulfone) can be used, and as a flexible substrate, a synthetic resin such as acrylic can be used.

As the insulating layer serving as a base film, silicon oxide, silicon nitride, silicon oxynitride, silicon nitride oxide, or the like can be used in a single layer structure or a stacked-layer structure to have two or three layers.

Next, a semiconductor layer is formed over the base film. The semiconductor layer may be formed by various methods (such as a sputtering method, an LPCVD method, and a plasma CVD method) to have a thickness of 25 to 200 nm (preferably, 30 to 150 nm). In this embodiment mode, it is preferable to use a crystalline semiconductor layer formed by crystallizing an amorphous semiconductor layer by laser irradiation.

The crystalline semiconductor layer may be formed by various methods (such as a laser crystallization method, a thermal crystallization method, and a thermal crystallization method using an element such as nickel that promotes crystallization). In addition, a microcrystalline semiconductor may be crystallized by laser irradiation to enhance crystallinity. In a case where an element that promotes crystallization is not used, before irradiating the amorphous semiconductor layer with laser light, the amorphous semiconductor layer is heated for one hour under a nitrogen atmosphere at 500° C. to discharge hydrogen so that a hydrogen concentration in the amorphous semiconductor layer becomes less than or equal to 1×10²⁰ atoms/cm³ or less. This is because, if the amorphous semiconductor layer contains much hydrogen, the amorphous semiconductor layer may be broken by laser light irradiation. Heat treatment for crystallization may be performed using a heating furnace, laser irradiation, irradiation of light emitted from a lamp (also referred to as a lamp annealing), or the like. As a heating method, an RTA method such as a GRTA (Gas Rapid Thermal Anneal) method or an LRTA (Lamp Rapid Thermal Anneal) method may be used. The GRTA is heat treatment using a high temperature gas, and the LRTA is heat treatment using lamp light.

Then, in the step of crystallizing an amorphous semiconductor layer to form a crystalline semiconductor layer, an element (also referred to as a catalyst element or a metal element) that promotes crystallization may be added to the amorphous semiconductor layer and crystallization may be performed by heat treatment (3 minutes to 24 hours at temperatures of 550 to 750° C.). One or more kinds of iron (Fe), nickel (Ni), cobalt (Co), ruthenium (Ru), rhodium (Rh), palladium (Pd), osmium (Os), iridium (Ir), platinum (Pt), copper (Cu), and gold (Au) can be used as a metal element that promotes crystallization.

A method for introducing a metal element into the amorphous semiconductor layer is not particularly limited as long as it is a method for introducing the metal element over a surface of or inside the amorphous semiconductor layer. For example, a sputtering method, a CVD method, a plasma treatment method (including a plasma CVD method), an adsorption method, or a method for coating a solution of metal salt can be used. Among them, a method for using a solution is simple and advantageous in that the concentration of the metal element can be easily controlled. At this time, it is desirable to form an oxide film by UV light irradiation in an oxygen atmosphere, a thermal oxidation method, treatment with ozone water containing hydroxyl radical or hydrogen peroxide, or the like to improve wettability of the surface of the amorphous semiconductor layer so as to diffuse an aqueous solution over the entire surface of the amorphous semiconductor layer.

In order to remove or reduce the element that promotes crystallization from the crystalline semiconductor layer, a semiconductor layer including an impurity element is formed in contact with the crystalline semiconductor layer and used as a gettering sink. The impurity element may be an impurity element imparting n-type conductivity, an impurity element imparting p-type conductivity, a rare gas element, or the like. For example, one or more kinds of elements of phosphorus (P), nitrogen (N), arsenic (As), antimony (Sb), bismuth (Bi), boron (B), helium (He), neon (Ne), argon (Ar), krypton (Kr), and xenon (Xe) can be used. A semiconductor layer including a rare gas element is formed in a crystalline semiconductor layer including an element that promotes crystallization, and thermal treatment is performed (3 minutes to 24 hours at 550 to 750° C.). The element that promotes crystallization included in the crystalline semiconductor layer moves into the semiconductor layer including a rare gas element. The element that promotes crystallization contained in the crystalline semiconductor layer is removed or reduced. Thereafter, the semiconductor layer including a rare gas element that is a gettering sink is removed.

A laser and the semiconductor layer are scanned relatively, whereby laser irradiation can be performed. In addition, in the laser irradiation, a marker can also be formed to overlap beams with high precision and control positions for starting and finishing laser irradiation. The marker may be formed over the substrate at the same time when an amorphous semiconductor film is formed.

In the case of laser irradiation, a continuous wave laser beam (CW laser beam) or a pulsed wave laser beam (pulsed laser beam) can be used. As the laser beam that can be used here, a laser beam oscillated from one or more of a gas laser such as an Ar laser, a Kr laser, and an excimer laser; a laser using, as a medium, single crystal of YAG YVO₄, forsterite (Mg₂SiO₄), YAlO₃, or GdVO₄ or a polycrystal (ceramic) of YAG, Y₂O₃, YVO₄, YAlO₃, and GdVO₄ doped with one or more kinds of Nd, Yb, Cr, Ti, Ho, Er, Tm, and Ta as a dopant; a glass laser; a ruby laser; an alexandrite laser; a Ti: sapphire laser; a copper vapor laser; and a gold vapor laser can be used. By emitting a laser beam of second to fourth wave of a fundamental harmonic in addition to a fundamental harmonic of the above laser beams, a crystal having a large grain size can be obtained. For example, a second harmonic (532 nm) or a third harmonic (355 nm) of Nd: YVO₄ laser (fundamental, 1064 nm) can be used. This laser can be emitted by CW or pulsed oscillation. In the case of CW, the laser requires power density of approximately from 0.01 to 100 MW/cm² (preferably, approximately from 0.1 to 10 MW/cm²). The laser is emitted at a scanning rate of approximately 10 to 2000 cm/sec.

Note that, a laser using, as a medium, single crystal of YAG, YVO₄, forsterite (Mg₂SiO₄), YAlO₃, or GdVO₄ or polycrystal (ceramic) of YAG, Y₂O₃, YVO₄, YAlO₃, or GdVO₄ doped with one or more kinds of Nd, Yb, Cr, Ti, Ho, Er, Tm, and Ta as a dopant; an Ar ion laser; or a Ti : sapphire laser can be continuously oscillated. Further, pulse oscillation thereof can be performed with an oscillation frequency of 10 MHz or more by performing Q switch operation, mode synchronization, or the like. When a laser beam is oscillated with a repetition rate of 10 MHz or more, a semiconductor layer is irradiated with a next pulse during the semiconductor layer is melted by the laser beam and then is solidified. Thus, differing from a case of using a pulse laser with a low repetition rate, a solid-liquid interface can be continuously moved in the semiconductor layer so that crystal grains, which continuously grow toward a scanning direction, can be obtained.

When ceramic (polycrystal) is used as a medium, the medium can be formed to have a free shape for short time at low cost. In a case of using a single crystal, a columnar medium with several mm in diameter and several tens of mm in length is usually used. However, in the case of using the ceramic, a medium bigger than the case of using the single crystal can be formed.

Concentration of a dopant such as Nd or Yb in a medium, which directly contributes to light emission, cannot be changed largely in both cases of the single crystal and the polycrystal; therefore, there is a limit in improvement in output of a laser by increasing the concentration to some extent. However, in the case of the ceramic, the size of a medium can be significantly increased as compared with the case of the single crystal; therefore, drastic improvement in output of a laser can be expected.

Further, in the case of the ceramic, a medium having a shape of a parallelepiped or a rectangular parallelepiped can be formed easily. In a case of using a medium having such a shape, when oscillated light is made travel in zigzag inside of the medium, a long path of the oscillated light can be obtained. Therefore, amplitude is increased and a laser beam can be oscillated at high output. Moreover, a cross-sectional shape of a laser beam emitted from a medium having such a shape is a quadrangular shape; therefore, as compared with a laser beam with a circular shape, the laser beam with the quadrangular shape in cross section have an advantage to be shaped into a linear beam. By shaping a laser beam emitted in the above manner using an optical system, a linear beam with 1 mm or less in length of a short side and several mm to several m in length of a long side can be easily obtained. Further, when a medium is uniformly irradiated with excited light, a linear beam is emitted with a uniform energy distribution in a long side direction. Furthermore, it is preferable that a semiconductor layer be irradiated with laser at an incident angle θ (0<θ<90°); therefore, an interference of the laser can be prevented.

The semiconductor layer is irradiated with this liner beam, whereby the entire surface of the semiconductor layer can be further uniformly annealed. When the linear beam is required to be uniform to the opposite ends, slits are provided at the opposite ends to shield light of energy attenuation portions or other measures are required to be taken.

The semiconductor layer may be irradiated with laser light under an inert gas atmosphere such as a rare gas or nitrogen as well. Accordingly, roughness of the surface of the semiconductor layer can be prevented by laser irradiation, and variation of a threshold voltage due to variation of interface state density can be prevented.

An amorphous semiconductor layer may be crystallized by a combination of crystallization of heat treatment and laser light irradiation, or one of heat treatment and laser light irradiation may be performed plural times.

The semiconductor layer thus obtained may be doped with a minute amount of impurity element (boron or phosphorus) to control a threshold voltage of the thin film transistor. This doping of the impurity element may be performed to the amorphous semiconductor layer before the crystallization step. When doping of the impurity element is performed in an amorphous semiconductor layer state, the impurity can be activated by heating treatment for crystallization in the subsequent step. Further, a defect or the like generated in the doping can be improved.

An impurity element is selectively added to the semiconductor layer that is a crystalline semiconductor layer to form element separation regions. The semiconductor layer is separated into plural element regions by the element separation regions. Mask layers 103a, 103b, 103c, and 103d are formed over the semiconductor layer, and an impurity element 104 that does not contribute to conductivity is added to the semiconductor layer. By addition of the impurity element 104 that does not contribute to conductivity, element separation regions 101a, 101b, 101c, 101d, 101e, 101f, 101g, and 101h, and element regions 102a, 102b, 102c, and 102d that are insulated by the element separation regions are formed in the semiconductor layer (see FIG. 5A).

In the uninterrupted semiconductor layer, in order to electrically separate elements, the element separation regions are formed by selective addition of at least one or more kinds of impurity elements of oxygen, nitrogen, and carbon. The element separation region to which the impurity element that does not contribute to conductivity is added becomes to have high resistance because conductivity is reduced due to mixture of the impurity element that does not contribute to conductivity and crystallinity is reduced due to physical impact (it can be also referred to as so-called sputtering effect) to the semiconductor layer when adding the impurity element. In the element separation region that becomes to have high resistance, the elements can be electrically separated because electron field-effect mobility is also reduced. On the other hand, the region to which the impurity element is not added holds electric field-effect mobility capable of serving as an element because high crystallinity and low resistance are held; therefore, the region to which the impurity element is not added can be used as an element region.

Resistivity of the element separation region is preferably greater than or equal to 1×10¹⁰ Ω·cm, and concentration of the impurity element such as oxygen, nitrogen, or carbon is preferably greater than or equal to 1×10²⁰ cm⁻³ and less than 4×10²² cm⁻³.

It can be said that the element separation region is amorphous because crystallinity is reduced due to addition of the impurity element. On the other hand, the element region is a crystalline semiconductor layer; therefore, in a case of forming a semiconductor element in the element region, crystallinity of a channel formation region thereof is higher than that in the element separation region, and high electron field-effect mobility can be obtained as for a semiconductor element.

As the impurity element added to the element separation region, a rare gas element such as argon (Ar), neon (Ne), krypton (Kr), or xenon (Xe) may be used. When the rare gas element that has comparatively large mass is further added in addition to oxygen, nitrogen, and carbon, physical impact to the semiconductor layer can be increased, and accordingly, crystallinity can be efficiently reduced.

In this embodiment mode, the element separation regions and the element regions are provided in the uninterrupted semiconductor layer; therefore, the element separation regions 101a, 101b, 101c, 101d, 101e, 101f, 101g, and 101h and the element regions 102a, 102b, 102c, and 102d that are insulated by the element separation regions are uninterrupted. Accordingly, a surface thereof has high planarity and no steep step.

Then, the masks are removed, and a first insulating layer 105 over the semiconductor layer and a charge accumulating layer 106 over the first insulating layer 105 are formed.

Since the first insulating layer 105 is formed over the semiconductor layer having high planarity, coverage is favorable and a defective shape is hardly generated. Therefore, defects such as a current leakage and a short between the charge accumulating layer 106 formed over the first insulating layer 105 and the element region 102c can be prevented. Accordingly, the semiconductor device of the nonvolatile semiconductor storage device of this embodiment mode can be a highly reliable semiconductor device in which defects such as a short between a charge accumulating layer and a semiconductor layer and a leakage current due to insufficient coverage of the semiconductor layer with the first insulating layer are prevented.

The first insulating layer 105 can be formed by heat treatment, plasma treatment, or the like to the semiconductor layer. For example, oxidation treatment, nitriding treatment, or oxynitriding treatment is performed to the semiconductor layer by high-density plasma treatment, whereby the first insulating layer 105 that is to be an oxide film, a nitride film, or an oxynitride film is formed over the semiconductor layer. Alternatively, the first insulating layer 105 may be formed by a plasma CVD method or a sputtering method.

For example, in a case where oxidation treatment or nitriding treatment is performed by high-density plasma density plasma treatment using a semiconductor layer containing Si as its main component as a semiconductor layer, a silicon oxide layer or a silicon nitride layer is formed as the first insulating layer 105. Alternatively, after oxidation treatment is conducted to the semiconductor layer by high-density plasma treatment, nitriding treatment may be conducted by performing high-density plasma treatment again. In this case, a silicon oxide layer is formed to be in contact with the semiconductor layer, and a nitrogen plasma treatment layer is formed over the surface of the silicon oxide layer or vicinity of the surface.

Here, the first insulating layer 105 is formed to have a thickness of 1 to 10 nm, preferably, 1 to 5 nm. For example, after oxidation treatment is performed to a semiconductor layer by high-density plasma treatment to form a silicon oxide layer with a thickness of about 3 nm over a surface of the semiconductor layer, nitriding treatment is performed by high-density plasma treatment to form a nitrogen plasma treatment layer over a surface of the silicon oxide layer or vicinity of the surface. Specifically, first, a silicon oxide layer with a thickness of 3 to 6 nm is formed over the semiconductor layer by plasma treatment under an oxide atmosphere. Subsequently, plasma treatment is continuously performed under a nitrogen atmosphere, whereby a nitrogen plasma treatment layer with high nitrogen concentration is provided over a surface of the silicon oxide layer or vicinity of the surface. Here, plasma treatment is performed under a nitrogen atmosphere, whereby nitrogen is contained at a ratio of 20 to 50 atom % at a depth of about 1 nm from the surface of the silicon oxide layer. In the nitrogen plasma treatment layer, silicon containing oxygen and nitrogen (silicon oxynitride) is formed. At this time, it is preferable that the oxidation treatment and nitriding treatment by high-density plasma treatment be continuously performed without being exposed to the atmospheric air absolutely. By performance of high-density plasma treatment continuously, prevention of mixture of containment and improvement in productivity can be achieved.

In a case of oxidizing the semiconductor layer by high-density plasma treatment, the treatment is performed under an oxygen atmosphere. As the oxygen atmosphere, for example, an atmosphere including oxygen (O₂) and a rare gas; an atmosphere including dinitrogen monoxide (N₂O) and a rare gas; an atmosphere including oxygen, hydrogen (H₂), and a rare gas; or an atmosphere including dinitrogen monoxide, hydrogen, and a rare gas is given. As the rare gas, at least one of He, Ne, Ar, Kr, and Xe is included. On the other hand, in a case of nitriding the semiconductor layer by high-density plasma treatment, the plasma treatment is performed under a nitrogen atmosphere. As the nitrogen atmosphere, for example, an atmosphere including nitrogen (N₂) and a rare gas; an atmosphere including nitrogen, hydrogen, and a rare gas; or an atmosphere including NH₃ and a rare gas is given. As the rare gas, at least one of He, Ne, Ar, Kr, and Xe is included.

As the rare gas, for example, Ar can be used. Alternatively, a gas in which Ar and Kr are mixed may be used. In a case of performing high-density plasma treatment under a rare gas atmosphere, the first insulating layer 105 may include the rare gas (at least one of He, Ne, Ar, Kr, and Xe) that is used for the plasma treatment. When Ar is used, the first insulating layer 105 may include Ar.

Moreover, the high-density plasma treatment is performed under an atmosphere including the aforementioned gas with an electron density of 1×10¹¹ cm⁻³ or more and plasma electron temperature of 1.5 eV or less. More specifically, the electron density is greater than or equal to 1×10¹¹ cm⁻³ and less than or equal to 1×10¹³ cm⁻³ and the plasma electron temperature is greater than or equal to 0.5 eV and less than or equal to 1.5 eV. Since the plasma electron density is high and the electron temperature in the vicinity of an object to be processed that is formed over the substrate 100 (here, the semiconductor layer) is low, plasma damage on the object to be processed can be prevented. Moreover, since the plasma electron density is as high as 1×10¹¹ cm⁻³ or more, an oxide film or a nitride film formed by oxidizing or nitriding the object to be processed by using the plasma treatment can be dense and superior in uniformity of its film thickness and the like as compared with a film formed by a CVD method, a sputtering method, or the like. Furthermore, since the plasma electron temperature is as low as 1.5 eV or less, oxidation treatment or nitriding treatment can be performed at a lower temperature as compared with that in conventional plasma treatment or a thermal oxidation method. For example, even plasma treatment at temperatures lower than the distortion point of a glass substrate by 100° C. or more can sufficiently perform oxidation treatment or nitriding treatment. When forming plasma, high frequency such as a microwave (for example, 2.45 GHz) can be used.

In this embodiment mode, in a case of performing oxidation treatment of the object to be processed by high-density plasma treatment, a mixture gas of oxygen (O₂), hydrogen (H₂), and argon (Ar) is introduced. The mixture gas used here may be introduced under the condition that oxygen is 0.1 to 100 sccm, hydrogen is 0.1 to 100 sccm, and argon is 100 to 5000 sccm. It is to be noted that the mixture gas is preferably introduced under the condition of a ratio of oxygen:hydrogen:argon=1:1: 100. For example, oxygen may be 5 sccm, hydrogen may be 5 sccm, and argon may be 500 sccm.

In a case of performing nitriding treatment by high-plasma treatment, a mixture gas of nitrogen (N₂) and argon (Ar) is introduced. The mixture gas used here may be introduced under the condition that nitrogen is 20 to 2000 sccm, and argon is 100 to 10000 sccm. For example, nitrogen may be 200 sccm, and argon may be 1000 sccm.

In this embodiment mode, the first insulating layer 105 that is formed over the semiconductor layer in the memory portion serves as a tunnel insulating film in a nonvolatile memory element to be completed later. Therefore, the thinner the first insulating layer 105 is, the more easily the tunnel current flows, which allows a higher-speed operation as a memory. Further, when the first insulating layer 105 is thinner, electric charges can be accumulated at a lower voltage in a charge accumulating layer to be formed later; therefore, the power consumption of a semiconductor device can be reduced. Accordingly, the first insulating layer 105 is preferably formed to be thin.

In general, a thermal oxidation method is given as a method for forming a thin insulating layer over a semiconductor layer. However, when a substrate of which melting point is not sufficiently high, such as a glass substrate, is used as the substrate 100, it is very difficult to form the first insulating layer 105 by a thermal oxidation method. Moreover, an insulating layer formed by a CVD method or a sputtering method does not have enough film quality because of a defect inside the film, and a problem may be caused, in that a defect such as a pinhole is produced when the film is formed to be thin. In addition, an insulating layer formed by a CVD method or a sputtering method does not cover an edge portion of the semiconductor layer sufficiently, resulting in that a conductive layer and the like to be later formed over the first insulating layer 105 and the semiconductor layer may be in contact with each other to cause a short. Thus, when the first insulating layer 105 is formed by the high-density plasma treatment as shown in this embodiment mode, the insulating layer can be denser than an insulating layer formed by a CVD method, a sputtering method, or the like. As a result, the high speed operation and a charge-holding characteristic as a memory can be improved. In a case of forming the first insulating layer 105 by a CVD method or a sputtering method, after the insulating layer is formed, high-density plasma treatment is performed, and a surface of the insulating layer is preferably subjected to oxidation treatment, nitriding treatment, or oxynitriding treatment.

The charge accumulating layer 106 serving as a floating gate can be formed using silicon, a silicon compound, germanium, or a germanium compound. As the silicon compound, silicon nitride, silicon nitride oxide, silicon carbide, silicon germanium containing germanium at concentration of greater than or equal to 10 atom %, metal nitride, metal oxide, or the like can be applied. As a typical example of the germanium compound, silicon germanium is given. In this case, germanium of greater than or equal to 10 atom % with respect to silicon is preferably included. When concentration of germanium is less than or equal to 10 atom %, effect as a structural element fades, and the band gap does not become small effectively.

The charge accumulating layer 106 is applied to a semiconductor device relating to the present invention, which is intended to accumulate electric charges; however, another semiconductor material can be also applied as long as it has a similar function. For example, a ternary semiconductor containing germanium may be used. In addition, the semiconductor material may be hydrogenated. Further, as a material having a function of a charge accumulating layer of a nonvolatile memory element, the semiconductor material can be replaced with an oxide of the germanium or the germanium compound, or a nitride of the germanium or the germanium compound.

Further, metal nitride or metal oxide can be used to form the charge accumulating layer 106. As metal nitride, tantalum nitride, tungsten nitride, molybdenum nitride, titanium nitride, or the like can be used. As metal oxide, tantalum oxide, titanium oxide, tin oxide, or the like can be used.

Furthermore, the charge accumulating layer 106 may be formed to have a stacked-layer structure of the above materials. When a layer made from the silicon or the silicon compound, the metal nitride or the metal oxide is provided on an upper layer side of a layer formed from germanium or a germanium compound, the charge accumulating layer can be used as a barrier layer for the purpose of water resistance or chemical resistance in a manufacturing process. Accordingly, a substrate in a photolithography step, an etching step, and a washing step can be handled easily, and productivity can be improved. In other words, the charge accumulating layer can be processed easily.

The first insulating layer 105 and the charge accumulating layer 106 are processed into a desired shape, and accordingly a first insulating layer 107 and a charge accumulating layer 108 are formed over the element region 102c used as a memory element. Then, a mask layer 120 is formed over the charge accumulating layer 108, and the charge accumulating layer 108 is selectively etched using the mask layer 120, whereby a charge accumulating layer 109 is formed.

Next, an impurity region is formed in a specific region in the element region 102d. Here, after the mask layer 120 is removed, mask layers 121a, 121b, and 121c are formed to cover the element regions 102a, 102b, and 102c, and mask layers 121d, 121e, and 121f are formed to selectively cover part of the element region 102d. Then, an impurity element 119 is introduced to the element region 102d that is not covered with the mask layers 121a to 121f, whereby impurity regions 122a and 122b are formed (see FIG. 5E). As the impurity element, an impurity element imparting n-type conductivity or an impurity element imparting p-type conductivity is used. As the impurity element showing n-type conductivity, phosphorus (P), arsenic (As), or the like can be used. As the impurity element showing p-type conductivity, boron (B), aluminum (Al), gallium (Ga), or the like can be used. Here, phosphorus (P) is introduced as the impurity element to the element region 102d.

Next, a second insulating layer 123 is formed to cover the element region 102d and the first insulating layer 107 and the charge accumulating layer 109 that are formed above the element region 102c.

The second insulating layer 123 is formed by a CVD method, a sputtering method, or the like, to have a single layer or a stacked-layer using an insulating material such as silicon oxide, silicon nitride, silicon oxynitride (SiOxNy) (x>y>0), or silicon nitride oxide (SiNxOy) (x>y>0). Alternatively, the second insulating layer 123 may be formed using aluminum oxide (AlOx), hafnium oxide (HfOx), or tantalum oxide (TaOx). For example, in a case where the second insulating layer 123 is formed to have a single layer, a silicon oxynitride film or a silicon nitride film is formed to have a thickness of 5 to 50 nm. Alternatively, in a case where the second insulating layer 123 is formed to have three-layer structure, a silicon oxynitride film is formed as a first insulating layer, a silicon nitride film is formed as a second insulating layer, and a silicon oxynitride film is formed as a third insulating layer. Further, an oxide or nitride of germanium may be used as the second insulating layer 123.

It is to be noted that the second insulating layer 123 formed above the element region 102c serves as a control gate insulating layer in the nonvolatile memory element to be completed later, and the second insulating layer 123 formed above the element region 102d serves as a gate insulating layer in a transistor to be completed later.

Next, a third insulating layer 135 is formed to cover the element regions 102a and 102b (see FIG. 6A).

The third insulating layer 135 is formed using any method shown in the above forming method of the first insulating layer 105. For example, oxidation treatment, nitriding treatment, or oxynitriding treatment is performed to the semiconductor layer including the element regions 102a and 102b and the element separation regions 101a, 101b, 101c, and 101d by high-density plasma treatment, and the third insulating layer 135 to be an oxide film of silicon, a nitride film of silicon, or an oxynitride film of silicon is formed over the semiconductor layer.

Here, the third insulating layer 135 is formed to have a thickness of 1 to 20 nm, preferably, 1 to 10 nm. For example, after oxidation treatment is performed to the semiconductor layer by high-density plasma treatment and a silicon oxide film is formed over a surface of the semiconductor layer including the element regions 102a and 102b and the element separation regions 101a, 101b, 101c, and 101d, nitriding treatment is performed by high-density plasma treatment to form a silicon oxynitride film over a surface of the silicon oxide film. In this case, oxidation treatment or nitriding treatment is performed to a surface of the second insulating layer 123 formed above the element regions 102c and 102d, and an oxide film or an oxynitride film is formed. The third insulating layer 135 formed above the element regions 102a and 102b serves as a gate insulating layer in the transistor to be completed later.

Subsequently, a conductive film is formed to cover the third insulating layer 135 formed above the element regions 102a and 102b in the semiconductor layer and the second insulating layer 123 formed above the element regions 102c and 102d. Here, an example in which a first conductive film and a second conductive film are sequentially stacked is shown as the conductive film. As a matter of course, the conductive film may be a single layer or a stacked-layer structure having three or more layers.

The first conductive film and the second conductive film can be formed using an element selected from tantalum (Ta), tungsten (W), titanium (Ti), molybdenum (Mo), aluminum (Al), copper (Cu), chromium (Cr), niobium (Nb), or the like or an alloy material or a compound material containing the element as its main component. Alternatively, the first and second conductive films can be formed using a metal nitride film in which these elements are nitrided. In addition, the first and second conductive films can be formed using a semiconductor material typified by polycrystalline silicon that is doped with an impurity element such as phosphorus.

Here, the first conductive film is formed using tantalum nitride, and the second conductive film is formed using the tungsten over the first conductive layer. In addition, as the first conductive film, a single layer or a stacked-layer film selected from tungsten nitride, molybdenum nitride, or titanium nitride can be used, and as the second conductive film, a single layer or a stacked-layer film selected from tantalum, molybdenum, or titanium can be used.

Next, the first conductive film and the second conductive film provided by being stacked are removed by selective etching, whereby the first conductive film and the second conductive film are partially left above the element regions 102a, 102b, 102c, and 102e in the semiconductor layer, and the first conductive layers 124a, 124b, 124c, and 124d and second conductive layers 125a, 125b, 125c, and 125d, each of which serves as a gate electrode layer, are formed (see FIG. 6B). It is to be noted that a first conductive layer 124c and the second conductive layer 125c that are formed above the element region 102c in the memory portion serve as a control gate electrode layer in the nonvolatile memory element to be completed later. Further, the first conductive layers 124a, 124b, and 124d and the second conductive layers 125a, 125b, and 125d serve as a gate electrode layer in the transistor to be completed later.

Subsequently, mask layers 126a, 126b, 126c, 126d, and 126e are selectively formed to cover the element regions 102a, 102c, and 102d, and an impurity element is introduced to the element region 102b using the mask layers 126a to 126e, the first conductive layer 124b, and the second conductive layer 125b as a mask, whereby impurity regions are formed (see FIG. 6C). As the impurity element, an impurity element imparting n-type conductivity or an impurity element imparting p-type conductivity is used. As the impurity element showing n-type conductivity, phosphorus (P), arsenic (As), or the like can be used. As the impurity element showing p-type conductivity, boron (B), aluminum (Al), gallium (Ga), or the like can be used. Here, an impurity element having different conductivity from that of the impurity element introduced in the element region 102d in FIG SE (for example, boron (B)) is introduced. As a result, high concentration impurity regions 132a and 132b forming a source region or a drain region and a channel formation region 134 are formed in the element region 102b.

Then, mask layers 128a, 128b, 128c, 128d, 128e, 128f, and 128g are selectively formed to cover the element region 102b, and an impurity element 129 is introduced to the element regions 102a, 102c, and 102d using the mask layers 128a to 128g, the first conductive layers 124a, 124c, and 124d, and the second conductive layers 125a, 125c, and 125d as a mask, whereby impurity regions are formed (see FIG. 6D). As the impurity element, an impurity element imparting n-type conductivity or an impurity element imparting p-type conductivity is used. As the impurity element showing n-type conductivity, phosphorus (P), arsenic (As), or the like can be used. As the impurity element showing p-type conductivity, boron (B), aluminum (Al), gallium (Ga), or the like can be used. Here, as the impurity element, phosphorus (P) is used.

In FIG. 6D, the impurity element 129 is introduced, whereby high concentration impurity regions 130a and 130b forming a source region or a drain region and a channel formation region 135a are formed in the element region 102a. High concentration impurity regions 130c and 130d forming a source region or a drain region, low concentration regions 131a and 131b forming an LDD region, and a channel formation region 135b are formed in the element region 102c. High concentration impurity regions 130e and 130f forming a source region or a drain region, low concentration regions 131c and 131d forming an LDD region, and a channel formation region 135c are formed in the element region 102d.

Further, the low concentration regions 131a and 131b formed in the element region 102c are formed by penetration of the impurity element introduced in FIG. 6D to the charge accumulating layer 109 serving as a floating gate. Accordingly, the channel formation region 135b is formed in a region that is overlapped with the second conductive layer 125c and the charge accumulating layer 109 in the element region 102c. The low concentration impurity regions 131a and 131b are formed in regions that are overlapped with the charge accumulating layer 109 and are not overlapped with the second conductive layer 125c. The high concentration impurity regions 130c and 130d are formed in regions that are not overlapped with the charge accumulating layer 109 and the first conductive layer 124c.

Next, an insulating layer 133 is formed to cover the second insulating layer 123, the third insulating layer 135, the first conductive layers 124a to 124d, and the second conductive layers 125a to 125d, and wiring layers 136a, 136b, 136c, 136d, 136e, 136f, 136g, and 136h are formed over the insulating layer 133 to electrically connected to the high concentration impurity regions 130a and 130b, 132a and 132b, 130c and 130d, 130e and 130f formed in the element regions 102a, 102b, 102c, and 102d, respectively (see FIG. 6E).

The insulating layer 133 can be provided by a CVD method, a sputtering method, or the like to have a single layer of an insulating layer including oxygen or nitrogen such as a silicon oxide (SiO_{X}) layer, a silicon nitride (SiN_{X}) layer, a silicon oxynitride (SiO_{X}N_{Y}) (x>y>0) layer, or a silicon nitride oxide (SiN_{X}O_{Y}) (x>y>0) layer, a film including carbon such as a DLC (diamond like carbon) film, an organic material such as epoxy, polyimide, polyamide, polyvinyl phenol, benzocyclobutene, or acrylic, or a siloxane material such as a siloxane resin; or a stacked-layer structure thereof.

The wiring layers 136a to 136h are formed by a CVD method, a sputtering method, or the like, from an element selected from aluminum (Al), tungsten (W), titanium (Ti), tantalum (Ta), molybdenum (Mo), nickel (Ni), platinum (Pt), copper (Cu), gold (Au), silver (Ag), manganese (Mn), neodymium (Nd), carbon (C), or silicon (Si), or an alloy material or a compound material containing the element as its main component. The alloy material containing aluminum as its main component corresponds to, for example, a material containing aluminum as its main component and nickel, or an alloy material containing aluminum as its main component, nickel, and one of or both carbon and silicon. The wiring layers 136a to 136h may have, for example, a stacked-layer structure of a barrier film, an aluminum silicon (Al—Si) film, and a barrier film, or a stacked-layer structure of a barrier film, an aluminum silicon (Al—Si) film, a titanium nitride (TiN) film, and a barrier film. It is to be noted that the barrier film corresponds to a thin film of titanium, nitride of titanium, molybdenum, or nitride of molybdenum. Aluminum and aluminum silicon have a low resistance value and are inexpensive, which are optimum for a material of the wiring layers 136a to 136h. When upper and lower barrier layers are provided, generation of a hillock of aluminum or aluminum silicon can be prevented. By forming the barrier film of titanium that is an element having a high reducing property, even when a thin natural oxide film is formed over a crystalline semiconductor layer, the natural oxide film can be reduced, so that favorable contact with the crystalline semiconductor layer can be formed.

Therefore, with the use of the present invention, separation into a plurality of element regions can be performed without division of a semiconductor layer into island shapes. A step is not generated in an edge portion of the semiconductor layer, and an insulating layer is formed over the plane semiconductor layer. As a result, coverage of the semiconductor layer with the insulating layer is improved. Accordingly, a semiconductor device of a highly reliable nonvolatile semiconductor storage device in which defects such as a short between a charge accumulating layer, a control gate electrode layer, a gate electrode layer, and a semiconductor layer and a leakage current due to insufficient coverage of the semiconductor layer with an insulating layer are prevented, and a manufacturing method of such a semiconductor device can be provided. Thus, further miniaturization and high integration can be performed in the semiconductor device, and high efficiency of the semiconductor device can be achieved. In addition, a defect due to a defective shape of such a film can be reduced; therefore, production can be performed with high yield in the manufacturing process.

This embodiment mode can be implemented by being combined with another embodiment mode shown in the present specification.

### Embodiment Mode 8

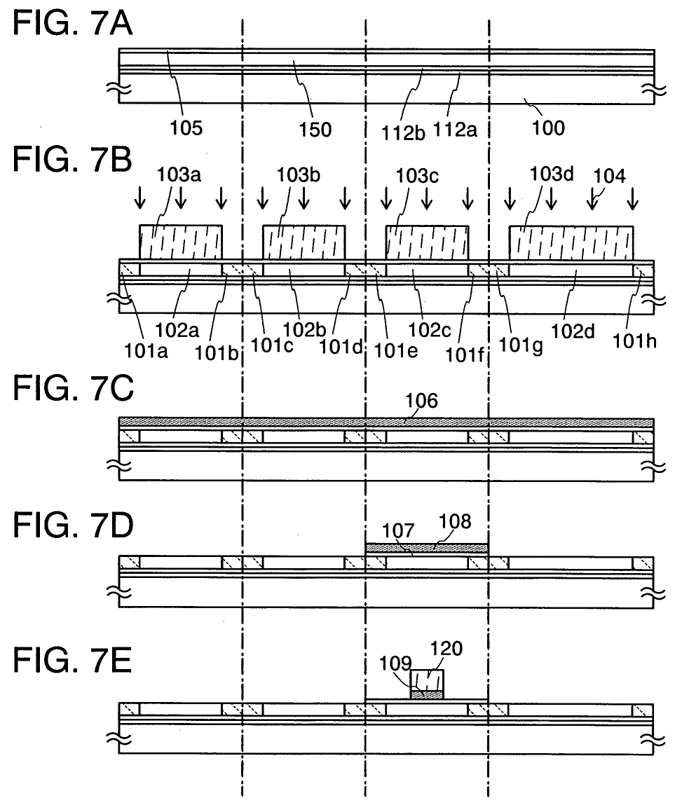

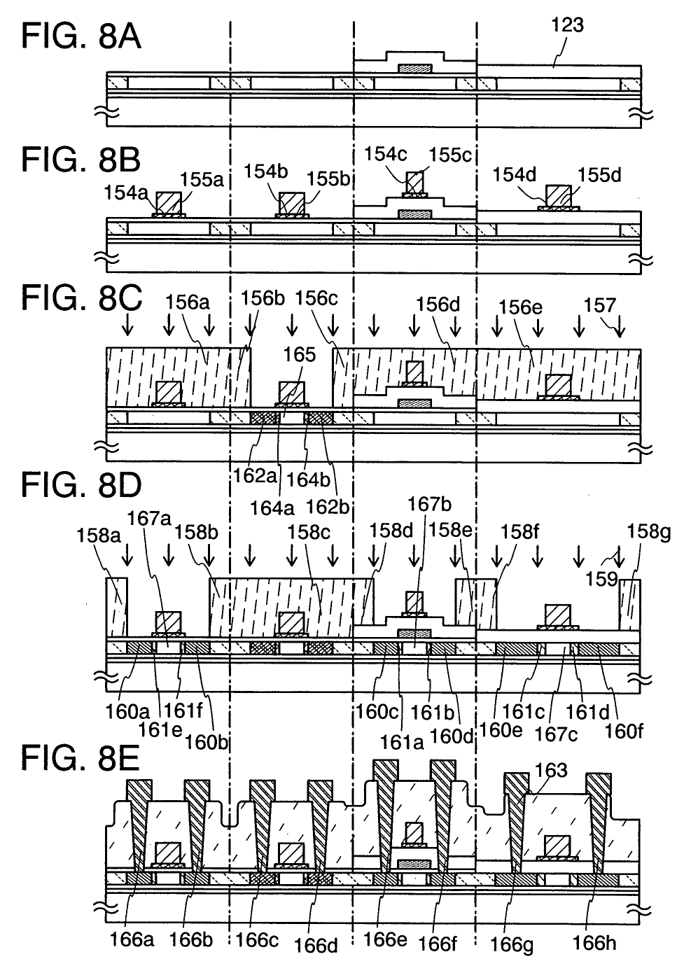

In this embodiment mode, an example of another semiconductor device will be explained with reference to drawings, which has a CMOS circuit and a memory element intended to prevent defects such as a short between a gate electrode layer and a semiconductor layer and a leakage current due to insufficient coverage of the semiconductor layer with an insulating layer in a semiconductor element and to give higher reliability. A manufacturing method of a semiconductor device in this embodiment mode will be explained in detail with reference to FIGS. 7A to 7E and FIGS. 8A to 8E. A semiconductor device of this embodiment mode has a different shape of a gate electrode layer and a control gate electrode layer from that of Embodiment Mode 7. When same portions as thoses in the above embodiment modes are indicated, the same reference numerals are denoted, and explanation thereof is omitted.

An insulating layer 112a and an insulating layer 112b that serve as a base film are stacked over a substrate 100 having an insulating surface.

Next, a semiconductor layer 150 is formed over the base film. The semiconductor layer 150 may be formed to have a thickness of 25 to 200 nm (preferably, 30 to 150 nm) by various methods (such as a sputtering method, an LPCVD method, or a plasma CVD method). In this embodiment mode, it is preferable that an amorphous semiconductor layer be subjected to laser crystallization to be a crystalline semiconductor layer.

The thus obtained semiconductor layer may be doped with a minute amount of an impurity element (boron or phosphorus) in order to control a threshold voltage of a thin film transistor. This doping of the impurity element may be performed to the amorphous semiconductor layer before a crystallization step. If doping of the impurity element is performed in the amorphous semiconductor layer state, the impurity can be activated by heat treatment for crystallization in the subsequent step. Further, a defect or the like generated in doping can be improved.

Then, a mask is removed, and a first insulating layer 105 is formed over the semiconductor layer 150.

The first insulating layer 105 can be formed by heat treatment, plasma treatment, or the like to the semiconductor layer. For example, oxidation treatment, nitriding treatment, or oxynitride treatment are performed to the semiconductor layer by high-density plasma treatment, whereby the first insulating layer 105 that is to be an oxide film, a nitride film, or an oxynitriding film is formed over the semiconductor layer. It is to be noted that the first insulating layer 105 may be formed by a plasma CVD method or a sputtering method.

For example, when oxidation treatment or nitriding treatment is performed using a semiconductor layer containing Si as its main component as the semiconductor layer by high-density plasma treatment, a silicon oxide layer or a silicon nitride layer is formed as the first insulating layer 105. Further, after oxidation treatment is performed to the semiconductor layer by high-density plasma treatment, nitriding treatment may be performed by high-density plasma treatment again. In this case, a silicon oxide layer is formed to be in contact with the semiconductor layer, and a nitride plasma treatment layer is formed over a surface of the silicon oxide layer or the vicinity of the surface.

Here, the first insulating layer 105 is formed to have a thickness of 1 to 10 nm, preferably, 1 to 5 nm. For example, after oxidation treatment is performed to the semiconductor layer by high-density plasma treatment to form a silicon oxide layer with a thickness of about 3 nm over a surface of the semiconductor layer, nitriding treatment is performed by high-density plasma treatment to form a nitrogen plasma treatment layer over the surface of a silicon oxide layer or the vicinity of the surface. Specifically, first, a silicon oxide layer is formed to have a thickness of 3 to 6 nm over the semiconductor layer by plasma treatment under an oxygen atmosphere. Subsequently, plasma treatment is continuously performed under a nitrogen atmosphere, whereby a nitrogen plasma treatment layer with high nitrogen concentration is provided over a surface of the silcon oxide layer or the vicinity of the surface. Here, nitrogen is contained at a ratio of 20 to 50 atom % at a depth of about 1 nm from the surface of the silicon oxide layer by plasma treatment under a nitrogen atmosphere. In the nitrogen plasma treatment layer, silicon containing oxygen and nitrogen (silicon oxynitride) is formed. At this time, it is preferable that oxidation treatment and nitriding treatment by high-density plasma treatment be continuously performed without being exposed to the atmospheric air even at a time. High-density plasma treatment is continuously performed, whereby prevention of mixture of contaminant and improvement in productivity can be achieved.

In this embodiment mode, the first insulating layer 105 formed over the semiconductor layer provided in a memory portion serves as a tunnel insulating layer in a nonvolatile memory element to be completed later. Therefore, the thinner the first insulating layer 105 is, the more easily the tunnel current flows, which allows a higher-speed operation as a memory. Further, when the first insulating layer 105 is thinner, charges can be accumulated at a lower voltage in a charge accumulating layer to be formed later; therefore, the power consumption of a semiconductor device can be reduced. Accordingly, the first insulating layer 105 is preferably formed to be thin.

An impurity element is selectively added to the semiconductor layer that is a crystalline semiconductor layer through the first insulating layer 105 to form element separation regions. The semiconductor layer is separated into a plurality of element regions by the element separation regions. Mask layers 103a, 103b, 103c, and 103d are formed over the semiconductor layer, and an impurity element 104 that does not contribute to conductivity is added. By addition of the impurity element 104 that does not contribute to conductivity, element separation regions 101a, 101b, 101c, 101e, 101f, 101g, and 101h and element regions 102a, 102b, 102c, and 102d that are insulated by the element separation regions are formed in the semiconductor layer (see FIG. 7B).

Since the impurity element is added to the semiconductor layer 150 through the first insulating layer 105 by a doping method or the like, physical energy in addition of the impurity element can be adjusted. Therefore, addition energy can be moderated at a level where the semiconductor layer is not damaged by breakdown or the like, and crystallinity of the semiconductor layer is selectively reduced to be able to form the element separation regions. After the impurity element is introduced and the element separation regions and the element regions are formed, the first insulating layer 105 is once removed and then is formed again. Plasma treatment is performed to the insulating layer that is formed again to have a dense surface of the insulating layer.

In the uninterrupted semiconductor layer, in order to electrically separate elements, the element separation regions are formed by selective addition of at least one or more kinds of impurity elements of oxygen, nitrogen, and carbon. The element separation region to which the impurity element that does not contribute to conductivity is added becomes to have high resistance because conductivity is reduced due to mixture of the impurity element that does not contribute to conductivity and crystallinity is reduced due to physical impact (it can be also referred to as so-called sputtering effect) to the semiconductor layer when adding the impurity element. In the element separation region that becomes to have high resistance, the elements can be electrically separated because electron field-effect mobility is also reduced. On the other hand, the region to which the impurity element is not added holds electric field-effect mobility capable of serving as an element because high crystallinity and low resistance are held; therefore, the region to which the impurity element is not added can be used as an element region.

Resistivity of the element separation region is preferably greater than or equal to 1×10¹⁰ Ω·cm, and concentration of the impurity element such as oxygen, nitrogen, or carbon is preferably greater than or equal to 1×10²⁰ cm⁻³ and less than 4×10²² cm⁻³.

It can be said that the element separation region is amorphous because crystallinity is reduced due to addition of the impurity element. On the other hand, the element region is a crystalline semiconductor layer; therefore, in a case of forming a semiconductor element in the element region, crystallinity of a channel formation region thereof is higher than that in the element separation region, and high electron field-effect mobility can be obtained as for a semiconductor element.

As the impurity element added to the element separation region, a rare gas element such as argon (Ar), neon (Ne), krypton (Kr), or xenon (Xe) may be used. When the rare gas element that has comparatively large mass is further added in addition to oxygen, nitrogen, and carbon, physical impact to the semiconductor layer can be increased, and accordingly, crystallinity can be efficiently reduced.

In this embodiment mode, the element separation regions and the element regions are provided in the uninterrupted semiconductor layer; therefore, the element separation regions 101a, 101b, 101c, 101d, 101e, 101f, 101g, and 101h and the element regions 102a, 102b, 102c, and 102d that are insulated in the element separation regions are uninterrupted. Accordingly, a surface thereof has high planarity and no steep step.

Since the first insulating layer 105 is formed over the semiconductor layer having high planarity, coverage is favorable and a defective shape is hardly generated. Therefore, defects such as a current leakage and a short between a charge accumulating layer 106 formed over the first insulating layer 105 and the element region 102c can be prevented. Accordingly, the semiconductor device of the nonvolatile semiconductor storage device of this embodiment mode can be a highly reliable semiconductor device in which defects such as a short between the charge accumulating layer, a control gate electrode layer to be formed later, and the semiconductor layer and a leakage current due to insufficient coverage of the semiconductor layer with the first insulating layer are prevented.

The charge accumulating layer 106 is formed over the first insulating layer 105 (see FIG. 7C).

The charge accumulating layer 106 can be formed using silicon, a silicon compound, germanium, or a germanium compound. As the silicon compound, silicon nitride, silicon nitride oxide, silicon carbide, silicon germanium containing germanium at concentration of greater than or equal to 10 atom %, metal nitride, metal oxide, or the like can be applied. As a typical example of the germanium compound, silicon germanium is given. In this case, germanium of greater than or equal to 10 atom % with respect to silicon is preferably contained. When concentration of germanium is less than or equal to 10 atom %, effect as a structural element fades, and the band gap does not become small effectively.

The charge accumulating layer 106 is applied to a semiconductor device relating to the present invention, which is intended to accumulate charges; however, another semiconductor material can be also applied as long as it has a similar function. For example, a ternary semiconductor containing germanium may be used. In addition, the semiconductor material may be hydrogenated. Further, as a material having a function of a charge accumulating layer of a nonvolatile memory element, the semiconductor material can be replaced with an oxide of the germanium or the germanium compound, or a nitride of the germanium or the germanium compound.

Further, metal nitride or metal oxide can be used to form the charge accumulating layer 106. As metal nitride, tantalum nitride, tungsten nitride, molybdenum nitride, titanium nitride, or the like can be used. As metal oxide, tantalum oxide, titanium oxide, tin oxide, or the like can be used.

Furthermore, the charge accumulating layer 106 may be formed to have a stacked-layer structure of the above materials. When a layer made from the silicon or the silicon compound, metal nitride or metal oxide is provided on an upper layer side of a layer formed from germanium or a germanium compound, the charge accumulating layer can be used as a barrier layer for the purpose of water resistance or chemical resistance in a manufacturing process. Accordingly, a substrate in a photolithography step, an etching step, and a washing step can be handled easily, and productivity can be improved. In other words, the charge accumulating layer can be processed easily

The first insulating layer 105 and the charge accumulating layer 106 are processed into a desired shape, and accordingly a first insulating layer 107 and a charge accumulating layer 108 are formed over the element region 102c used as a memory element. Then, a mask layer 120 is formed over the charge accumulating layer 108, and the charge accumulating layer 108 is selectively etched using the mask layer 120, whereby a charge accumulating layer 109 is formed.

Next, a second insulating layer 123 is formed to cover the element region 102i d and the first insulating layer 107 and the charge accumulating layer 109 that are formed above the element region 102c (see FIG. 8A).

It is to be noted that the second insulating layer 123 formed above the element region 102c serves as a control insulating layer in the nonvolatile memory element to be completed later, and the second insulating layer 123 formed above the element region 102d serves as a gate insulating layer in a transistor to be completed later.

Next, a third insulating layer 135 is formed to cover the element regions 102a and 102b.

Subsequently, a conductive film is formed to cover the third insulating layer 135 formed above the element regions 102a and 102b in the semiconductor layer and the second insulating layer 123 formed above the element regions 102c and 102d. Here, an example in which a first conductive film and a second conductive film are sequentially stacked is shown as the conductive film. As a matter of course, the conductive film may be a single layer or a stacked-layer structure having three or more layers.

Then, the stacked first conductive film and second conductive film are removed by selective etching, whereby the first conductive film and the second conductive film are partially left above the element regions 102a, 102b, 102c, and 102d, and first conductive layers 154a, 154b, 154c, and 154d and second conductive layers 155a, 155b, 155c, and 155d, each of which serves as a gate electrode layer are formed (see FIG. 8B). It is to be noted that the first conductive layer 154c and the second conductive layer 155c that are formed above the element region 102c in the memory portion serve as a control gate electrode layer in the nonvolatile memory element to be completed later. Further, the first conductive layers 154a, 154b, and 154d and the second conductive layer 155a, 155b, and 155d serve as a gate electrode layer in the transistor to be completed later.

Subsequently, mask layers 156a, 156b, 156c, 156d, and 156e are selectively formed to cover the element regions 102a, 102c, and 102d. An impurity element 157 is introduced to the element region 102b using the mask layers 156a to 156e, the first conductive layer 154b, and the second conductive layer 155b as a mask to form impurity regions (see FIG. 8C). As the impurity element, an impurity element imparting n-type conductivity or an impurity element imparting p-type conductivity is used. As the impurity element showing n-type conductivity, phosphorus (P), arsenic (As), or the like can be used. As the impurity element showing p-type conductivity, boron (B), aluminum (Al), gallium (Ga), or the like can be used. Here, an impurity element (for example, boron (B)) is introduced. As a result, high concentration impurity regions 162a and 162b forming a source region or a drain region, low concentration impurity regions 164a and 164b forming an LDD region, a channel formation region 164 are formed in the element region 102b.

Then, mask layers 158a, 158b, 158c, 158d, 158e, 158f, and 158g are selectively formed to cover the element region 102b. An impurity region 159 is introduced to the element regions 102a, 102c, and 102d using the mask layers 158a to 158g, the first conductive layers 154a, 154c, and 154d, and the second conductive layers 155a, 155c, and 155d as a mask to form impurity regions (see FIG. 8D). As the impurity element, an impurity element imparting n-type conductivity or an impurity element imparting p-type conductivity is used. As the impurity element showing n-type conductivity, phosphorus (P), arsenic (As), or the like can be used. As the impurity element showing p-type conductivity, boron (B), aluminum (Al), gallium (Ga), or the like can be used. Here, as the impurity element, phosphorus (P) is used.

In FIG. 8D, the impurity element is introduced, whereby high concentration impurity regions 160a and 160b forming a source region or a drain region, low concentration impurity regions 161e and 161f forming an LDD region, and a channel formation region 167a are formed in the element region 102a. In the element region 102c, high concentration impurity regions 160c and 160d forming a source region or a drain region, low concentration impurity regions 161a and 161b forming an LDD region, and a channel formation region 167b are formed. In the element region 102d, high concentration impurity regions 160e and 160f forming a source region or a drain region, low concentration impurity regions 161c and 161d forming an LDD region, and a channel formation region 167c are formed.

Then, an insulating layer 163 is formed to cover the second insulating layer 123, the third insulating layer 135, the first conductive layers 154a to 154d, and the second conductive layers 155a to 155d, and wiring layers 166a, 166b, 166c, 166d, 166e, 166f, 166g, and 166h are formed over the insulating layer 163, which are electrically connected to the high concentration impurity regions 160a and 160b, 162a and 162b, 160c and 160d, 160e and 160f, respectively, in the element regions 102a, 102b, 102c, and 102d.

Therefore, with the use of the present invention, separation into a plurality or element regions can be performed without division of a semiconductor layer into island shapes. A step is not generated in an edge portion of the semiconductor layer, and an insulating layer is formed over the plane semiconductor layer. As a result, coverage of the the semiconductor layer with insulating layer is improved. Accordingly, a semiconductor device of a highly reliable nonvolatile semiconductor storage device in which defects such as a short between a charge accumulating layer, a control gate electrode layer, a gate electrode layer, and a semiconductor layer and a leakage current due to insufficient coverage of the semiconductor layer with the insulating layer are prevented, and a manufacturing method of such a semiconductor device can be provided. Thus, further miniaturization and high integration can be performed in the semiconductor device, and high efficiency of the semiconductor device can be achieved. In addition, a defect due to a defective shape of such a film can be reduced; therefore, production can be performed with high yield in the manufacturing process.

This embodiment mode can be implemented by being combined with another embodiment mode shown in the present specification.

### Embodiment Mode 9

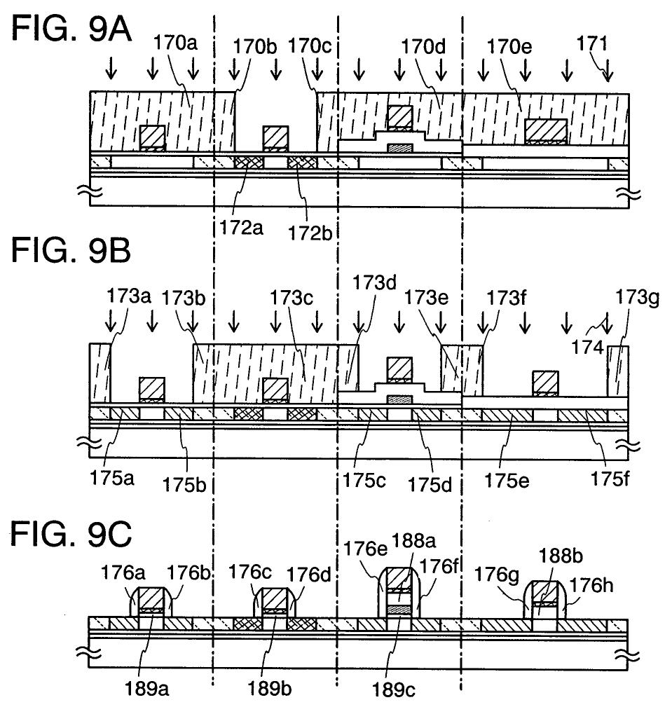

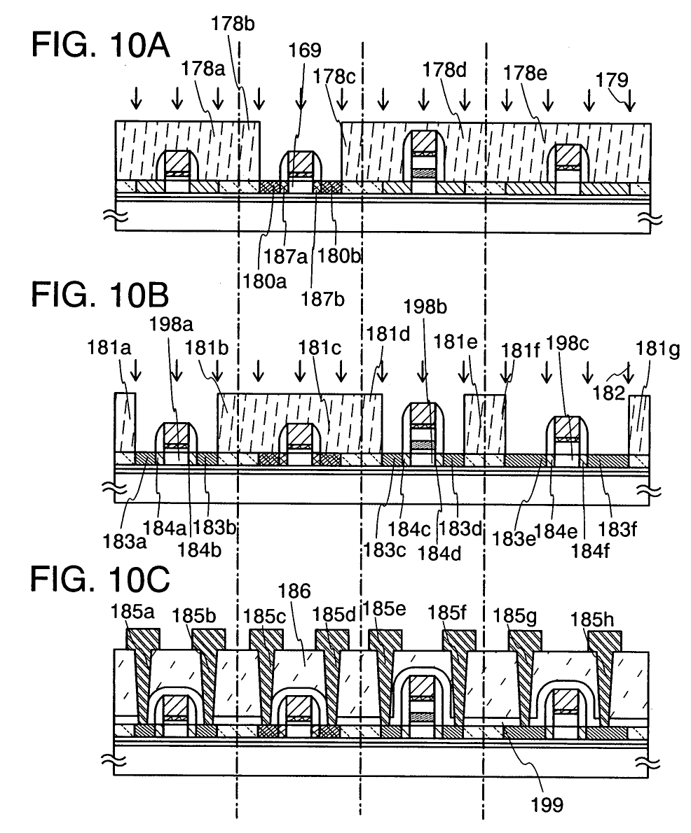

In this embodiment mode, an example of another semiconductor device will be explained with reference to drawings, which has a CMOS circuit and a memory element intended to prevent defects such as a short between a gate electrode layer and a semiconductor layer and a leakage current due to insufficient covergage of an insulating layer in a semiconductor element and to give higher reliability. A manufacturing method of a semiconductor device of this embodiment mode will be explained detail with reference to FIGS. 9A to 9C and FIGS. 10A to 10C. A semiconductor device of this embodiment mode has a different shape of a first insulating layer and a second insulating layer from that in the semiconductor device of Embodiment Mode 7. When same portions as thoses in the above embodiment modes are indicated, the same reference numerals are denoted, and explanation thereof is omitted.

In Embodiment Mode 9, a semiconductor device that has a CMOS circuit and a memory element is manufactured up to a state of FIG. 6B.

As shown in FIG. 9A, makes layers 170a, 170b, 170c, 170d, and 170e are selectively formed to cover the element regions 102a, 102c, and 102d. An impurity element 171 is introduced to the element region 102b using the mask layers 170a to 170e, the first conductive layer 154b, and the second conductive layer 155b as a mask, whereby impurity regions are formed (see FIG. 9A). As the impurity element, an impurity element imparting n-type conductivity or an impurity element imparting p-type conductivity is used. As the impurity element showing n-type conductivity, phosphorus (P), arsenic (As), or the like can be used. As the impurity element showing p-type conductivity, boron (B), aluminum (Al), gallium (Ga), or the like can be used. Here, an impurity element (for example, boron (B)) is introduced. As a result, impurity regions 172a and 172b are formed in the element region 102b.

Next, mask layers 173a, 173b, 173c, 173d, 173e, 173f, and 173g are selectively formed to cover the element region 102b. An impurity element 174 is introduced to the element regions 102a, 102c, and 102d using the mask layers 173a to 173g, the first conductive layers 154a, 154c, and 154d, and the second conductive layers 155a, 155c, and 155d as a mask, whereby impurity regions are formed (see FIG. 9B). As the impurity element, an impurity element imparting n-type conductivity or an impurity element imparting p-type conductivity is used. As the impurity element showing n-type conductivity, phosphorus (P), arsenic (As), or the like can be used. As the impurity element showing p-type conductivity, boron (B), aluminum (Al), gallium (Ga), or the like can be used. Here, as the impurity element, phosphorus (P) is used.

In FIG. 9B, an impurity element 174 is introduced, whereby impurity regions 175a and 175b are formed in the element region 102a. In the element region 102c, impurity regions 175c and 175d are formed. In the element region 102d, impurity regions 175e and 175f are formed.

Next, the first insulating layer 107, the second insulating layer 123, and the third insulating layer 135 are selectively etched using the first conductive layers 154a to 154d and the second conductive layers 155a to 155d as a mask to form insulating layers 188a and 188b and insulating layers 189a, 189b, and 189c. Insulating layers (also referred to as a sidewall) 176a, 176b, 176c, 176d, 176e, 176f, 176g, and 176h are formed, which are in contact with the first conductive layers 154a to 154d, the second conductive layers 155a to 155d, the charge accumulating layer 109, the insulating layers 188a and 188b, and the insulating layers 189a to 189c.

As shown in FIG. 10A, mask layers 178a, 178b, 178c, 178d, and 178e are selectively formed to cover the element regions 102a, 102c, and 102d. An impurity element 179 is introduced to the element region 102b using the mask layers 178a to 178e, the first conductive layer 154b, the second conductive layer 155b, and the insulating layers 176c, 176d, and 189a as a mask, whereby impurity regions are formed (see FIG. 10A). As the impurity element, an impurity element imparting n-type conductivity or an impurity element imparting p-type conductivity is used. As the impurity element showing n-type conductivity, phosphorus (P), arsenic (As), or the like can be used. As the impurity element showing p-type conductivity, boron (B), aluminum (Al), gallium (Ga), or the like can be used. Here, an impurity element (for example, boron (B)) is introduced. As a result, high concentration impurity regions 180a and 180b forming a source region or a drain region, low concentration impurity regions 187a and 187b forming an LDD region, and a channel formation region 169 are formed in the element region 102b.

Next, mask layers 181a, 181b, 181c, 181d, 181e, 181f, and 181g are selectively formed to cover the element region 102b. An impurity element 174 is introduced to the element regions 102a, 102c, and 102d using the mask layers 181a to 181g, the first conductive layers 154a, 154c, and 154d, the second conductive layers 155a, 155c, and 155d, and the insulating layers 176a, 176v, 176e, 176f, 176g, and 176h as a mask, whereby impurity regions are formed (see FIG. 10B). As the impurity element, an impurity element imparting n-type conductivity or an impurity element imparting p-type conductivity is used. As the impurity element showing n-type conductivity, phosphorus (P), arsenic (As), or the like can be used. As the impurity element showing p-type conductivity, boron (B), aluminum (Al), gallium (Ga), or the like can be used. Here, as the impurity element, phosphorus (P) is used.

In FIG. 10B, the impurity element is introduced, whereby high concentration impurity regions 183a and 183b forming a source region or a drain region, low concentration impurity regions 184a and 184b forming an LDD region, and a channel formation region 198a are formed in the element region 102a. In the element region 102c, high concentration impurity regions 183c and 183d forming a source region or a drain region, low concentration impurity regions 184c and 184d forming an LDD region, and a channel formation region 198b are formed. In the element region 102d, high concentration impurity regions 183e and 183f forming a source region or a drain region, low concentration impurity regions 184e and 184f forming an LDD region, and a channel formation region 198c are formed.

Subsequently, insulating layers 199 and 186 are formed to cover the first conductive layers 154a to 154d, the second conductive layers 155a to 155d, and the insulating layers 176a to 176h, and wiring layers 185a, 185b, 185c, 185d, 185e, 185f, 185g, and, 185h are formed, which are electrically connected to the high concentration impurity regions 183a and 183b, 180a and 180b, 183c and 183d, 183e and 183f formed, respectively, in the element regions 102a, 102b, 102c, and 102d over the insulating layers 199 and 186 (see FIG. 10C).

In a semiconductor element of this embodiment mode, element separation regions including the impurity element are formed in the semiconductor layer to use element regions that are subjected to element separation.

In the uninterrupted semiconductor layer, in order to electrically separate elements, the element separation regions are formed by selective addition of at least one or more kinds of impurity elements of oxygen, nitrogen, and carbon. The element separation region to which the impurity element that does not contribute to conductivity is added becomes to have high resistance because conductivity is reduced due to mixture of the impurity element that does not contribute to conductivity and crystallinity is reduced due to physical impact (it can be also referred to as so-called sputtering effect) to the semiconductor layer when adding the impurity element. In the element separation region that becomes to have high resistance, the elements can be electrically separated because electron field-effect mobility is also reduced. On the other hand, the region to which the impurity element is not added holds electric field-effect mobility capable of serving as an element; therefore, the region to which the impurity element is not added can be used as an element region.

Resistivity of the element separation region is preferably greater than or equal to 1×10¹⁰ Ω·cm, and concentration of the impurity element such as oxygen, nitrogen, or carbon is preferably greater than or equal to 1×10²⁰ cm⁻³ and less than 4×10²² cm⁻³.

It can be said that the element separation region is amorphous because crystallinity is reduced due to addition of the impurity element. On the other hand, the element region is a crystalline semiconductor layer; therefore, in a case of forming a semiconductor element in the element region, crystallinity of a channel formation region thereof is higher than that in the element separation region, and high electron field-effect mobility can be obtained as for a semiconductor element.

As the impurity element added to the element separation region, a rare gas element such as argon (Ar), neon (Ne), krypton (Kr), or xenon (Xe) may be used. When the rare gas element that has comparatively large mass is further added in addition to oxygen, nitrogen, and carbon, physical impact to the semiconductor layer can be increased, and accordingly, crystallinity can be efficiently reduced.

Therefore, with the use of the present invention, separation into a plurality of element regions can be performed without division of a semiconductor layer into island shapes. A step is not generated in an edge portion of the semiconductor layer, and an insulating layer is formed over the plane semiconductor layer. As a result, coverage of the semiconductor layer with the insulating layer is improved. Accordingly, a semiconductor device of a highly reliable nonvolatile semiconductor storage device in which defects such as a short between a charge accumulating layer, a control gate electrode layer, a gate electrode layer, and a semiconductor layer and a leakage current due to insufficient coverage of the semiconductor layer with an insulating layer are prevented, and a manufacturing method of such a semiconductor device can be provided. Thus, further miniaturization and high integration can be performed in the semiconductor device, and high efficiency of the semiconductor device can be achieved. In addition, a defect due to a defective shape of such a film can be reduced; therefore, production can be performed with high yield in the manufacturing process.

This embodiment mode can be implemented by being combined with another embodiment mode shown in the present specification.

### Embodiment Mode 10

In this embodiment mode, an example of another nonvolatile semiconductor storage device will be explained with reference to drawings, which is a semiconductor device intended to prevent defects such as a short between a charge accumulating layer, a control gate electrode layer, and a semiconductor layer and a leakage cuurent due to insufficient coverage of the semiconductor layer with an insulating layer and to give higher reliability.

The memory elements shown in Embodiment Modes 2 to 9 show an example in which metal or a semiconductor material is used as the charge accumulating layer. In this embodiment mode, an insulating layer or an insulating layer including conductive particles or semiconductor particles such as silicon or germanium is used as a charge accumulating layer.

In order to accumulate charges, a charge accumulating layer is applied to a nonvolatile semiconductor storage device relating to the present invention. However, another material can be applied as long as it has similar function. A charge accumulating layer can be formed of an insulating layer having a defect of trapping charges in a film, or an insulating layer including conductive particles or semiconductor particles such as silicon or germanium. As a typical example of such a material, a silicon compound and a germanium compound are given. As the silicon compound, silicon nitride to which oxygen is added, silicon oxide to which nitrogen is added, nitride silicon to which oxygen and hydrogen are added, silicon oxide to which nitrogen and hydrogen are added, or the like is given. As the germanium compound, germanium nitride, germanium oxide, germanium nitride to which oxygen is added, germanium oxide to which nitrogen is added, germanium nitride to which oxygen and hydrogen are added, germanium oxygen to which nitrogen and hydrogen are added, or the like is given. Further, germanium particles or silicon germanium particles may be included in the charge accumulating layer.

In a memory element of this embodiment mode, element separation regions including an impurity element are formed in a semiconductor layer to use element regions that are subjected to element separation.

In the uninterrupted semiconductor layer, in order to electrically separate elements, the element separation regions are formed by selective addition of at least one or more kinds of impurity elements of oxygen, nitrogen, and carbon. The element separation region to which the impurity element that does not contribute to conductivity is added becomes to have high resistance because conductivity is reduced due to mixture of the impurity element that does not contribute to conductivity and crystallinity is reduced due to physical impact (it can be also referred to as so-called sputtering effect) to the semiconductor layer when adding the impurity element. In the element separation region that becomes to have high resistance, the elements can be electrically separated because electron field-effect mobility is also reduced. On the other hand, the region to which the impurity element is not added holds electric field-effect mobility capable of serving as an element; therefore, the region to which the impurity element is not added can be used as an element region.

Resistivity of the element separation region is preferably greater than or equal to 1×10¹⁰ Ω·cm, and concentration of the impurity element such as oxygen, nitrogen, or carbon is preferably greater than or equal to 1×10²⁰ cm⁻³ and less than 4×10²² cm⁻³.

It can be said that the element separation region is amorphous because crystallinity is reduced due to addition of the impurity element. On the other hand, the element region is a crystalline semiconductor layer; therefore, in a case of forming a semiconductor element in the element region, crystallinity of a channel formation region thereof is higher than that in the element separation region, and high electron field-effect mobility can be obtained as for a semiconductor element.

As the impurity element added to the element separation region, a rare gas element such as argon (Ar), neon (Ne), krypton (Kr), or xenon (Xe) may be used. When the rare gas element that has comparatively large mass is further added in addition to oxygen, nitrogen, and carbon, physical impact to the semiconductor layer can be increased, and accordingly, crystallinity can be efficiently reduced.

Therefore, with the use of the present invention, separation into a plurality of element regions can be performed without division of a semiconductor layer into island shapes. A step is not generated in an edge portion of the semiconductor layer, and an insulating layer is formed over the plane semiconductor layer. As a result, coverage of the semiconductor layer with the insulating layer is improved. Accordingly, a semiconductor device of a highly reliable nonvolatile semiconductor storage device in which defects such as a short between a charge accumulating layer, a control gate electrode layer, and a semiconductor layer and a leakage current due to insufficient coverage of the semiconductor layer with the insulating layer are prevented, and a manufacturing method of such a semiconductor device can be provided. Thus, further miniaturization and high integration can be performed in the semiconductor device, and high efficiency of the semiconductor device can be achieved. In addition, a defect due to a defective shape of such a film can be reduced; therefore, production can be performed with high yield in the manufacturing process.

This embodiment mode can be implemented by being combined with another embodiment mode shown in the present specification.

### Embodiment Mode 11

In this embodiment mode, an example of a semiconductor device will be explained with reference to drawings, which is intended to prevent defects such a short between a gate electrode layer and a semiconductor layer and a leakage current due to insufficient coverage of the semiconductor layer with an insulating layer in a semiconductor element and to give higher reliability.

In Embodiment Modes 1 to 10, the examples in which a semiconductor layer is provided over a substrate having an insulating surface are shown; however, in this embodiment mode, an example in which a semiconductor substrate such as Si or a SOI substrate is used instead of the thin film processes is shown.

An SOI (Silicon on Insulator) substrate in which a crystalline semiconductor layer formed over an insulating surface can be formed by a method for attaching a wafer or a method for implanting oxygen ions into a Si substrate to form an insulating layer inside, which is referred to as SIMOX.

In a memory element of this embodiment mode, element separation regions including an impurity element are formed in a semiconductor layer to use element regions that are subjected to element separation.

In the uninterrupted semiconductor layer, in order to electrically separate elements, the element separation regions are formed by selective addition of at least one or more kinds of impurity elements of oxygen, nitrogen, and carbon. The element separation region to which the impurity element that does not contribute to conductivity is added becomes to have high resistance because conductivity is reduced due to mixture of the impurity element that does not contribute to conductivity and crystallinity is reduced due to physical impact (it can be also referred to as so-called sputtering effect) to the semiconductor layer when adding the impurity element. In the element separation region that becomes to have high resistance, the elements can be electrically separated because electron field-effect mobility is also reduced. On the other hand, the region to which the impurity element is not added holds electric field-effect mobility capable of serving as an element; therefore, the region to which the impurity element is not added can be used as an element region.

Resistivity of the element separation region is preferably greater than or equal to 1×10¹⁰ Ω·cm, and concentration of the impurity element such as oxygen, nitrogen, or carbon is preferably greater than or equal to 1×10cm⁻³ and less than 4×10²² cm⁻³.

It can be said that the element separation region is amorphous because crystallinity is reduced due to addition of the impurity element. On the other hand, the element region is a crystalline semiconductor layer; therefore, in a case of forming a semiconductor element in the element region, crystallinity of a channel formation region thereof is higher than that in the element separation region, and high electron field-effect mobility can be obtained as for a semiconductor element.

As the impurity element added to the element separation region, a rare gas element such as argon (Ar), neon (Ne), krypton (Kr), or xenon (Xe) may be used. When the rare gas element that has comparatively large mass is further added in addition to oxygen, nitrogen, and carbon, physical impact to the semiconductor layer can be increased, and accordingly, crystallinity can be efficiently reduced.

Therefore, with the use of the present invention, separation into a plurality of element regions can be performed without division of a semiconductor layer into island shapes. Further, heat treatment at a high temperature is not performed; thus, volume expansivity is not caused, and planarity of a surface of the semiconductor layer (or a semiconductor substrate) is favorably held. A step is not generated in an edge portion of the semiconductor layer, and an insulating layer is formed over the plane semiconductor layer. As a result, coverage of the semiconductor layer with the insulating layer is improved. Accordingly, a semiconductor device of a highly reliable nonvolatile semiconductor storage device in which defects such as a short between a charge accumulating layer, a control gate electrode layer, a gate electrode layer, and a semiconductor layer and a leakage current due to insufficient coverage of the semiconductor layer with the insulating layer are prevented, and a manufacturing method of such a semiconductor device can be provided without a complicated process. Thus, further miniaturization and high integration can be performed in the semiconductor device, and high efficiency of the semiconductor device can be achieved. In addition, a defect due to a defective shape of such a film can be reduced; therefore, production can be performed with high yield in the manufacturing process.

This embodiment mode can be implemented by being combined with another embodiment mode shown in the present specification.

### Embodiment Mode 12

In this embodiment mode, an application example of a semiconductor device provided with a nonvolatile semiconductor storage device or the like formed with the use of the present invention, in which data can be input and output without contact, will be explained with reference to drawings. The semiconductor device in which data can be input and output without contact is referred to as an RFID tag, an ID tag, an IC tag, an IC chip, an RF tag, a wireless tag, an electron tag, or a wireless chip depending on the usage mode.

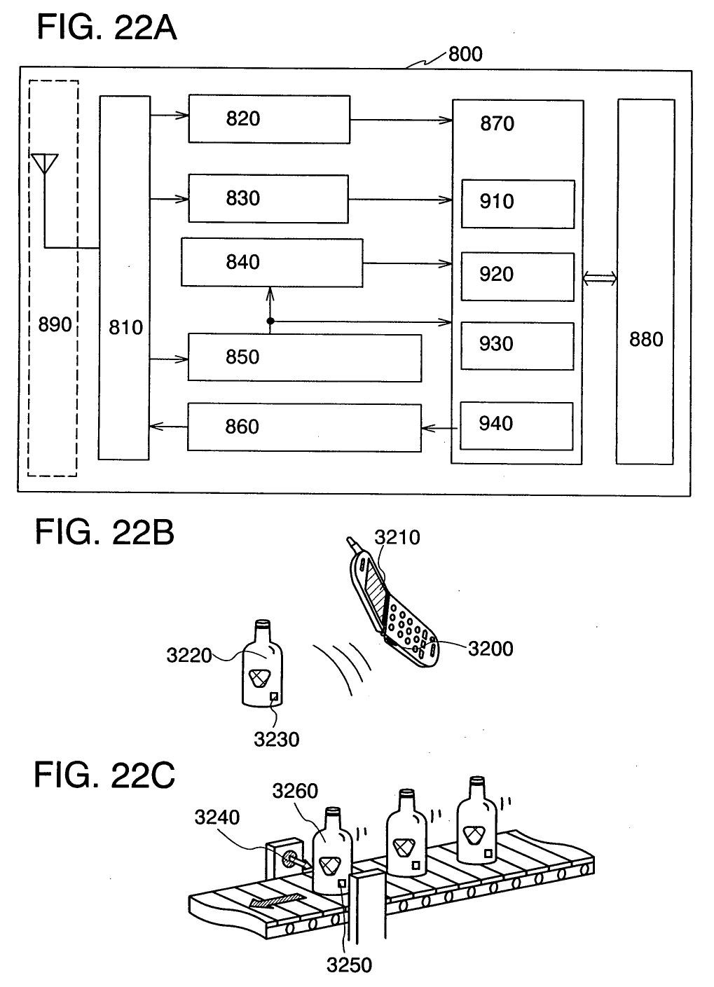

A semiconductor device 800 has a function of exchanging data without contact, and includes a high-frequency circuit 810, a power supply circuit 820, a reset circuit 830, a clock generating circuit 840, a data demodulating circuit 850, a data modulating circuit 860, a control circuit 870 for controlling another circuit, a storage circuit 880, and an antenna 890 (FIG 22A). The high-frequency circuit 810 receives a signal from the antenna 890 and outputs a signal, which is received from the data modulating circuit 860, from the antenna 890. The power supply circuit 820 generates power supply potential from a received signal. The reset circuit 830 generates a reset signal. The clock generating circuit 840 generates various clock signals based on a received signal input from the antenna 890. The data demodulating circuit 850 demodulates a received signal and outputs the demodulated signal to the control circuit 870. The data modulating circuit 860 modulates a signal received from the control circuit 870. As the control circuit 870, for example, a code extracting circuit 910, a code judging circuit 920, a CRC judging circuit 930, and an output unit circuit 940 are provided. It is to be noted that the code extracting circuit 910 extracts each of plural codes included in an instruction sent to the control circuit 870. The code judging circuit 920 judges the content of the instruction by comparing the extracted code with a code corresponding to a reference. The CRC judging circuit 930 detects whether or not there is a transmission error or the like based on the judged code.

Subsequently, an example of operation of the aforementioned semiconductor device is explained. First, a wireless signal is received by the antenna 890 and then sent to the power supply circuit 820 through the high-frequency circuit 810, whereby high power supply potential (hereinafter referred to as VDD) is generated. The VDD is supplied to each circuit in the semiconductor device 800. A signal sent to the data demodulating circuit 850 through the high-frequency circuit 810 is demodulated (hereinafter, this signal is referred to as a demodulated signal). Moreover, signals passed through the reset circuit 830 and the clock generating circuit 840 and the demodulated signal through the data demodulating circuit 850, via the high-frequency circuit 810, are sent to the control circuit 870. The signals sent to the control circuit 870 are analyzed by the code extracting circuit 910, the code judging circuit 920, the CRC judging circuit 930, and the like. Then, based on the analyzed signals, the information of the semiconductor device stored in the storage circuit 880 is output. The output information of the semiconductor device is encoded through the output unit circuit 940. Further, the encoded information of the semiconductor device 800 passes through the data modulating circuit 860 and then is sent by the antenna 890 as a wireless signal. It is to be noted that low power supply potential (hereinafter, referred to as VSS) is common in the plural circuits included in the semiconductor device 800 and VSS can be GND. A nonvolatile semiconductor storage device or the like of the present invention can be applied to the storage circuit 880.

In such a manner, when a signal is sent from a reader/writer to the semiconductor device 800 and the signal sent from the semiconductor device 800 is received by the reader/writer, the data in the semiconductor device can be read.

Moreover, in the semiconductor device 800, a power supply voltage may be supplied to each circuit by electromagnetic waves without mounting a power supply (battery), or a power supply (battery) may be mounted so that a power supply voltage is supplied to each circuit by both electromagnetic waves and the power supply (battery) that is mounted.

Next, an example of usage of a semiconductor device in which data can be input and output without contact is explained. A side surface of a mobile terminal including a display portion 3210 is provided with a reader/writer 3200. A side surface of a product 3220 is provided with a semiconductor device 3230 (FIG. 22B). When the reader/writer 3200 is held over the semiconductor device 3230 included in the product 3220, the display portion 3210 displays information on the product, such as a material, a production area, an inspection result for each production step, history of circulation process, and description of the product. In addition, when a product 3260 is transferred by a conveyer belt, the product 3260 can be inspected by using a semiconductor device 3250 provided to the product 3260 and a reader/writer 3240 (FIG. 22C). In such a manner, by using the semiconductor device in the system, information can be obtained easily and higher performance and higher value addition are achieved.

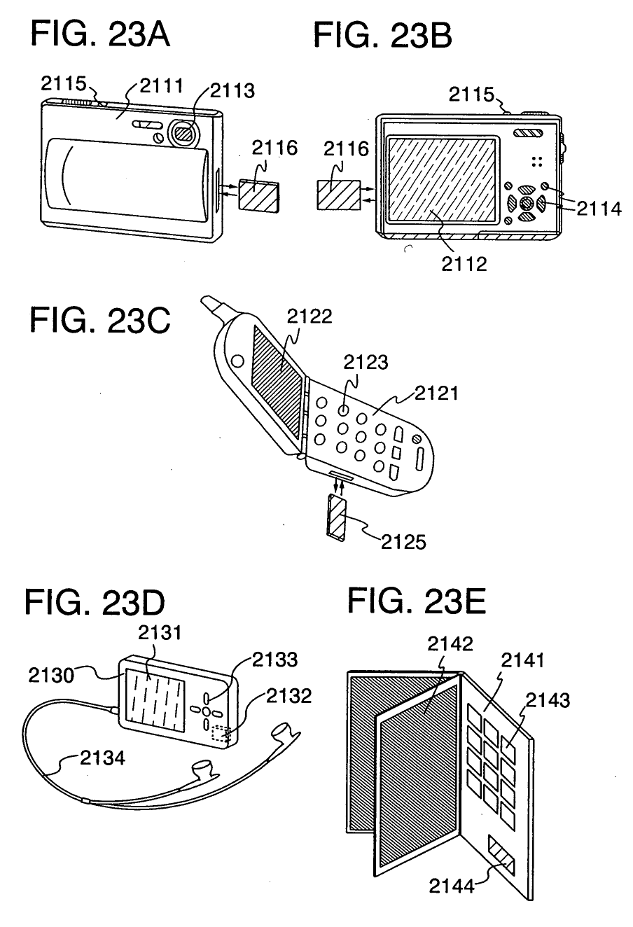

The nonvolatile semiconductor storage device or the like that is a semiconductor device with the use of the present invention can be used for various fields of electronic devices provided with a memory. For example, as an electronic device to which the nonvolatile semiconductor storage device of the present invention is applied, a camera such as a video camera and a digital camera, a goggle type display (a head mount display), a navigation system, an audio reproducing device (a car audio set, an audio component set, or the like), a computer, a game machine, a mobile information terminal (a mobile computer, a mobile phone, a portable game machine, an electronic book device, or the like), and an image reproducing device provided with a recording medium (specifically, a device provided with a display that can reproduce a recording medium such as a Digital Versatile Disc (DVD) and display the image), and the like can be given. Specific examples of such electronic devices are shown in FIGS. 23A to 23E.

FIGS. 23A and 23B show a digital camera. FIG. 23B is a view showing a rear side of FIG. 23A. This digital camera includes a chassis 2111, a display portion 2112, a lens 2113, operation keys 2114, a shutter button 2115, and the like. In addition, the digital camera is provided with a nonvolatile memory 2116 that can be detached, and has a structure in which data photographed by the digital camera is stored in the memory 2116. A nonvolatile semiconductor storage device that is a semiconductor device formed with the use of the present invention can be applied to the memory 2116.

FIG. 23C shows a mobile phone, which is a typical example of a mobile terminal. This mobile phone includes a chassis 2121, a display portion 2122, operation keys 2123, and the like. Further, this mobile phone is provided with a nonvolatile memory 2125 that can be detached, in which data such as a telephone number of the mobile phone, an image, music data, and the like can be stored and reproduced. A nonvolatile semiconductor storage device or the like that is a semiconductor device formed with the use of the present invention can be applied to the memory 2125.

FIG. 23D shows a digital player, which is a typical example of an audio reproducing device. The digital player shown in FIG. 23D includes a main body 2130, a display portion 2131, a memory portion 2132, an operation portion 2133, an earphone 2134, and the like. Instead of the earphone 2134, a headphone or a wireless earphone can be used. A nonvolatile semiconductor storage device or the like that is a semiconductor device formed with the use of the present invention can be used for the memory portion 2132. For example, a NAND-type nonvolatile memory in which memory capacity is 20 to 200 gigabyte (GB) is used to operate the operation portion 2133, whereby image and sound (music) can be recorded and reproduced. The display portion 2131 can suppress power consumption through display of white characters on the black background. This is particularly effective in a mobile audio device. It is to be noted that the nonvolatile semiconductor storage device provided in the memory portion 2132 may have a detachable structure.

FIG. 23E shows an electronic book device (also referred to as an electronic paper). This electronic book device includes a main body 2141, a display portion 2142, operation keys 2143, and a memory portion 2144, and the like. Further, a modem may be incorporated in the main body 2141, or a structure in which information can be sent and received without contact may be made. A nonvolatile semiconductor storage device or the like that is a semiconductor device formed with the use of the present invention can be used for the memory portion 2144. For example, a NAND-type nonvolatile memory in which memory capacity is 20 to 200 gigabyte (GB) is used to operate the operation keys 2143, whereby image and sound (music) can be recorded and reproduced. It is to be noted that the nonvolatile semiconductor storage device provided in the memory portion 2144 may have a detachable structure.

As described above, the application range of the semiconductor device of the present invention (particularly, a nonvolatile semiconductor storage device or the like that is a semiconductor device formed with the use of the present invention) is extremely wide and can be used for various fields of electronic devices as long as they have a memory.

### Embodiment Mode 13

A semiconductor device serving as a chip (hereinafter, also referred to as a processor chip, a wireless chip, a wireless processor, a wireless memory, or a wireless tag) that has a processor circuit can be formed by the present invention. The application range of the semiconductor device of the present invention is wide. For example, the semiconductor device of the present invention can be used by being provided for an object such as paper money, coins, securities, certificates, bearer bonds, packing containers, books, recording media, personal belongings, vehicles, food, clothing, health products, commodities, medicine, electronic devices, and the like.

The semiconductor device having a memory element with the use of the present invention has favorable adhesiveness inside the memory element; therefore, a peeling and transfer process can be performed with a good state. Therefore, an element can be freely transferred to various types of substrates, and therefore, an inexpensive material can also be selected for a substrate, so that the semiconductor device can be manufactured at low cost as well as having a wide function in accordance with the intended purpose can be given. Therefore, the chip having a processor circuit has also such features as low-cost, small and thin size, and light-weight according to the present invention, and thus is suitable for currency or coins circulating widely, or books, personal belongings, clothing, or the like which tend to be carried

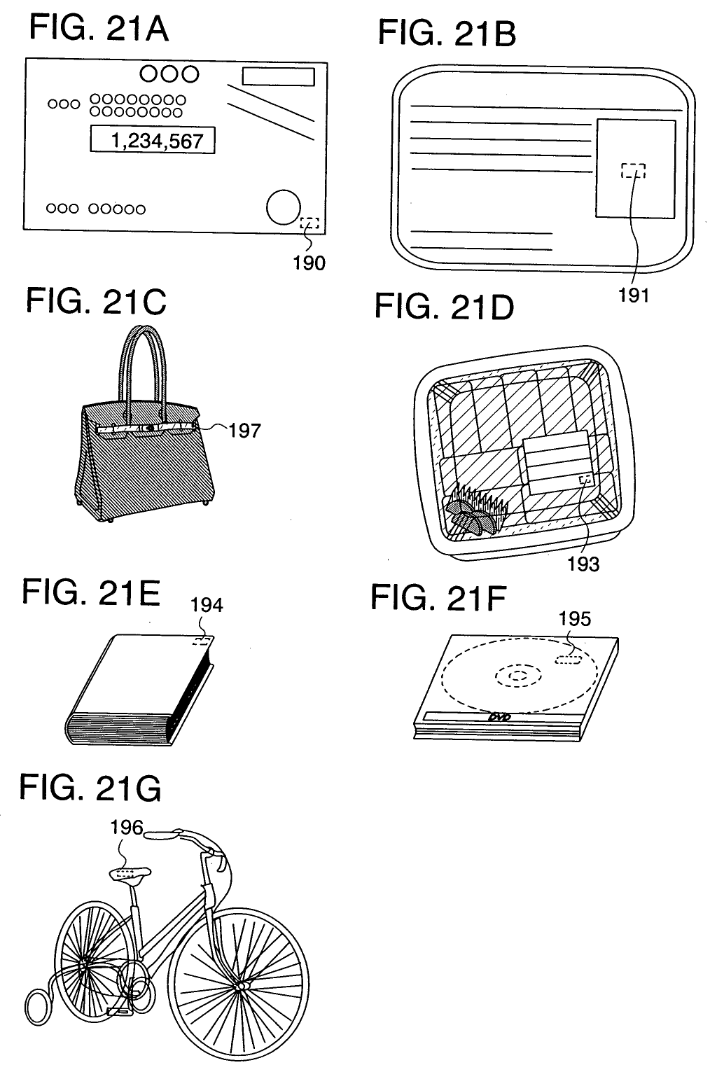

Paper money and coins are money circulated in the market and include in its category ones (cash vouchers) valid in a certain area similarly to currency, memorial coins, and the like. Securities refer to checks, certificates, promissory notes, and the like, and can be provided with a chip 190 having a processor circuit (see FIG. 21A). Certificates refer to driver's licenses, certificates of residence, and the like, and can be provided with a chip 191 having a processor circuit (see FIG. 21B). Personal belongings refer to bags, glasses, and the like, and can be provided with a chip 197 having a processor circuit (see FIG. 21C). Bearer bonds refer to stamps, rice coupons, various gift certificates, and the like. Packing containers refer to wrapping paper for food containers and the like, plastic bottles, and the like, and can be provided with a chip 193 having a processor circuit (see FIG. 21D). Books refer to hardbacks, paperbacks, and the like, and can be provided with a chip 194 having a processor circuit (see FIG. 21E). Recording media refer to DVD software, video tapes, and the like, and can be provided with a chip 195 having a processor circuit (see FIG. 21F). Vehicles refer to wheeled vehicles such as bicycles, ships, and the like, and can be provided with a chip 196 having a processor circuit (see FIG. 21G). Food refers to food articles, drink, and the like. Clothing refers to clothes, footwear, and the like. Health products refer to medical instruments, health instruments, and the like. Commodities refer to furniture, lighting equipment, and the like. Medicine refers to medical products, pesticides, and the like. Electronic devices refer to liquid crystal display devices, EL display devices, television devices (TV sets and thin TV sets), cellular phones, and the like.

The semiconductor device of the present invention is fixed on such an article by being mounted onto a printed-circuit board, by being attached to a surface thereof, or by being embedded therein. For example, in the case of a book, the semiconductor device may be embedded in paper thereof; in the case of a package made from an organic resin, the semiconductor device may be embedded in the organic resin; and then they are fixed on the article. The semiconductor device of the present invention which can realize small and thin size and light weight does not damage the design of an article itself even after being fixed on the article. Further, by providing the semiconductor device of the present invention for paper money, coins, securities, certificates, bearer bonds, or the like, an identification function can be provided, and forgery can be prevented by utilization of the identification function. Further, efficiency of a system such as an inspection system can be improved by providing the semiconductor device of the present invention for packing containers, recording media, personal belongings, food, clothing, commodities, electronic devices, or the like.

This application is based on Japanese Patent Application serial no. 2006-126993 filed in Japan Patent Office on Apr. 28 in 2006, the entire contents of which are hereby incorporated by reference.

What is claimed is:

1. A semiconductor device comprising:
a semiconductor layer over an insulating surface, the semiconductor layer includes at least two element regions, and an element separation region, and
an insulating layer over the semiconductor layer,
wherein:
the element separation region is disposed between the two element regions,
the element separation region includes at least one impurity element selected from the group consisting of oxygen, nitrogen, and carbon, and
the element separation region has higher resistance than a first source and drain regions included in one of the two element regions and a second source and drain regions included in the other of the two element regions.

2. The semiconductor device according to claim 1, further includes at least a gate electrode over the insulating layer, and wherein the gate electrode overlaps with the one of the two element regions.

3. The semiconductor device according to claim 1, wherein a surface of the semiconductor layer is a plane surface.

4. The semiconductor device according to claim 1, wherein the first source and drain regions and the second source and drain regions are electrically insulated by the element separation region.

5. The semiconductor device according to claim 1, wherein concentration of the impurity element included in the element separartion region is greater than or equal to 1×10²⁰ cm⁻³ and less than 4×10²² cm⁻³.

6. The semiconductor device according to claim 1, wherein resistivity of the element separation region is greater than or equal to 1×10¹⁰ Ω·cm.

7. The semiconductor device according to claim 1, wherein the element separation region further includes a rare gas element.

8. A semiconductor device comprising:
a semiconductor layer over an insulating surface, the semiconductor layer includes at least two element regions, and an element separation region, and
an insulating layer over the semiconductor layer,
wherein:
the element separation region is disposed between the two element regions,
the element separation region includes at least one impurity element selected from the group consisting of oxygen, nitrogen, and carbon,
the element separation region has higher resistance than a first source and drain regions included in one of the two element regions and a second source and drain regions included in the other of the two element regions, and
the element separation region has lower crystallinity than a first channel formation region included in the one of the two element regions and a second channel formation region included in the other of the two element regions.

9. The semiconductor device according to claim 8, further includes at least a gate electrode over the insulating layer, and wherein the gate electrode overlaps with the one of the two element regions.

10. The semiconductor device according to claim 8, wherein a surface of the semiconductor layer is a plane surface.

11. The semiconductor device according to claim 8, wherein the first source and drain regions and the second source and drain regions are electrically insulated by the element separation region.

12. The semiconductor device according to claim 8, wherein concentration of the impurity element included in the element separartion region is greater than or equal to 1×10²⁰ cm⁻³ and less than 4×10²² cm⁻³.

13. The semiconductor device according to claim 8, wherein resistivity of the element separation region is greater than or equal to 1×10¹⁰ Ω·cm.

14. The semiconductor device according to claim 8, wherein the element separation region further includes a rare gas element.

15. A method of manufacturing a semiconductor device comprising the steps of:
forming a semiconductor layer over an insulating surface,
forming at least two element regions and an element separation region in the semiconductor layer by selectively adding at least one impurity element selected from the group consisting of oxygen, nitrogen, and carbon, and
forming an insulating layer over the semiconducor layer.

16. The method of manufacturing a semiconductor device according to claim 15, further includes a step of forming at least a gate electrode over the insulating layer, and wherein the gate electrode overlaps with the one of the two element regions.

17. The method of manufacturing a semiconductor device according to claim 15, wherein a surface of the semiconductor layer is a plane surface.

18. The method of manufacturing a semiconductor device according to claim 15, wherein the first source and drain regions and the second source and drain regions are electrically insulated by the element separation region.

19. The method of manufacturing a semiconductor device according to claim 15, wherein concentration of the impurity element included in the element separartion region is greater than or equal to 1×10²⁰ cm⁻³ and less than 4×10²² cm⁻³.

20. The method of manufacturing a semiconductor device according to claim 15, wherein resistivity of the element separation region is greater than or equal to 1×101 Ω·cm.

21. The method of manufacturing a semiconductor device according to claim 15, wherein the element separation region further includes a rare gas element.
